(19) United States
(12) Patent Application Publication
(10) Pub. No.: US 2005/0151555 A1
(43) Pub. Date: Jul. 14, 2005

(54) Cooling devices and methods of using them

(75) Inventors: Brian Lewis, Branford, CT (US); Siman Slim, Piscataway, NJ (US); Angelo J. Gulino, Cranbury, NJ (US)

Correspondence Address: LOWRIE, LANDO & ANASTASI, RIVERFRONT OFFICE, ONE MAIN STREET, ELEVENTH FLOOR, CAMBRIDGE, MA, 02142, US

(73) Assignee: Cookson Electronics, Inc., Providence, RI (US)

(21) Appl. No.: 10/944,434

(22) Filed: Sep. 17, 2004

Related U.S. Application Data
(63) Continuation-in-part of application No. 10/892,303, filed on Jul. 15, 2004.
(63) Continuation-in-part of application No. 10/755,944, filed on Jan. 13, 2004.

(51) Int. Cl. G01R 31/02

(52) U.S. Cl. 324/760

(57) ABSTRACT

A method and device for cooling an electronic component during its manufacture, repair, or rework is disclosed. In certain examples, the cooling device includes a cooling device body optionally with one or more voids. In certain examples, a cooling medium that can receive, absorb or extract heat from the electronic component and/or the surrounding environment is disposed on or in the cooling device body. In some examples, a cooling device that includes a polymeric cooling device body, optionally with tape disposed on the polymeric cooling device body, is disclosed.

### CROSS REFERENCE TO RELATED APPLICATIONS

This application claims the benefit of, and is a continuation-in-part application of, U.S. application Ser. No. 10/892,303 entitled “Cooling Devices and Methods of Using Them” and filed Jul. 15, 2004, which itself is a continuation-in-part application of U.S. application Ser. No. 10/755,944 entitled “Thermal Protection for Electronic Components During Processing” and filed Jan. 13, 2004, the entire disclosure of each of which is incorporated herein by reference for all purposes.

### FIELD OF THE INVENTION

Certain examples disclosed herein relate generally to a cooling device. More particularly, certain examples relate to a method and device for protecting heat sensitive features of electronic components from damage during processing.

### BACKGROUND

As electronic products continue to shrink, there is a persistent effort to reduce the size of the integrated circuits (IC) found therein. At reduced architectural dimensions, an IC's heat sensitivity increases because of small feature size and thin wafers that distort easily. Additionally, ICs are now being designed to utilize novel and very thin organic or inorganic dielectrics, which also have limited thermal stability, in some cases well below 200° C. At the same time, the change to lead-free solders in ICs has increased the peak processing temperatures from, for example, about 220° C. for tin-lead solders to 245° C. or even 260° C. for tin-silver-copper solders.

The problem of thermal sensitivity is most pronounced with processor chips, which develop considerable heat during normal operation. In one current practice, these chips are mounted within an IC package using a flip chip format. During high power operation, the heat generated by the flip chip IC is dissipated through the package's solder joints to the main circuit board as well as through the package's lid.

In addition to ICs, other electronic components such as optoelectronic communication devices (e.g., transceivers) and displays (e.g., vacuum fluorescent displays) suffer from similar heat sensitivity during various processing stages. Specifically, optoelectronic communication devices are currently considered stable up to temperatures of about 80° C. to 90° C., while vacuum fluorescent displays must be assembled using selective soldering techniques because of their thermal instability. As with ICs, some method of heat dissipation is required to maintain the integrity of these electronic components during processing and in-service use.

Thermal dissipation devices are commonly used to keep electronic components stable during high temperature, in-service operation. These devices are in thermal communication with the component and generally employ conduction, convection, or a combination thereof to dissipate heat energy. Heat sinks in particular are common thermal dissipation devices for in-service operation. A heat sink is typically a mass of material that is thermally coupled to one of the electronic component's heat-conducting features, e.g., the package lid of an IC, with thermal grease or adhesive. Heat sinks rely on conduction to draw heat energy away from a high-temperature region toward the heat sink. The heat energy is then dissipated from the heat sink's surface to the atmosphere by convection.

A heat sink's thermal efficiency can be increased by forcing convection with an air stream over the surface, usually with a fan, or, in more advanced applications, by using a liquid to absorb heat from the heat sink. However, the efficiency of a heat sink is necessarily limited by the surface area of the heat sink, i.e., its convecting surface area. Further, while heat sinks have been utilized to dissipate heat during in-service operation, they have not been employed to address heat dissipation needs during elevated processing temperatures.

Reflective heat shields in the form of a metal cap or fiberboard masks have been used to try to protect electronic components during processing. However, these devices act only to shield the covered area from receiving the full impact of the ambient heat, rather than actually acting to help extract heat from the electronic component. As one consequence, these devices provide no protection to infrared heat. If there existed a method of extracting thermal energy from the electronic component during elevated temperature processing stages, the stability of heat sensitive components would accordingly be enhanced.

### SUMMARY

In accordance with a first aspect, a cooling device for cooling heat sensitive features or heat sensitive materials is provided. In certain examples, the cooling device is configured to provide thermal protection to heat sensitive features or heat sensitive materials to prevent destruction or damage to the heat sensitive features or heat sensitive materials during exposure to high temperatures or to a high temperature processing step, for example. Examples of the cooling devices disclosed here provide a significant technological advance to protect heat sensitive features or heat sensitive materials during storage and/or processing of such features and materials.

In accordance with a second aspect, a cooling device comprising a cooling device body is disclosed. In certain examples, the cooling device body, or a portion thereof, is in thermal communication with a heat sensitive component, e.g., a printed circuit board, a semiconductor wafer, and/or the components thereof. The cooling device body can be constructed of suitable materials such that thermal transfer may occur from the heat sensitive component to the cooling device body. In certain examples, the cooling device body includes metal, glass, ceramics, inorganic solids and/or one or more polymers. The cooling device body may also be constructed in the form of suitable shapes or molds such that heat transfer from the heat sensitive component to the cooling device body is maximized. Exemplary materials, shapes and molds for the cooling device body are discussed in more detail below. In certain examples, the cooling device body can be placed on top of a heat sensitive component, can be molded around a heat sensitive component or can be molded underneath a heat sensitive component. In some examples, the cooling device is placed or molded to the heat sensitive component during assembly of a larger electronic component, e.g., during assembly of a printed circuit board. Such placement can be performed using suitable methods including, but not limited to, automated pick and place equipment and the like.

In accordance with an additional aspect, a cooling device comprising at least one cooling medium is provided. In certain examples, the cooling device can be configured to provide thermal protection to heat sensitive components, e.g., printed circuit boards, semiconductor wafers, and/or the components thereof. In certain other examples, the cooling medium can absorb or dissipate heat transferred from the heat sensitive component or can prevent heat from adversely affecting the operation of the heat sensitive component. In some examples, the cooling medium is selected such that it undergoes an endothermic process, e.g., an endothermic phase change, an endothermic reaction, an endothermic rearrangement, etc., so that the temperature differential between a heat sensitive component and the cooling device is increased. In selected examples, a cooling medium with high heat capacity is used such that the temperature change of the system, e.g., a heat sensitive component and cooling device, during one or more processing steps is substantially small with the majority of the heat being transferred to and/or absorbed by the cooling medium and/or the cooling device body of the cooling device. In certain examples, the cooling medium is disposed on or within a cooling device body which rests on or around the heat sensitive component, whereas in other examples the cooling medium may be disposed on or around a heat sensitive component and the cooling device body can be omitted. In yet other examples, the cooling medium is impregnated or coated onto the surface of the cooling device body, or the cooling device body itself may be constructed from the cooling media. Other possible and exemplary configurations for the cooling medium and/or cooling device body are discussed below.

In accordance with another aspect, a cooling device for cooling electronic components during a processing operation is disclosed. The cooling device comprises one or more indicators to provide a measure of hydration, flux content, temperature threshold, etc. In certain examples, the indicator changes color to indicate the temperature is above a certain threshold temperature, for example. In other examples, the indicator may degrade or deliquesce above a certain temperature. The indicator can be located on the cooling device body of the cooling device or can be in the cooling medium, or can be in both. The indicator may take numerous forms, e.g., solids, liquids, pastes, suspensions and the like. The indicator may also change from infrared translucent to infrared opaque, or vice versa, above a certain temperature such that the indicator can be optically monitored, for example. Other exemplary indicator materials for use with optical monitoring, e.g., UV opaque materials, UV translucent materials, etc., are discussed below.

In accordance with an additional aspect, a cooling device is provided that is configured to allow for selective heat adsorption, such as, for example, heat reflective or heat adsorbent patterns to create a particular temperature profile. In certain examples, the cooling device includes areas configured to enhance thermal transfer from a heat sensitive component to the cooling device and also includes areas configured to reduce or retard thermal transfer from a heat sensitive component to the cooling device. In certain examples, the cooling media is disposed on select areas of the cooling device and no cooling media is disposed in other areas of the device. Other suitable configurations and placement of the cooling devices disclosed here will be selected by the person of ordinary skill in the art, given the benefit of this disclosure.

In accordance with yet an additional aspect, a cooling medium for absorbing, extracting or removing heat from a heat sensitive component, e.g., an electrical component, is provided. In certain examples, the cooling medium is disposed directly on one or more electrical components. In certain other examples, the cooling medium is disposed on or in a sleeve, cup, basket, screen, film, mesh, scrim, etc. in such a manner that cooling media can be readily disposed on the heat sensitive component to allow heat transfer to the cooling medium. In yet other examples, the cooling medium is not in direct contact with the electronic component but is placed at a suitable position such that thermal transfer can occur from the electronic component to the cooling medium. In certain examples, a container or body comprising standoffs or projections is disposed on the heat sensitive component and the cooling medium is disposed within the container or body such that thermal transfer can occur from the heat sensitive component to the cooling medium. In certain other examples, the container or body contains two or more compartments with cooling media such that thermal transfer occurs to a higher degree at certain areas of the heat sensitive component than at other areas of the heat sensitive component. Other exemplary devices for use with the cooling medium and cooling devices disclosed here are discussed below and additional devices for use with the illustrative cooling media and illustrative cooling devices disclosed here will be recognized by the person of ordinary skill in the art, given the benefit of this disclosure. In certain examples, a cooling device is disclosed comprising cut-outs, holes, stand-offs, etc. to accommodate parts of components requiring higher temperatures or parts of components that can withstand higher temperatures. For example, certain areas of an electronic component may not be heat sensitive, whereas other areas of the electronic component may be heat sensitive.

In accordance with yet an additional aspect, a cooling device that is operative as a heat sink is provided. In some examples, the cooling device is operative to cool a heat sensitive component during processing of the component and remains operative as a heat sink after final assembly of a larger electronic device, e.g., a printed circuit board, in which the heat sensitive component is used. The cooling device may optionally include a fan or additional cooling apparatus, such as, for example, a Peltier cooler, to dissipate heat from the cooling device during operation of the larger electronic device. It will be within the ability of the person of ordinary skill in the art, given the benefit of this disclosure, to design suitable cooling devices that are operative as heat sinks.

In accordance with another aspect, a cooling device is provided that is in thermal communication with an entire surface of an electronic component, e.g., a printed circuit board, semiconductor wafer, etc. The cooling device can be configured such that it includes areas with disposed cooling media and/or cooling device bodies which come into thermal communication with heat sensitive components on the surface of the electronic component. Exemplary materials for use in constructing board sized cooling devices are discussed below.

In accordance with other aspects, the cooling device can be strengthened or reinforced with suitable materials such as, for example, steel wires, fibers, meshes, screens, etc. The steel wires, fibers, meshes, screens, and the like can be included in the cooling device body, can be disposed within the cooling medium or can be arranged in other suitable configurations to strengthen or reinforce the cooling devices disclosed here.

In accordance with an additional aspect, a cooling device is provided that is operative to extract or remove heat from an electronic component during exposure of the component to a process temperature between about 100° C. and about 300° C., for example, during a processing operation, such as manufacture, repair, or reflow of the electrical component. The cooling device may take numerous shapes and forms, and, in certain examples, the cooling device comprises a body and a cooling medium disposed on or within the body. In some examples, the cooling medium is capable of undergoing an endothermic process, e.g., an endothermic reaction, an endothermic phase change or an endothermic rearrangement, at or around the processing temperature, which allows for the absorption of heat resulting from the processing operation.

In accordance with another aspect, a cooling device comprising two or more stackable units is provided. In certain examples, the stackable units are configured such that stacking more units together increases heat transfer between the heat sensitive material or the heat sensitive component and the stacked units. Exemplary configurations using stackable units are described below.

In accordance with yet another aspect, a cooling device comprising a conformable material is disclosed. In certain examples, the conformable material takes the form or a moldable or compliant foam or sponge, e.g., heat-moldable foams, visco-elastic foams, froth foams, thermoplastic foams and the like. In certain other examples, the conformable material comprises one or more foam materials that is organic based, silicone based, inorganic based, or combinations or mixtures thereof. In other examples, the conformable materials are selected from lyosols, aerosols, hydrosols, organosols, lyogels, aerogels, hydrogels, organogels, resins and the like. Other exemplary conformable materials are discussed below. In some examples, the conformable material may be positioned in a cooling device body which itself is in thermal communication with a heat sensitive material or a heat sensitive component, whereas in other examples the conformable material is placed in contact with the heat sensitive material and a cooling device body, and optionally a cooling medium, may be positioned in contact with the conformable material. Other suitable arrangements and configurations will be recognized by the person of ordinary skill in the art, given the benefit of this disclosure, and exemplary configurations and arrangements are discussed in detail below.

In accordance with another aspect, a cooling device that includes one or more coatings is disclosed. In certain examples, the coating is disposed on one or more surfaces of the cooling device using suitable coating techniques, e.g. brushing, sputtering, vapor deposition, etc., that will be readily selected by the person of ordinary skill in the art, given the benefit of this disclosure. The coating may take numerous forms and compositions depending on the intended effect of the coating. In certain examples, the coating includes at least one metal, metal compound or an oxide of a metal or metal compound. In some examples, the coating is reflective and/or conductive. The coating may include a single layer, e.g., a monolayer, or may include a plurality of layers, where each layer may be the same or different, disposed on each other. Exemplary coatings are discussed below and additional suitable coatings will be selected by the person of ordinary skill in the art, given the benefit of this disclosure.

In accordance with a method aspect, a method for cooling an electronic component during a processing operation is provided. In certain examples, the method can be used to keep the temperature of the electronic component substantially constant during the processing operation. The method includes bringing a cooling device into thermal communication with an electronic component, performing one or more processing operations on the electronic component, and optionally removing the cooling device post-processing. During the processing operation, the cooling device is configured to remove, absorb or dissipate heat that results from the processing operation. Such heat removal can prevent destruction of or damage to the electronic component or features of the electronic component.

In accordance with another method aspect, a cooling device configured to cool an electronic component during an elevated temperature operation during manufacture, repair, or rework is disclosed. The method includes bringing a cooling device into thermal communication with the electronic component, subjecting the electronic component to the elevated temperature operation during which the cooling device cools the electronic component by way of an endothermic process. The endothermic process can increase the temperature differential between the electronic component and the cooling device to assist in transfer of heat from the electronic component to the cooling device.

In accordance with an additional aspect, a cooling device for cooling heat sensitive features or heat sensitive materials is provided. In certain examples, the cooling device includes a cooling device body adapted to thermally protect an electronic component. In certain examples, the cooling device comprises a void constructed and arranged to allow heat to enter the device to provide heat to components underneath and/or near the void. In other examples, the cooling device comprises a void constructed and arranged to allow heat to escape from areas underlying or near the void. The exact shape, dimensions, etc. of the void can vary and in certain examples, the void is circular, oval, rectangular, rhomboidal, hexagonal, octahedral, etc. In other examples, the cooling device also includes a cooling medium disposed on or within the cooling device body, wherein the cooling device is constructed and arranged to cool an electronic component during exposure of the electronic component to a process temperature between about 100° C. and 300° C. during a processing operation.

In accordance with another aspect, a cooling device comprising a cooling device body that includes a plurality of voids is disclosed. In certain examples, each of the voids is configured to allow heat to enter in areas in or near the voids or to allow heat in or near the voids to escape. In some examples, the voids or holes are perpendicular to the surface of the component to be cooled. In other examples, at least some portion of the void or hole is non-perpendicular to the surface to be cooled. In some examples, the voids are partially or completely filled with a cooling medium. In yet other examples, the voids are partially obstructed to reduce the amount of heat that can enter, or escape as the case may be, the cooling device.

In accordance with another aspect, a cooling device comprising tape optionally with cooling medium disposed on the tape is disclosed. In certain examples the tape is constructed and arranged to cool an electronic component during exposure of the electronic component to a process temperature between about 100° C. and 300° C. during a processing operation. In some examples, the cooling medium is sprayed, rolled or coated onto the tape prior to placement of the tape on the device to be cooled. Cooling devices comprising tape may be especially useful for use in automated placement of the cooling devices, using, for example, pick and place equipment.

In accordance with yet an additional aspect, a cooling device comprising a conforming cooling device body is disclosed. In certain examples, the cooling device is constructed by stamping a metal sheet, perforated metal sheet, or metal screen to form a conforming cap or ring. In some examples, the cooling device may be coated with or dipped into one or more cooling media to provide additional cooling for an electronic component exposed to a process temperature.

In accordance with an additional aspect, a cooling device comprising a polymeric cooling device body is disclosed. In certain examples, the polymeric cooling device body is constructed and arranged to cool an electronic component during exposure of the electronic component to a process temperature between about 100° C. and 300° C. during a processing operation. In some examples, the polymeric cooling device body is coated, or partially coated, with one or more cooling media, and/or an infrared or heat reflective medium, to provide additional cooling control. In other examples, the polymeric cooling device body includes tape disposed on the polymeric cooling device body. In some examples, the polymeric cooling device body includes one or more voids to allow a portion of localized heat to pass through. In some examples, the voids are filled, or partially filled, with one or more cooling media to provide additional cooling control.

In accordance with yet another aspect, a cooling device body fabricated from stamped metal is constructed and arranged to cool an electronic component during exposure of the electronic component to a process temperature between about 100° C. and 300° C. during a processing operation. In certain examples, the stamped metal is coated, or partially coated, with one or more cooling media to provide additional cooling control, and may also include voids, perforations or the like.

In accordance with yet another aspect, a cooling device comprising a cooling device body that includes one or more valves is disclosed. In certain examples, at least one valve is constructed and arranged to actuate in response to exposure of an electronic component to a process temperature between about 100° C. and 300° C. during a processing operation. In some examples, the valve actuates in response to pressure or temperature. In certain examples, the valve is passive in that the valve operates at a certain temperature, whereas in other examples, the valve is active.

In accordance with another aspect, a cooling device comprising a mold compound body is disclosed. In certain examples, the mold compound provides increased thermal mass to particular areas of an electronic component to provide additional cooling to those areas. In some examples, the cooling device body includes tape disposed on the mold compound. In other examples, the mold compound may include depressions, dimples or the like that are configured to receive a fluid or cooling medium to enhance cooling.

In accordance with an additional aspect, a cooling device comprising heat reflective materials is provided. In certain examples, at least one area of the cooling device includes a heat or infrared reflective material configured to reflect or direct heat to certain regions of an electronic component, e.g., regions of an electronic component that include solder spheres. In some examples, the entire cooling device body is heat or infrared reflective and one or more cooling media are disposed on certain areas of the cooling device body to minimize reflection of heat. Other exemplary configurations are discussed below.

In accordance with an additional aspect, a cooling device configured for surface mount applications is provided. In certain examples, the cooling device is configured to be in thermal communication with exposed surfaces of an electronic component. In some examples, the cooling device is permanently or removably mounted to a surface of an electronic component and is configured suitably to provide thermal protection to substantially all exposed surfaces of the electronic component. In certain examples, the cooling device includes a cooling device body that contacts exposed surfaces of an electronic component, whereas in other examples the cooling device body is not in direct contact with exposed surfaces of the electronic component but is still configured to provide thermal protection to the electronic component. In yet other examples, the cooling device includes one or more cooling media, tape or the like disposed on the cooling device body, or other suitable devices and compositions disposed on the cooling device body to provide additional thermal protection to an electronic component.

In accordance with a method aspect, a method of cooling an electronic component is disclosed. The method includes selecting a cooling device constructed and arranged to cool an electronic component during a processing operation, and placing the selected cooling device on the electronic component after placement of the electronic component on a substrate. In certain examples, the cooling device comprises tape optionally with a cooling medium disposed on the tape.

In accordance with another method aspect, a method of placing an electronic component is provided. The method includes selecting a cooling device constructed and arranged to cool an electronic component during a processing operation, placing the selected cooling device on the electronic component, selecting the electronic component with the placed cooling device and placing the selected electronic component with the placed cooling device on a substrate.

In accordance with an additional aspect, an integral cooling device and electronic component, which may be used, for example, in an automated process, is disclosed. In certain examples, an integral cooling device and electronic component may be coplaced in the tape and reel and removed together for pick and place to an assembly site. In some examples, the cooling device is unitary with the electronic component, e.g., the electronic component may be manufactured with a cooling device on-board and the unitary device can be selected and placed using automated equipment, such as, for example, pick and place equipment.

It will be recognized by the person of ordinary skill in the art, given the benefit of this disclosure, that the cooling devices disclosed here provide significant benefits not achievable using prior existing technologies. Robust cooling devices can be configured to provide protective cooling to heat sensitive features and heat sensitive materials to minimize damage to such features and materials, which can increase overall efficiency of automated production of electronic components that include heat sensitive features and/or heat sensitive materials. These and other advantages, features, aspects and examples of the cooling devices disclosed here are discussed in detail below.

### BRIEF DESCRIPTION OF THE DRAWINGS

Certain examples are described below with reference to the accompanying drawings in which:

FIG. 1 is a first example of a cooling device, in accordance with certain examples;

FIG. 2 is another example of a cooling device, in accordance with certain examples;

FIG. 3 is an additional example of a cooling device, in accordance with certain examples;

FIG. 4 is an example of a cooling device including embossed areas, in accordance with certain examples;

FIG. 5 is an example of a cooling device with compartments and with embossed areas, in accordance with certain examples;

FIGS. 6A and 6B are examples showing the embossed patterns on a base of a cooling device, in accordance with certain examples;

FIG. 7 is an example of a cooling device with lugs, in accordance with certain examples;

FIG. 8 is another example of a cooling device with lugs, in accordance with certain examples;

FIGS. 9A and 9B are examples of stackable cooling devices, in accordance with certain examples;

FIG. 10 is a schematic illustration of a typical flip chip package prior to reflow processing, in accordance with certain examples;

FIG. 11 is a schematic illustration of a typical flip chip package with a cooling device placed on the package's lid, in accordance with certain examples;

FIGS. 12A-12D are examples of cooling devices configured in various manners, in accordance with certain examples;

FIGS. 13A-13C are illustrative schematics showing placement of a cooling device on an electronic component (FIGS. 13A and 13B) and also showing the use of an interstitial material between the cooling device and an electronic component (FIG. 13C), in accordance with certain examples;

FIG. 14 is a schematic illustration of a flip chip package with a heat sink attached to the lid, in accordance with certain examples;

FIGS. 15-19 are schematics of cooling devices with voids, in accordance with certain examples;

FIG. 20 is a side view of a cooling device with a void that penetrates the top surface of the cooling device body, in accordance with certain examples;

FIG. 21 is a side view of a cooling device with a fan disposed on the cooling device, in accordance with certain examples;

FIG. 22 is a perspective view of a cooling device that includes a plurality of voids, in accordance with certain examples;

FIG. 23 is a perspective view of a cooling device that includes two voids that span the width of the cooling device body, in accordance with certain examples;

FIG. 24 is a side section view through line X-X shown in FIG. 23, in accordance with certain examples;

FIG. 25 is a top view of an electronic component with a cooling device comprising tape disposed on the electronic component, in accordance with certain examples;

FIG. 26 is an example of a cooling device comprising a conforming cooling device body, in accordance with certain examples;

FIG. 27 is an example of a cooling device comprising a valve, in accordance with certain examples;

FIG. 28 is an example of a cooling device comprising a valve in electrical communication with a controller, in accordance with certain examples;

FIG. 29 is an example of a cooling device comprising a mold compound body disposed on an electronic component, in accordance with certain examples;

FIG. 30 is an example of a cooling device comprising a mold compound body with tape disposed on the mold compound, in accordance with certain examples;

FIG. 31 is an example of a cooling device comprising a cooling device body with depressions, in accordance with certain examples;

FIG. 32 is a side view of an example of a cooling device comprising heat reflective material, in accordance with certain examples;

FIG. 33 is a top view of the cooling device of FIG. 32, in accordance with certain examples;

FIG. 34 is an example of a cooling device comprising a heat reflective cooling device body which includes heat absorptive regions, in accordance with certain examples;

FIG. 35 is an example of a cooling device comprising a variable thickness cooling device body, in accordance with certain examples;

FIG. 36 is example of a cooling device integral with an electronic component, in accordance with certain examples;

FIG. 37 is an example of a cooling device configured to provide thermal protection to the perimeter of an electronic component, in accordance with certain examples.

FIGS. 38-43 are graphs of data for Example 1, representing the data collected by T1 and T2 during reflow at a peak temperature of 125° C., in accordance with certain examples;

FIGS. 44-49 are graphs of data for Example 2, representing the data collected by T1 and T2 during reflow at a peak temperature of 220° C., in accordance with certain examples; and

FIGS. 50-55 are graphs of data for Example 3, representing the data collected by T1 and T2 during reflow at a peak temperature of 260° C., in accordance with certain examples.

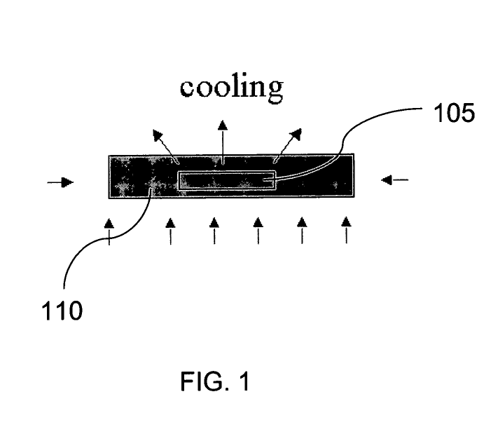

It will be apparent to the person of ordinary skill in the art, given the benefit of this disclosure, that the exemplary electronic components, cooling devices, cooling media, etc., shown in FIGS. 1-37 are not necessarily to scale. Certain dimensions, such as the thickness of the cooling device body or cooling medium, may have been enlarged relative to other dimensions, such as the thickness of the heat sensitive component, for clarity of illustration and for a more user-friendly description of the illustrative examples discussed below. It will also be understood by the person of ordinary skill in the art, given the benefit of this disclosure, that the cooling devices disclosed here can be used generally in any orientation relative to gravity and/or other components to which they might be disposed on or be in thermal communication.

### DETAILED DESCRIPTION OF CERTAIN EXAMPLES

It will be recognized by the person of ordinary skill in the art, given the benefit of this disclosure, that the cooling devices disclosed here represent a significant commercial development. Cooling devices can be constructed and assembled to provide thermal protection to minimize damage to heat sensitive materials and heat sensitive components. Such cooling devices allow the use of high temperature processing steps without undesirable side effects, such as heat damage to a heat sensitive component, for example.

In accordance with certain examples, a cooling device for cooling heat sensitive features or heat sensitive materials is provided. As used here, “heat sensitive feature” refers to an electrical device, or component thereof, whose performance degrades after exposure to high temperature, such as temperatures at or above those temperatures commonly used in electronic processing operations. It should be noted that the heat sensitive feature is not necessarily physically destroyed or damaged by the temperatures of the processing operation, but some aspect of the performance, e.g., operation or function, of the heat sensitive feature can be adversely affected or altered by exposure to the high temperature. As used here “heat sensitive component” is an electronic component or device of a larger electronic device, e.g., a semi-conductor chip of a printed circuit board. As used here “heat sensitive materials” refers to compounds and compositions that are subject to degradation or an undesirable change(s) in physical, chemical or physicochemical properties when subjected to high temperature, e.g., a temperature above about 100° C., 200° C. or 300° C. Certain examples of the cooling device disclosed here are configured to provide thermal protection to heat sensitive features or heat sensitive materials to prevent destruction or damage to the heat sensitive features or heat sensitive materials during exposure to high temperatures or to one or more high temperature processing steps, for example. It will be understood by the person of ordinary skill in the art, given the benefit of this disclosure, that thermal protection does not require that the heat sensitive feature or heat sensitive material remain at a substantially constant temperature during the heat processing, but rather, thermal protection is accomplished as long as the temperature of the heat sensitive material or heat sensitive feature is maintained below a threshold temperature value. The exact threshold temperature value will depend on the nature and properties of heat sensitive material and/or the heat sensitive feature, and exemplary threshold temperature values include temperatures of about 75° C. to about 150° C. for electronic components used on printed circuit boards and about 75° C. to about 150° C. for semiconductor wafers. The person of ordinary skill in the art, given the benefit of this disclosure, will be able to select, determine and/or recognize suitable threshold temperature values for a given heat sensitive material or a given heat sensitive feature.

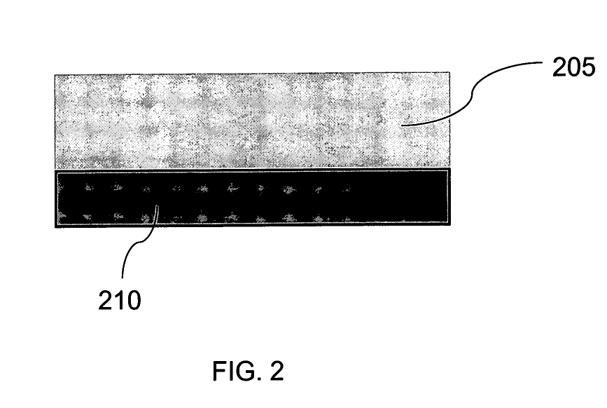

In accordance with certain examples, a cooling device comprising a cooling device body is disclosed. The cooling device body is positioned such that it is in thermal communication with a heat sensitive material or heat sensitive component. Such thermal communication can be accomplished using numerous methods including, but not limited to, placing the cooling device body directly onto the heat sensitive material or heat sensitive component, placing the cooling device body a suitable distance from the heat sensitive material or heat sensitive component while maintaining heat transfer between the heat sensitive material or the heat sensitive component, etc. For example, referring to FIG. 1, cooling device body 105 is in thermal communication with heat sensitive component 110. Cooling device body 105 is operative to cool heat sensitive component 110 during thermal processing. In the arrangement shown in FIG. 1, cooling device body is in thermal communication with the top surface of heat sensitive component 110. Heat sensitive component 110 can be an entire device or a heat sensitive component of the entire device. In certain examples discussed below, the cooling device body may include a cooling medium, such as cooling medium 205 shown in FIG. 2. Cooling medium 205 is typically disposed in or on the cooling device body, which is in thermal communication with a heat sensitive component, such as heat sensitive component 210, which can be an entire device or a heat sensitive component of the entire device. Other exemplary configurations for the cooling device body, cooling medium and heat sensitive components are discussed below.

In accordance with certain examples, the cooling device body can be constructed from suitable materials that can rapidly absorb heat from the heat sensitive component or material. In certain examples, the cooling device body includes pores or through holes to provide fluid communication throughout the body. The pores or holes may take any shape or form including circular, ovoid, trapezoidal, rectangular and may be formed, for example, as a result of adoption of a crystal structure by the material used to construct the cooling device body. In certain examples, the materials used to construct the cooling device body may have a unit cell structure that is hexagonally closed packed, cubic close packed, face-centered cubic, body-centered cubic, primitive cubic, etc., and holes, e.g., tetrahedral holes, octahedral holes, and the like, may result because of the adoption of such unit cell structure by the material. In some examples, the pores have a mean diameter between about 10 um to about 100 um. In addition, the materials may include a bimodal or other complex pore structure so that pore size can be selected or optimized to control the rate of water evaporation. For example, the material can include a primary pore size of about 100 microns, which can result in rapid evaporation of water, and a second pore size of about 1 micron, which can result in slow evaporation of water, in order to customize the evaporation rate and/or provide additional control over the cooling of a heat sensitive feature or a heat sensitive material.

In accordance with certain examples, the exact composition of the cooling device body can vary depending on numerous factors, for example, the desired amount of heat to be transferred from the heat sensitive material or heat sensitive component to the cooling device body. In certain examples, the cooling device body is constructed from materials having high heat capacities or high thermal transfer coefficients such that the maximum amount of heat is transferred from the heat sensitive material or heat sensitive component to the cooling device body. For example, in certain applications, the cooling device body is constructed from one or more materials having a heat capacity of at least about 28-30 cal/deg-mol at 25° C., more particularly at least about 40-42 cal/deg-mol at 25° C., for example at least about 50, 75 or 100 cal/deg-mol at 25° C. In certain examples, the cooling device body can be constructed using one or more inorganic salts or inorganic solids, such as calcium sulfate dihydrate (gypsum) or calcium sulfate hemihydrate (Plaster of Paris). Without wishing to be bound by any particular scientific theory, in the presence of water calcium sulfate hemihydrate can be converted into calcium sulfate dihydrate. This reaction is reversible and the calcium sulfate dihydrate can be reconverted into calcium sulfate hemihydrate by application of heat. Gypsum and Plaster of Paris are available commercially from numerous manufacturers such as U.S. Gypsum, Inc. (Chicago, Ill.), for example. In other examples, the cooling device body can be constructed from one or more suitable inorganic or organic materials including, but not limited to: Al₂O₃.H₂O, Al₂O₃.3H₂O, Al₂SO₄, Al₂SO₄.6H₂O, Al(NO₃)₃.6H₂O, NH₄Al(SO₄)₂.12H₂O, Al₆Si₂O₁₃, Ba(BrO₃).2H₂O, Ba(IO₃)₂, Ba(NO₃)₂, BaO.2SiO₂, 2BaO.SiO₂, 2BaO.3SiO₂, BaCrO₄, Bi₂(SO₄)₃, B(C₂H₅)₃, B(OCH₃)₃, HBrO₃, Ca(PO₃)₂, Ca₂P₂O₇, Ca₃(PO₄)₂, CaHPO₄.2H₂O, Ca(H₂PO₄).H₂O, CaC₂O₄.H₂O, 2CaO.SiO₂, CaO.Al₂O₃, CaO.2Al₂O₃, 2CaO.Al₂O₃, 3 CaO.Al₂O₃, CaO.Al₂O₃.2 SiO₂, CaO.Fe₂O₃, 2CaO.5MgO.8SiO₂.H₂O, CCl₄, CBr₄, NH₄CN, CH₃NO₃, CH₃COOH, CH₃COO—, CH₂ClCH₂Cl, CCl₃CHO, CCl₃CH(OH)₂, CF₂ClCFCl₂, CH₂BrCH₂Br, (CH₃)₂SO, C₂H₅NO₂, CH₃CH₂ONO₂, (NH₄)₂C₂O₄, CH₃N, Ce₂(SO₄)₃.5H₂O, Cs₂SO₄, Cs₂Cr₂O₇, Cs₂UO₄, Cr₂(SO₄)₃, Cr₇C₃, Cr₂₃C₆, Ag₂CrO₄, CoSO₄.6H₂O, CoSO₄.7H₂O, [Co(NH₃)₆]Br₃, CuSO₄.3H₂O, CuSO₄.5H₂O, DyCl₃.6H₂O, ErCl₃.6H₂O, EuCl₃.6H₂O, Eu₂(SO₄).8H₂O, GdCl₃.6H₂O, Gd₂(SO₄).8H₂O, Gd(NO₃).6H₂O, HoCl₃.6H₂O, Fe₃O₄, FeSO₄.7H₂O, LaCl₃.7H₂O, La₂(SO₄)₃.9H₂O, LiSO₄.H₂O, Li₂SO₄.D₂O, LuCl₃.6H₂O, MgCl₂.2H₂O, MgCl₂.4H₂O, MgCl₂.6H₂O, MgSO₄.6H₂O, Mg₂P₂O₇, Mg₃(PO₄)₂, Mg₃Si₂O₅(OH)₄, Mg₃Si₄O₁₀(OH)₂, Mg₂Al₄Si₅O₁₈, MgV₂O₆, MgV₂O₇, Mg₂TiO₄, MgUO₄, MgU₃O₁₀, Mn₃O₄, MnSO₄.5H₂O, Hg₂SO₄, MoF₆, Mo(CO)₆, FeMoO₄, NdCl₃.6H₂O, Nd₂(SO₄)₃.8H₂O, Nd₂Se₃, NiSO₄, NiSO₄.6H₂O, NiSO₄.7H₂O, Ni(NO₃)₂.6H₂O, NiCO₃, Ni(CO)₄, Nb₂O₅, NbF₅, NbCl₅, N₂O₃, NH₄OH, NH₄NO₃, (NH₄)₂O, P₄O₁₀, KClO₄, KBrO, KBrO₃, KBrO₄, K₂SO₄, KH₂AsO₄, KAl(SO₄)₂, KAl(SO₄)₂.12H₂O, K₄Fe(CN)₆, C₂Cr₂O₇, Rb₂SO₄, Sm₂O₃, SmCl₃.6H₂O, Sc₂(SO₄)₃, Sc(HCO₂)₃, Sc₂(C₂O₄)₃, Ag₂SO₄, Na₂SO₄, Na₃PO₄, (NaPO₃)₃, Na₄P₂O₇, Na₅P₃O₁₀, Na₂HPO₄, Na₂H₂P₂O₇, Na₂CO₃.H₂O, Na₂CO₃.10H₂O, Na₂C₂O₄, Na₂B₄O₇, Na₂B₄O₇.10H₂O, NaAlSi₂O₆, Na₂CrO₄, Na₂MoO₄, Na₂WO₄, Na₂VO₃, Na₄V₂O₇, Na₂Ti₂O₅, Na₂UO₄, SrCl₂.2H₂O, Sr(NO₃)₂, Sr₂SiO₄, Sr₂TiO₄, H₂SO₄.1H₂O, H₂SO₄.2H₂O, H₂SO₄.3H₂O, H₂SO₄.4H₂O, H₂SO₄.6.5H₂O, SOCl₂, SO₂Cl₂, Ta₂O₅, Tb₂O₃, Tm₂O₃, SnCl₂.2H₂O, TiCl₄, TiBr₄, TiI₂, W(CO)₆, Fe₇W₆, MnWO₄, V₂O₄, V₂O₅, ZnSO₄.6H₂O, ZnSO₄.7H₂O, Zn(NO₃)₂.6H₂O, Zn₂SiO₄, ZrCl₄, and Zr(SO₄)₂. Other suitable materials can be found in the National Bureau of Standards Technical Notes 270-3, 270-4, 270-5, 270-6, 270-7 and 270-8, for example and additional suitable materials for use in the cooling device body will be selected by the person of ordinary skill in the art, given the benefit of this disclosure. The materials listed above can obtained from suitable chemical companies such as, for example, Sigma-Aldrich, Mallinckrodt Chemicals and the like. In some examples, the material is selected from one or more of the hydrated materials listed above, e.g., the materials listed above that include coordinated water molecules. In certain other examples, the material is one or more hydrated, or partially hydrated, deuterated (²H), or partially deuterated, or tritiated (³H), or partially tritiated, metal sulfate compounds, such as those metal sulfate compounds listed above. In certain examples, the materials listed above may be mixed with fillers, solid particles and the like to provide the final cooling device body structure. For example, where the material is liquid at the operating temperature, the material can be mixed with suitable fillers or solid particles to provide a solid structure. The inorganic materials may also take numerous crystal forms, e.g., hexagonal, monoclinic, triclinic, etc. It will be recognized by the person of ordinary skill in the art, given the benefit of this disclosure, that certain materials listed above may have a limited temperature range. For example, certain materials may have boiling points around 100° C., for example, and are suitable for use at processing temperatures around 100° C., whereas the materials may not provide optimal cooling at processing temperatures above 200° C., for example. The person of ordinary skill in the art, given the benefit of this disclosure, will be able to select suitable materials depending on the intended use of the cooling device and on the temperature of the processing operation(s). In other examples, the materials may be mixed with one or more acids, bases, catalysts, etc. to promote, or deter, one or more chemical processes. For example, the materials can be mixed with a suitable reactant such that the material undergoes a synthesis reaction, a disproportionation reaction, an acid-base reaction, a dissolution reaction, an oxidation-reduction reaction, a decomposition reaction, etc. It will be within the ability of the person of ordinary skill in the art, given the benefit of this disclosure, to select suitable additional materials for including in the cooling device bodies disclosed here.

In accordance with certain other examples, the cooling device body can be constructed from one or more reticulated foams, such as the reticulated zirconia foam available commercially from Vesuvius Hi-Tech, Inc. (Alfred Station, N.Y.). Other exemplary suitable reticulated foams include PURIPORE reticulated foam available from Vitec Composite Systems (Manchester, England) and reticulated foams commercially available from Advanced Packaging Inc. (Baltimore, Md.). In some examples, the reticulated foams may be impregnated with or soaked in other suitable materials, such as those inorganic and organic materials listed herein. In certain other examples, the reticulated foam can be saturated with one or more cooling media as discussed herein. For example, the reticulated foam can be disposed in a suitable vessel and a cooling medium can be added to the vessel to allow the foam to soak up or take in the cooling medium. In some examples, the void volume of the foam is at least about 75%, more particularly about 85%, for example at least about 90%, 95% or about 98% void volume, such that large amounts of cooling media can enter into the pores of the foam. It will be within the ability of the person of ordinary skill in the art, given the benefit of this disclosure, to select suitable reticulated foams having suitable properties, such as void volume, for construction of the cooling devices disclosed here.

In accordance with yet other examples, the cooling device body can include glass, ceramics, fibers, whiskers, powders, platelets, screens, metal particles, carbon black particles, fillers, potting compounds, and other suitable materials that can absorb heat and/or can add strength or reinforcement to the cooling device body. In at least certain examples one or more of these additional materials are included in the cooling device body to provide structural reinforcement to the cooling device body. For example, carbon fibers can be added to the cooling device body to provide structural reinforcement while adding minimal additional weight to the cooling device body. Exemplary glass and glass particles include, but are not limited to, those derived from soda-lime glass, lead glass, borosilicate glass, aluminosilicate glass, 96% silica glass and fused silica glass. Exemplary ceramics include, but are not limited to, alumina based ceramics, aluminum nitride based ceramics, aluminum silicate based ceramics, braze alloys, glass ceramics, magnesium aluminum silicate based ceramics, magnesium oxide based ceramics, magnesium silicate based ceramics, silica based ceramics, silicon nitride based ceramics, and other ceramics commercially available from numerous manufacturers including but not limited to Morgan Advanced Ceramics (Fairfield, N.J.), Alcan Chemicals (Cleveland, Ohio), Kyocera Industrial Ceramics Corporation (Vancouver, Wash.), and other manufacturers of ceramic products. Exemplary fibers, platelets, whiskers and powders include, but are not limited to, those containing boron, carbon, cellulose, silicon carbide, silicon nitride, alumina, tantalum carbide, niobium carbide, and other transition metal carbides, carbonitrides, and nitrides. Exemplary screens include, but are not limited to, those commercially available from Universal Wire Cloth (Morrisville, Pa.), McNichols Co. (Westford, Mass.), Dorstener Wire Tech. (Spring, Tex.) and other manufacturers of wire screens and meshes. Exemplary metal particles include, but are not limited to, those containing titanium and titanium alloys, beryllium and beryllium alloys, magnesium and magnesium alloys, manganese and manganese alloys and other suitable metal and metal alloys. Exemplary fillers include, but are not limited to, carbon black, polyisoprene, dimethyl-methylvinyl polysiloxane, polybutadiene, silica, fly ash and the like. Exemplary potting compounds include, but are not limited to, epoxies, adhesives and the like, such as those available commercially from Cotronics Corp. (Brooklyn, N.Y.), Abatron, Inc. (Kenosha, Wis.) and 3M (St. Paul, Minn.). Other suitable materials for strengthening the cooling device body will be selected by the person of ordinary skill in the art, given the benefit of this disclosure.

In accordance with additional examples, one or more materials that can decrease the rigidity of the cooling device body can be included. For example, in certain applications, it may be necessary to bend, bow, or distort one or more surfaces of the cooling device body to provide optimal thermal transfer between the electronic component and the cooling device. Certain materials used in construction of the cooling device may be too rigid to bend, distort or bow or may break under the continuous force of being bent, distorted or bowed. In such applications, a material which decreases the rigidity of the cooling device body can be included such that the cooling device body may be distorted without risking failure to the cooling device body. Exemplary materials that can decrease the rigidity of the cooling device body include, but are not limited to, gels, foams, elastomers, flexible ceramics, and other compliant materials in particulate, fibrous, lamellar, monolithic or foamed form. Other suitable materials for decreasing the rigidity of the cooling device body will be selected by the person of ordinary skill in the art, given the benefit of this disclosure.

In accordance with certain examples, the cooling device can be held in place using suitable devices and materials. For example, the cooling device can be held to the heat sensitive component using thermal paste or grease. In other examples, the cooling device is held to the electronic component using a spring, clip, clamp, screw, bolt, single-sided adhesive tape, two-sided adhesive tape, tacky flux and related materials. It will be within the ability of the person of ordinary skill in the art, given the benefit of this disclosure, to select suitable devices and materials for keeping the cooling device in thermal communication with a heat sensitive component or a heat sensitive material.

In accordance with other examples, one or more interstitial or intervening materials can be placed between the cooling device body and the heat sensitive material or heat sensitive component to facilitate heat transfer. Suitable interstitial or intervening materials include, but are not limited to, thermal grease, thermal paste, flux, a thin layer of cooling medium, etc, and other materials that will be selected by the person of ordinary skill in the art, given the benefit of this disclosure, that can increase the rate of heat transfer from the heat sensitive material or heat sensitive component to the cooling device body. The interstitial or intervening materials can be disposed using suitable methods, such as brush application, spraying, sputter depositing, vapor deposition and the like, such that a sufficient amount of interstitial or intervening material is disposed on the cooling device body or a portion of the cooling device body.

In accordance with certain examples, the cooling device body may include fins, a fan or other device to facilitate heat transfer from the cooling device body to the surrounding environment. The cooling device body can have air holes, weep holes, through holes, etc. to allow for air circulation through the cooling device body. The cooling device body may take numerous forms and shapes depending, for example, on the shape of the heat sensitive component or the shape of the feature for which it is desirable to remove heat from or protect from high temperatures. In certain examples, the cooling device body includes at least one generally planar surface that can be placed on a surface of a heat sensitive component. In examples where the cooling device body includes a planar surface, the other portions of the cooling device body may be selected based on the intended use of the cooling device body and based on additional elements, e.g., cooling medium, to be used with the cooling device body. For example, the cooling device body may have sidewalls configured to retain a cooling medium that can be disposed within the interior of the cooling device body for increasing heat transfer from the heat sensitive component to the cooling device body. The planar surface of the cooling device body may contain open portions or voids if certain areas of the heat sensitive component are not heat sensitive and do not need to be kept cool during processing. In certain examples, the cooling device body has dimensions of about 10 mm to about 50 mm long by about 10 mm to about 50 mm wide and the thickness of the planar surface is about 1 mm to about 15 mm.

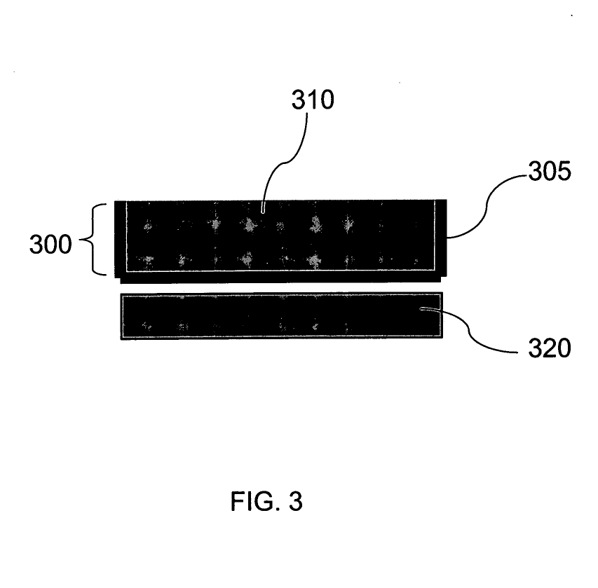

In accordance with certain examples, the cooling device body may take the form of a sleeve, cup, basket or other suitable shape that can retain a cooling medium, for example. Referring now to FIG. 3, cooling device 300 includes cooling device body 305, which is in the form of a thin conductive cup. Disposed within cooling device body is cooling medium 310, which can be one or more of the cooling media discussed herein. Cooling device body 305 can be constructed from suitable materials such as aluminum, copper, stainless steel, galvanized steel and the like. In certain examples, the material is selected such that it can be readily cast into the form of a thin conductive cup. Such casting simplifies preparation of the cooling device body and handling of the cooling device without unduly reducing the cooling effect. As shown in FIG. 3, cooling device body 305 can be placed in thermal communication with heat sensitive component 320 to provide thermal protection to heat sensitive component 320. Heat sensitive component 320 may be any one or more of the heat sensitive components discussed herein, e.g., semi-conductor wafers, printed circuit boards and the like.

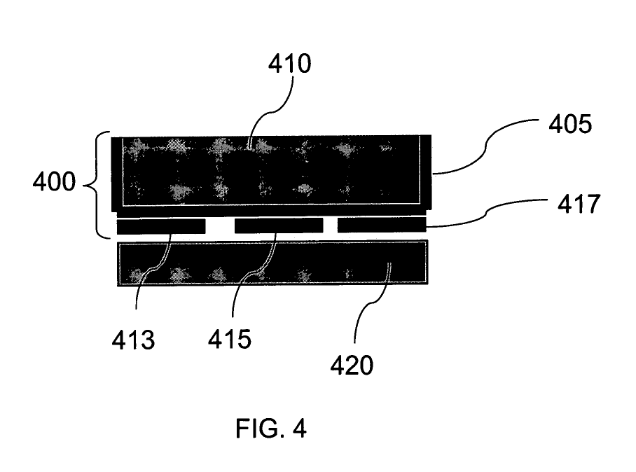

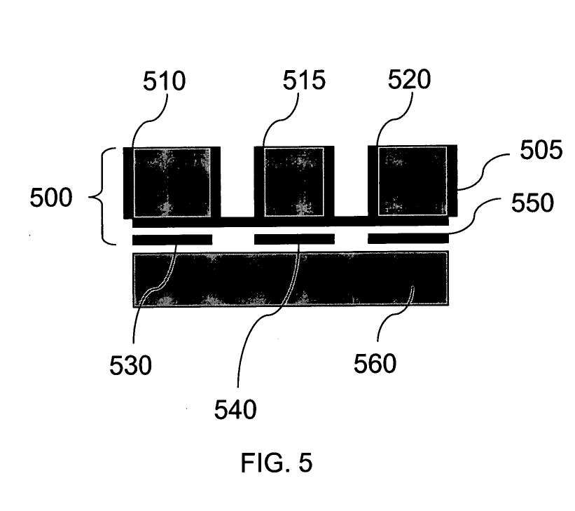

In accordance with certain examples, the base of cooling device body 305 can be embossed to direct the cooling effect to specific areas of the package to concentrate cooling effects in sensitive areas without applying uniform cooling that might distort the package through thermal expansion effects or prevent bottom-side formation of solder joints, for example. Referring now to FIG. 4, cooling device 400 includes cooling device body 405 that includes embossed areas 413, 415 and 417 (shown in exploded view from the cooling device body) each of which can be placed in thermal communication with an area of heat sensitive component 420. In addition, the cooling device body may be compartmentalized such that cooling media is disposed only in areas above or near the embossed areas. For example, referring now to FIG. 5, cooling device 500 includes cooling device body 505 that includes three compartments 510, 520 and 530, each with a cooling medium disposed in them. Cooling device 500 also includes embossed areas 530, 540 and 550 (shown exploded from the cooling device body), which can be brought into thermal communication with certain areas of heat sensitive component 560. Using the example shown in FIG. 5, lower amounts of cooling media can be used while still providing sufficient thermal protection to heat sensitive areas of a heat sensitive component.

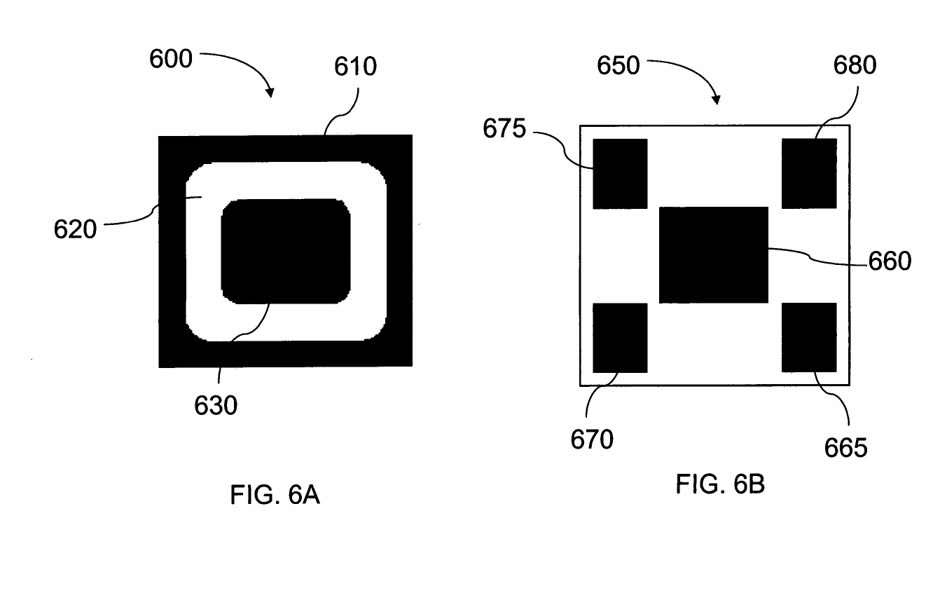

In accordance with certain examples, the exact shape and nature of the embossed areas can vary depending on the exact shape and nature of the heat sensitive areas to be protected. For example, referring now to FIG. 6A, the base of a cooling device with embossed areas is shown. Base 600 includes peripheral embossing area 610 and central embossing area 630 separated by a non-embossed area 620. A second example of a cooling device base is shown in FIG. 6B. Base 650 includes a central embossed area 660 and four peripheral rectangular embossed areas 665, 670, 675 and 680. The examples shown in FIGS. 6A and 6B are illustrative of only two of the many different embossing patterns that are possible. The person of ordinary skill in the art, given the benefit of this disclosure, will be able to design cooling device bases with a desired embossing pattern and/or embossing shapes suitable for providing thermal protection to selected areas of a heat sensitive component. In certain examples, the embossed areas are constructed from the same materials used to construct the cooling device body, whereas in other examples the embossed areas are constructed from a different material than the material used to construct the cooling device body. Typically, the embossed areas are constructed from one or more materials selected from aluminum, copper, stainless steel, galvanized steel and the like, though other suitable materials will be selected by the person of ordinary skill in the art, given the benefit of this disclosure.

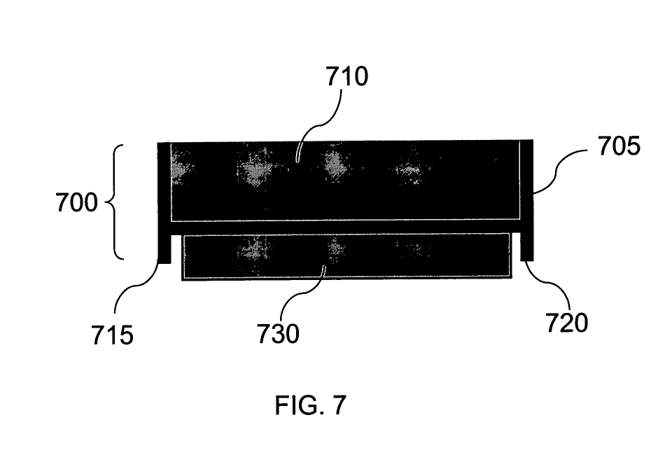

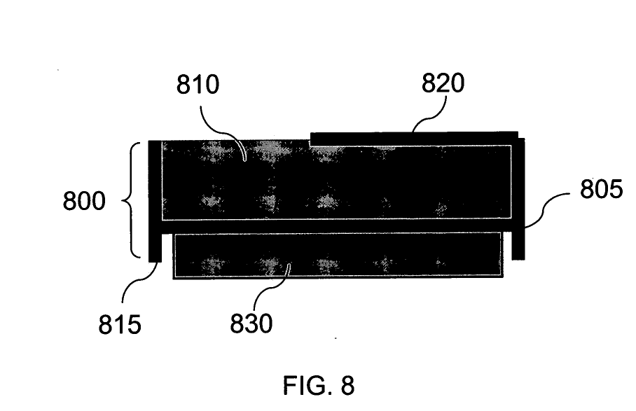

In accordance with additional examples, a cooling device comprising a cup-shaped support structure with embossing or lugs formed on the base of the cooling device body is provided. The embossing or lugs can act to secure or position the cooling device to the heat sensitive component or can assist in providing a snug fit of the cooling device to the heat sensitive component. For example, referring to FIG. 7, cooling device 700 includes support structure 705, cooling medium 710 and lugs 715 and 720. In the example shown in FIG. 7, lugs 715 and 720 are configured to provide sufficient space such that expansion of heat sensitive component 730 is permitted, e.g., expansion of heat sensitive component 730 is permitted during a high temperature processing operation. Referring now to FIG. 8, a second example of a cooling device with lugs is shown. Cooling device 800 includes a support structure 805, cooling medium 810 and lugs 815 and 820. Lug 820 is formed on a top surface of cooling device 800 to provide a site for pick and place vacuum equipment, which can permit automated placement on heat sensitive component 830 and can also provide automated removal of the cooling device. Suitable pick and place vacuum lifting equipment are commercially available from numerous manufacturers including, for example, Assembleon (Eindhoven, Netherlands), Automated Production Systems, Inc. (Huntingdon Valley, Pa.), Crux Engineering (Bainbridge Island, Wash.), Contact Systems, Inc. (Danbury, Conn.), Siemens Dematic (Alpharetta, Ga.), Universal Instruments (Binghamton, N.Y.) and other commercial suppliers of pick and place machines.

In accordance with yet other examples, the cooling device may include cut-outs, holes, stand-offs, etc. to accommodate parts that project upward from the surface of the heat sensitive component. For example, the surface of a heat sensitive electronic component may not necessarily be flat, but instead, can include peaks and valleys created by the different thicknesses of the areas of the heat sensitive components. The cooling devices disclosed here can be constructed with suitable projections and depressions to accommodate the variable thicknesses of different areas of the heat sensitive component. It will be within the ability of the person of ordinary skill in the art, given the benefit of this disclosure, to design and configure cooling devices suitable for use with heat sensitive components having non-flat surfaces.

In accordance with certain other examples, a cooling device that can be cast in a tape and reel pocket is provided. The cooling device may be any of the cooling devices disclosed here, and may include, for example, embossing areas, lugs, cooling media and the like. In certain examples, one or more cooling device bodies are cast in the tape and reel pocket. The cooling device body is allowed to dry at least sufficiently such that is can be loosened from the tape and reel pocket and automatically placed on a selected heat sensitive component. Such casting greatly simplifies the overall process and reduces costs associated with the overall process. In some examples, it may be necessary to include a tape that is flexible enough to release the caps, is heat resistant to withstand drying and/or is reasonably rigid so that the shape of the cooling device is not distorted beyond use. It will be within the ability of the person of ordinary skill in the art, given the benefit of this disclosure, to design and/or select suitable tape and reel pockets for casting the cooling devices disclosed here and for automated placement of the cooling devices disclosed here.

In accordance with some examples, the cooling device body can be molded around the heat sensitive component such that the cooling device body surrounds substantially all exposed surfaces of the heat sensitive component. For example, a moldable cooling device body can be disposed on a surface of a heat sensitive component and the shape or form of the cooling device body can be manually manipulated such that substantially all exposed surfaces of the heat sensitive component are surrounded by the cooling device body. Areas of the heat sensitive component that need to be exposed, e.g., those areas to be re-soldered, re-worked, re-flowed, etc., can be left exposed such that local areas of high temperature can be created.

In accordance with certain other examples, a cooling device comprising one or more indicators to provide a measure of hydration, flux content, temperature threshold, etc. is disclosed. In some examples, the indicator is a water soluble cobalt salt, such as cobalt chloride (CoCl₂). Without wishing to be bound by any particular scientific theory, cobalt chloride can take various hydrated and dehydrated forms that differ in color. For example, CoCl₄⁻² is blue in color, whereas Co(H₂O)₆⁺² is faint pinkish/red in color. At high temperatures, a solution of CoCl₂ turns blue due to the formation of CoCl₄⁻², whereas in the cold a solution of CoCl₂ is faint pink due to the presence of the Co(H₂O)₆⁺². Similarly, under conditions where the humidity is low, the cobalt indicator is blue, whereas under high humidity conditions, the cobalt indicator turns faint pink. Other water soluble forms of cobalt can also be used as an indicator such as, for example, cobalt sulfates, cobalt bromides, cobalt iodides, cobalt thiocyanates, and the like. In certain examples, the indicator changes color to indicate the temperature is above a certain threshold temperature, for example. In other examples, the indicator may degrade or deliquesce above a certain temperature. The indicator can be located on the cooling device body of the cooling device or can be in the cooling medium, or can be in both. The indicator may take numerous forms, e.g., solids, liquids, pastes, suspensions and the like. The indicator may also change from infrared translucent to infrared opaque, or vice versa, above a certain temperature such that the indicator can be optically monitored, for example. Other exemplary indicator materials can also be used, e.g., UV opaque materials, UV translucent materials, etc. In certain examples, a chemical reaction occurs such that the products are colored. For example, under appropriate temperature conditions, colorless reactants can react to form a colored product which can be used as an indicator that the temperature has exceeded a certain threshold value. In particular, reactants which are capable of undergoing an endothermic reaction to yield a colored product(s) are especially useful as indicators in the cooling devices disclosed here.

In accordance with certain examples, the cooling devices disclosed here can be configured with selective heat absorption and reflection profiles. For example, certain areas of the cooling device can include heat conductive areas, whereas other areas of the cooling device can include heat reflective areas. In certain examples, the heat conductive areas are placed in thermal communication with heat sensitive areas on electronic components. The heat reflective areas typically are positioned where it is unnecessary to cool those areas of the electronic component, or can be used to direct heat to specific areas, such as areas where flux or solder has been disposed. It will be within the ability of the person of ordinary skill in the art, given the benefit of this disclosure, to design suitable devices with heat sensitive and heat reflective areas suitable for an intended use.

In accordance with yet another aspect, a heat sink is disclosed that is operative as a cooling device. The heat sink may be placed in thermal communication with one or more heat sensitive electrical components to remove, extract or dissipate heat generated by the electrical component or to remove, extract or dissipate heat experienced by the electronic component during one or more processing operations. In certain examples, the heat sink remains in thermal communication with the electronic component even after the processing operation, whereas in other examples the heat sink is removed from the electronic component after the processing operation. In certain examples, the heat sink includes one or more cutouts to accommodate attached components. In other examples, the heat sink may be strengthened or reinforced with suitable materials such as, for example, steel wires, fibers, meshes, screens, etc.

In accordance with additional examples, a board sized cooling device configured to fit over, under or around an entire board is provided. The board sized cooling device can be prepared using suitable molds or casts such that the dimensions and thickness of the cooling device provides suitable thermal protection for those areas of a board that are heat sensitive. In certain examples, the board is about 12-16 inches wide, about 20-24 inches long and is about 0.25 to about 0.5 inches thick, though depending on the component thickness, the size of the board sized cooling device can vary. The board sized cooling device may be made from any of the materials listed herein, e.g., inorganic materials, etc. The cooling device can be fixed to the board using suitable materials such as, for example, adhesives, epoxies, silicones, and the like or using suitable mechanical fasteners such as, for example, screws, bolts, pop rivets, clips, clamps, springs and the like. In at least certain examples, the board sized cooling device is attached to the board using the existing fastener openings on the board. In other examples, one or more holes is drilled into the board for fastening the cooling device to the board. In yet other examples, the bottom of the surface is dipped into the materials used to construct the cooling device such that the cooling device forms on the undersurface of the board itself. Other suitable methods for constructing and attaching board sized cooling devices will be readily selected by the person of ordinary skill in the art, given the benefit of this disclosure.

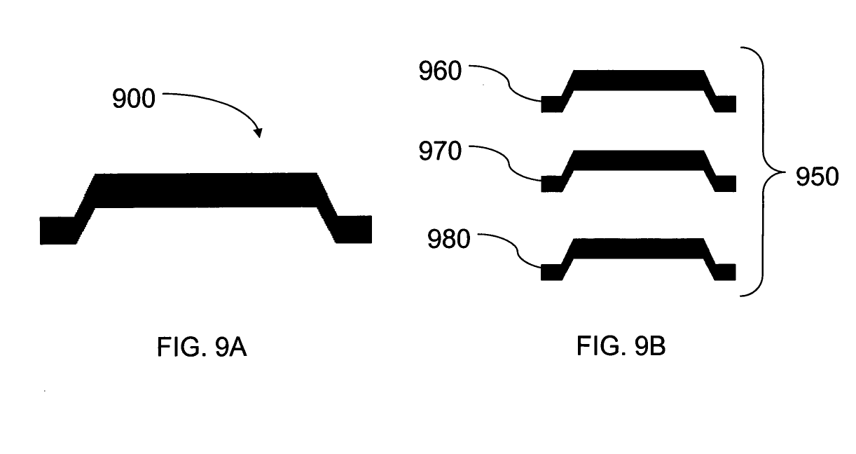

In accordance with certain examples, a cooling device comprising two or more stackable units is provided. The stackable units generally have a surface that can fit against a heat sensitive component. For example, referring to FIG. 9A, stackable cooling device 900 is shown. Cooling device 900 may be constructed from one or more of the materials discussed herein for use in constructing the cooling device body. In at least some examples, cooling device 900 may be stacked together to increase the amount of heat that can be absorbed from heat sensitive component. That is, in certain examples, the stackable units are configured such that stacking more units together increases heat transfer between the heat sensitive material or the heat sensitive component and the stacked cooling devices. For example, referring to FIG. 9B, stackable cooling devices 960, 970 and 980 can be stacked together to form cooling device 950. The exact dimensions and thicknesses of the stackable units can vary depending on the desired amount of cooling. For example, each stackable unit can be about 1 mm to about 5 mm thick and may have dimensions of about 1-7 cm wide, more particularly about 1-3 cm wide, and about 1-7 cm in length, more particularly about 1-3 cm in length. The person of ordinary skill in the art, given the benefit of this disclosure, will be able to design suitable cooling devices that include stackable cooling devices.

In accordance with certain other examples, a cooling device comprising a cooling medium is provided. The cooling medium is operative to enhance thermal transfer from the heat sensitive material or heat sensitive component to the cooling device body and/or the cooling medium. Without wishing to be bound by any particular scientific theory, the cooling medium can be selected such that it undergoes an endothermic reaction, endothermic phase change and/or endothermic rearrangement. In keeping with the traditional usage, the term endothermic refers to a process where heat is absorbed from the surroundings e.g., where the change in enthalpy is positive. For example, a cooling medium undergoing an endothermic phase change requires heat to achieve such phase change. Similarly, a cooling medium undergoing an endothermic reaction requires heat for the reactant to react and yield any product(s) or absorbs heat from the surrounding as the reaction proceeds. One example of an endothermic reaction is when solid ammonium nitrate (NH₄NO₃) is placed in water. Without wishing to be bound by any particular scientific theory, as the solid ammonium nitrate dissociates into ammonium ions and nitrate ions, the temperature of the solution decreases and creates a larger temperature differential between the surroundings than the temperature differential that existed between the surroundings and the solid ammonium nitrate. Another example of an endothermic reaction is when solid magnesium sulfate is placed in water to form magnesium ions and sulfate ions. Yet another example of an endothermic reaction is when sodium sulfate decahydrate (Na₂SO₄.10H₂O) reacts with sulfuric acid (H₂SO₄) to produce sodium bisulfate (NaHSO₄) and water. Without wishing to be bound by any particular scientific theory, the temperature of the solution can drop so rapidly that ice can form. An additional example of an endothermic reaction occurs when solid barium hydroxide octahydrate (Ba(OH)₂.8H₂O) reacts with ammonium nitrate (NH₄NO₃). Without wishing to be bound by any particular scientific theory, as the reaction proceeds due to a large increase in entropy as products are formed, the solution absorbs heat from the environment to produce barium nitrate and ammonia and the temperature drops to around about −20° C. to about −30° C. As an additional benefit, the produced ammonia can be monitored as an indicator that the cooling medium is reacting and the reactants have not all been exhausted. The resulting solid barium nitrate product can be removed using suitable techniques, such as compressed air, vacuuming and the like. Also, a cooling medium undergoing an endothermic rearrangement or an endothermic conversion can absorb heat as the crystal structure of the cooling medium is altered or as the number of waters of hydration are altered, for example. An exemplary cooling medium that can be used in the cooling device disclosed here is calcium sulfate hemihydrate (CaSO₄.½H₂O). Again without wishing to be bound by any particular scientific theory, as solid calcium sulfate hemihydrate is mixed with water, the solid calcium sulfate hemihydrate absorbs some of the water to form solid gypsum (CaSO₄.2H₂O). During this conversion, the temperature of the solution decreases creating a larger temperature differential between the solution and the surrounding environment. Other suitable materials include those materials that undergo an endothermic crystallization process in the presence of one or more suitable solvents, e.g., such as water.

In accordance with certain examples, a cooling medium with high heat capacity is used such that the temperature change of the system, e.g., a heat sensitive component and cooling device, during one or more processing steps is substantially small with the majority of the heat being transferred to and/or absorbed by the cooling medium and/or the cooling device body of the cooling device. As used here, the term heat capacity refers to the amount of heat required to change the temperature of the system by one degree. Materials with higher heat capacities can absorb more heat before any temperature change is observed. Materials having heat capacities of at least about 50 cal/deg-mol to at least about 100 cal/deg-mol at 25° C. are especially useful in the cooling devices disclosed here. In some examples, the material has an infinite heat capacity, e.g., is undergoing a phase change, at or near the processing temperature.

In certain examples, the cooling medium is an aqueous solution or suspension of one or more of the following inorganic or organic materials: Al₂O₃.H₂O, Al₂O₃.3H₂O, Al₂SO₄, Al₂SO₄.6H₂O, Al(NO₃)₃.6H₂O, NH₄Al(SO₄)₂.12H₂O, Al₆Si₂O₁₃, Ba(BrO₃).2H₂O, Ba(IO₃)₂, Ba(NO₃)₂, BaO.2SiO₂, 2BaO.SiO₂, 2BaO.3SiO₂, BaCrO₄, Bi₂(SO₄)₃, B(C₂H₅)₃, B(OCH₃)₃, HBrO₃, Ca(PO₃)₂, Ca₂P₂O₇, Ca₃(PO₄)₂, CaHPO₄.2H₂O, Ca(H₂PO₄).H₂O, CaC₂O₄.H₂O, 2CaO.SiO₂, CaO.Al₂O₃, CaO.2Al₂O₃, 2CaO.Al₂O₃, 3CaO.Al₂O₃, CaO.Al₂O₃.2SiO₂, CaO.Fe₂O₃, 2CaO.5MgO.8SiO₂.H₂O, CCl₄, CBr₄, NH₄CN, CH₃NO₃, CH₃COOH, CH₃COO—, CH₂ClCH₂Cl, CCl₃CHO, CCl₃CH(OH)₂, CF₂ClCFCl₂, CH₂BrCH₂Br, (CH₃)₂SO, C₂H₅NO₂, CH₃CH₂ONO₂, (NH₄)₂C₂O₄, CH₃N, Ce₂(SO₄)₃.5H₂O, Cs₂SO₄, Cs₂Cr₂O₇, Cs₂UO₄, Cr₂(SO₄)₃, Cr₇C₃, Cr₂₃C₆, Ag₂CrO₄, CoSO₄.6H₂O, CoSO₄.7H₂O, [Co(NH₃)₆]Br₃, CuSO₄.3H₂O, CuSO₄.5H₂O, DyCl₃.6H₂O, ErCl₃.6H₂O, EuCl₃.6H₂O, Eu₂(SO₄).8H₂O, GdCl₃.6H₂O, Gd₂(SO₄).8H₂O, Gd(NO₃).6H₂O, HoCl₃.6H₂O, Fe₃O₄, FeSO₄.7H₂O, LaCl₃.7H₂O, La₂(SO₄)₃.9H₂O, LiSO₄.H₂O, Li₂SO₄.D₂O, LuCl₃.6H₂O, MgCl₂.2H₂O, MgCl₂.4H₂O, MgCl₂.6H₂O, MgSO₄.6H₂O, Mg₂P₂O₇, Mg₃(PO₄)₂, Mg₃Si₂O₅(OH)₄, Mg₃Si₄O₁₀(OH)₂, Mg₂Al₄Si₅O₁₈, MgV₂O₆, MgV₂O₇, Mg₂TiO₄, MgUO₄, MgU₃O₁₀, Mn₃O₄, MnSO₄.5H₂O, Hg₂SO₄, MoF₆, Mo(CO)₆, FeMoO₄, NdCl₃.6H₂O, Nd₂(SO₄)₃.8H₂O, Nd₂Se₃, NiSO₄, NiSO₄.6H₂O, NiSO₄.7H₂O, Ni(NO₃)₂.6H₂O, NiCO₃, Ni(CO)₄, Nb₂O₅, NbF₅, NbCl₅, N₂O₃, NH₄OH, NH₄NO₃, (NH₄)₂O, P₄O₁₀, KClO₄, KBrO, KBrO₃, KBrO₄, K₂SO₄, KH₂AsO₄, KAl(SO₄)₂, KAl(SO₄)₂.12H₂O, K₄Fe(CN)₆, C₂Cr₂O₇, Rb₂SO₄, Sm₂O₃, SmCl₃.6H₂O, Sc₂(SO₄)₃, Sc(HCO₂)₃, Sc₂(C₂O₄)₃, Ag₂SO₄, Na₂SO₄, Na₃PO₄, (NaPO₃)₃, Na₄P₂O₇, Na₅P₃O₁₀, Na₂HPO₄, Na₂H₂P₂O₇, Na₂CO₃.H₂O, Na₂CO₃.10H₂O, Na₂C₂O₄, Na₂B₄O₇, Na₂B₄O₇.10H₂O, NaAlSi₂O₆, Na₂CrO₄, Na₂MoO₄, Na₂WO₄, Na₂VO₃, Na₄V₂O₇, Na₂Ti₂O₅, Na₂UO₄, SrCl₂.2H₂O, Sr(NO₃)₂, Sr₂SiO₄, Sr₂TiO₄, H₂SO₄.1H₂O, H₂SO₄.2H₂O, H₂SO₄.3H₂O, H₂SO₄.4H₂O, H₂SO₄.6.5H₂O, SOCl₂, SO₂Cl₂, Ta₂O₅, Tb₂O₃, Tm₂O₃, SnCl₂.2H₂O, TiCl₄, TiBr₄, TiI₂, W(CO)₆, Fe₇W₆, MnWO₄, V₂O₄, V₂O₅, ZnSO₄.6H₂O, ZnSO₄.7H₂O, Zn(NO₃)₂.6H₂O, Zn₂SiO₄, ZrCl₄, and Zr(SO₄)₂. Other suitable materials that can be used as or in the cooling medium can be found in the National Bureau of Standards Technical Notes 270-3, 270-4, 270-5, 270-6, 270-7 and 270-8, for example, and additional suitable materials for use in the cooling medium will be selected by the person of ordinary skill in the art, given the benefit of this disclosure. In other examples, the materials may be mixed with one or more acids, bases, catalysts, etc. to promote, or deter, one or more chemical processes. For example, the materials can be mixed with a suitable reactant such that the material undergoes a synthesis reaction, a disproportionation reaction, an acid-base reaction, a dissolution reaction, an oxidation-reduction reaction, a decomposition reaction, etc. It will be within the ability of the person of ordinary skill in the art, to select suitable additional materials for including in the cooling media disclosed here.

In accordance with certain examples, the cooling medium is disposed on or within a cooling device body which rests on or around the heat sensitive component, whereas in other examples the cooling medium may be disposed on or around a heat sensitive component and the cooling device body can be omitted. In yet other examples, the cooling medium is impregnated or coated onto the surface of the cooling device body, or the cooling device body itself may be constructed from the cooling media. Other possible and exemplary configurations for the cooling medium and/or cooling device body are discussed below.

In accordance with yet additional examples, one or more additional materials may be included in the cooling device body, the cooling medium or both that can absorb or scavenge water molecules to prevent damage to the electronic components. Without wishing to the bound by any particular scientific theory, when the cooling media undergoes an endothermic reaction or process, the temperature drop can be so great that solid water (ice) forms on the surfaces of the cooling device. To prevent damage to the electronic components by the ice, suitable materials to absorb water can be used such as, for example, “getters” or drying agents, e.g. magnesium sulfate, sodium sulfate, calcium chloride, calcium sulfate (Drierite), potassium carbonate, potassium hydroxides, molecular sieves, and the like. Other suitable agents will be selected by the person of ordinary skill in the art, given the benefit of this disclosure.

In accordance with certain examples, the cooling devices disclosed here can be used to cool an electronic component during an elevated temperature operation during manufacture, repair, or rework thereof. In some examples, the method comprises bringing a cooling device into thermal communication with the electronic component, subjecting the electronic component to the elevated temperature operation during which the cooling device cools the electronic component by way of heat transfer from the electronic component to the cooling device. Some package processing stages where heat sensitivity is particularly at issue include the reflow stage, the preheating stage prior to wave soldering, and any required rework or repair stage. Without wishing to be limiting and for convenience purposes only, a reflow process will be described below for illustrative purposes. Also, while the cooling device has potential application to myriad types of heat sensitive features, heat sensitive materials and electronic components that are exposed to elevated processing temperatures, such as packaged ICs, multi-chip modules, optoelectronic communication devices, or electronic displays, a flip chip IC package will be used herein for illustrative purposes.

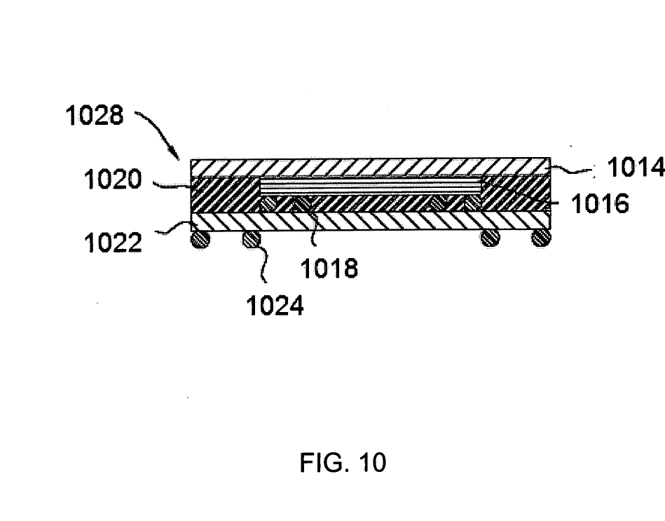

In accordance with certain examples and with reference to FIG. 10, flip chip package 1028 comprises substrate 1022 with a chip bonding area for mounting semiconductor chip 1016 thereon and a semiconductor chip with two sides, one side with electrically active features and a plurality of contact areas, and the other side without any electrical features. Semiconductor chip 1016 is oriented such that the electrically active side faces toward substrate 1022, to which it is electrically connected by a plurality of solder bumps 1018. Substrate 1022 contains electrical traces, such as barrels or vias, that facilitate electrical connection between semiconductor chip 1016 and the device to which the package is ultimately attached by solder balls 1024. Underfill material and molding compound, collectively 1020, are applied to the substrate's chip side to provide lateral and subjacent support to semiconductor chip 1016. Lid 1014 is then placed on the non-active side of the chip, such that lid 1014 adjoins both semiconductor chip 1016 and molding compound 1020. After lid 1014 is attached to the assembly, the package may be placed on another electronic component, such as a printed circuit board (PCB), which is discussed herein for illustrative purposes only. After the package's assembly, it can undergo subsequent processing stages at elevated temperatures. In accordance with certain examples, heat can be extracted from the electronic package during these processing stages prior to in-service use of, for example, the PCB.

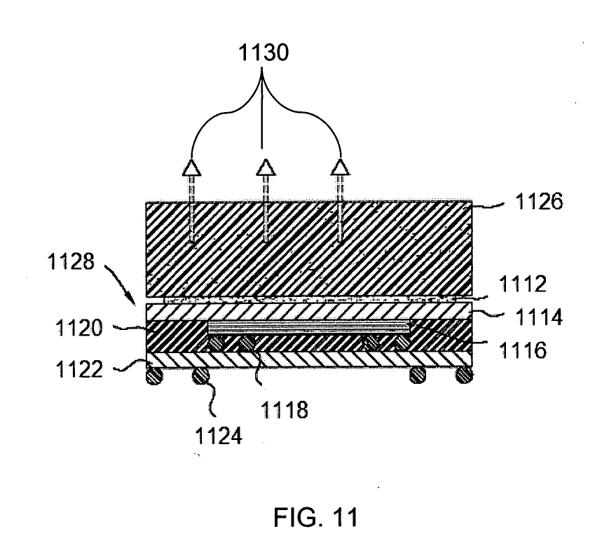

As discussed above, certain examples take advantage of an endothermic reaction or process taking place in proximity to the electronic package to extract the internal heat thereof for the period between the package's assembly and its in-service operation, or for a segment thereof. In one example and with reference to the schematic illustration in FIG. 11, a cooling device 1126 is attached to lid 1114. FIG. 11 includes those components directed to the package assembly described in reference to FIG. 10. Specifically, flip chip package 1128 comprises substrate 1122 with a chip bonding area for mounting semiconductor chip 1116 thereon and a semiconductor chip with two sides, one side with electrically active features and a plurality of contact areas, and the other side without any electrical features. Semiconductor chip 1116 is oriented such that the electrically active side faces toward substrate 1122, to which it is electrically connected by a plurality of solder bumps 1118. Substrate 1122 contains electrical traces, such as barrels or vias, that facilitate electrical connection between semiconductor chip 1116 and the device to which the package is ultimately attached by solder balls. 1124. Underfill material and molding compound, collectively 1120, are applied to the substrate's chip side to provide lateral and subjacent support to semiconductor chip 1116. Lid 1114 is then placed on the non-active side of the chip, such that lid 1114 adjoins both semiconductor chip 1116 and molding compound 1120. As discussed above, cooling device 1126 is operative to extract and dissipate heat from the electronic package during processing stages with optional assistance from a cooling medium. Bringing the cooling device into thermal communication with the electronic component includes, for example, positioning the cooling device in sufficient proximity to the electronic component to allow a suitable transfer of heat from the electronic component to the cooling device. In at least certain examples, this process involves placement of the cooling device on a surface of the electronic component, e.g., surface-to-surface contact exists between the cooling device and the electronic component. While the cooling device body provides some measure of heat extraction based on conduction, the endothermic reaction, process or rearrangement of the cooling medium at typical processing temperatures can further assist in cooling the electronic component. For example, water, optionally containing one or more of the inorganic and/or organic materials discussed herein, which has a vaporization temperature of 100° C., can be used for cooling during a 150° C. operation, provided the operation is brought up to 150° C. quickly enough that all the water in the cooling device does not evaporate prior to reaching the process temperature of 150° C. In certain examples below, vaporization of a volatile species is used for illustrative purposes.

In accordance with certain examples, to facilitate the endothermic phase change or reaction of the cooling medium, the cooling device's thermal conductivity can be tailored by selecting an appropriate cooling device body material. Specifically, the material can be selected to meet the particular endothermic reaction kinetics of the cooling medium. For example, when water is selected as the cooling medium, it might be advantageous to select a cooling device body material with a lower thermal conductivity so that the water does not evaporate before reaching the 150° C. operation temperature. In general, the cooling device body can be made of any inorganic or organic material, including metals, polymers, glass, ceramics, composite materials, and other inorganic and organic materials discussed herein. If the material selected is not capable of being impregnated with a cooling medium, a second material can be added to the cooling device body to retain the cooling medium. For example, in examples where the cooling device body is made of porous glass or metal, an inorganic material impregnated with a cooling medium can be added to the cooling device.

In certain examples as discussed above, the cooling device is a structure made of an inorganic material. For example, two representative inorganic materials are hydrated forms of CaSO₄, such as Plaster of Paris, and reticulated zirconia foams (RZF). In examples using Plaster of Paris as the inorganic material, the cooling device is formed to shape and solidified in a room temperature casting process. The Plaster of Paris is mixed with additives, per the supplier's instructions, and approximately 50 wt % water prior to casting. Desired dimensions can be achieved either through casting in molds or sawing single units from a larger bulk cast. As the Plaster of Paris casting process is a room temperature process, organic materials are acceptable as the mold material. In examples employing RZF as the inorganic material, the cooling device can be formed by a high temperature ceramic forming process akin to investment casting. An open-cell organic foam can impregnated with a zirconia-based ceramic slurry by soaking the foam in the ceramic slurry for a suitable period. The impregnated organic foam is then dried and fired, during which process the organic foam is eliminated. Without wishing to be bound by any particular scientific theory, the resulting ceramic foam has roughly the same pore size and density as the organic foam, meaning that these variables can be altered by selecting or designing an organic foam with the desired values. The cooling device in this instance is physically characterized by a multicellular configuration, with each “cell” having substantially continuous walls and a voided center, but with some degree of porosity to allow impregnation of the volatile species in the liquid phase and outgassing in the vapor phase. In one example, the cooling device has length and width in accord with the package's lid and thickness of about 1 cm to about 3 cm, for example.

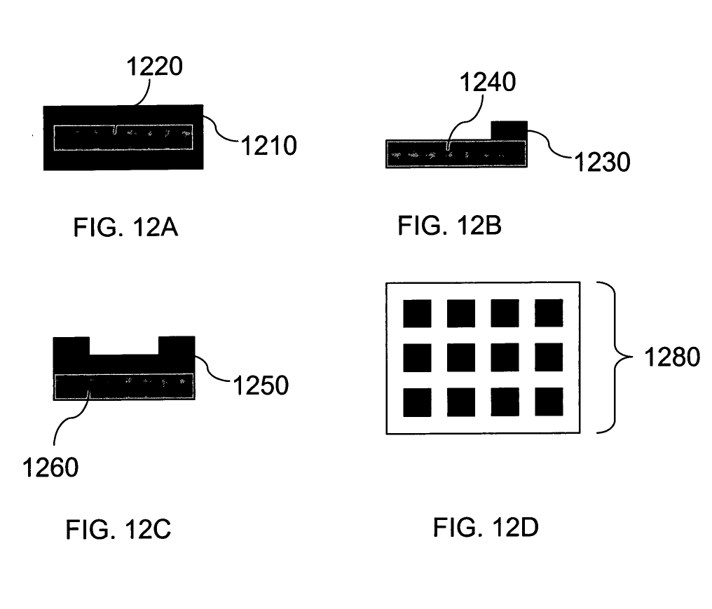

While the above embodiments refer to a cooling device for a single electronic component with dimensions mimicking the component's length and width, alternative embodiments with various physical configurations will be readily constructed by the person of ordinary skill in the art, given the benefit of this disclosure. For example, referring to FIG. 12A, cooling device 1210 can be formed so that is surrounds entire heat sensitive component 1220. In another example and referring to FIG. 12B, cooling device 1230 is much smaller than electronic component 1240 and only contacts a heat-sensitive area of electronic component 1240, such as, for example, a connector or socket. In yet another example and referring to FIG. 12C, cooling device 1250 is formed with varying cross-sectional thickness so that the thicker portions of cooling device 1250 are positioned over or near a heat-sensitive area of electronic component 1260. In yet other examples and referring to FIG. 12D, a bottom view of a cooling device 1270 designed in an array configuration to simultaneously extract and dissipate heat from multiple electronic components is shown. Here, the array configuration is characterized by areas configured to be in sufficient proximity to heat sensitive areas of an electronic component to achieve significant heat transfer from the heat sensitive areas of the component to the cooling device. Other suitable configurations will be selected or designed by the person of ordinary skill in the art, given the benefit of this disclosure.

In accordance with certain examples and as discussed elsewhere herein, the cooling device body can be impregnated with a cooling medium that is compatible with the reflow equipment, the flip chip package, and the PCB, if applicable. As discussed above, at least certain examples of the cooling medium are solid or liquid substances, such as a volatile liquid species, which have the function of undergoing a reaction or a phase change process to increase the temperature differential between the cooling device and the electronic component. As used here, the term “volatile species” refers to any species that has a heat of vaporization below the processing temperature of the stage during which the cooling device is designed to extract heat from the electronic component. In one example, the volatile species is comprised of the volatile components normally found in solder flux. One such flux is Alpha NR330, which is available from Alpha Metals (Jersey City, N.J.), and which comprises succinic acid, tetraethylene glycol, and dimethyl ether glutaraldehyde. In a second example, the volatile species is water optionally including one or more of the inorganic or organic materials discussed herein. In yet another example, the volatile species is a solution of water and a soluble inorganic or organic species which may undergo an endothermic reaction, process or rearrangement as the water vaporizes and/or may alter the vaporization temperature of the water. Based on the selection of the inorganic or organic species and by varying its concentration, the solution's vaporization temperature can be tailored to meet the specific heat dissipation characteristics the user desires. By increasing the vaporization temperature of the species, maximum heat dissipation efficiency can be altered to match the process temperature, maximum component temperature, and heat flow characteristics in order to best protect the component. In one example, the cooling medium is a solution of water and borax (hydrated sodium borate), wherein the borax provides additional endothermic cooling after the water is vaporized. Other suitable materials for use as cooling media are discussed herein and additional materials suitable for use as cooling media will be readily selected by the person of ordinary skill in the art, given the benefit of this disclosure. For example, there are presently available volatile organic compound-free (VOC-free) fluxes, such as VOC-free fluxes sold by Alpha Metals under the EF Series brand name. Other suitable VOC-free fluxes will be readily selected by the person of ordinary skill in the art, given the benefit of this disclosure.

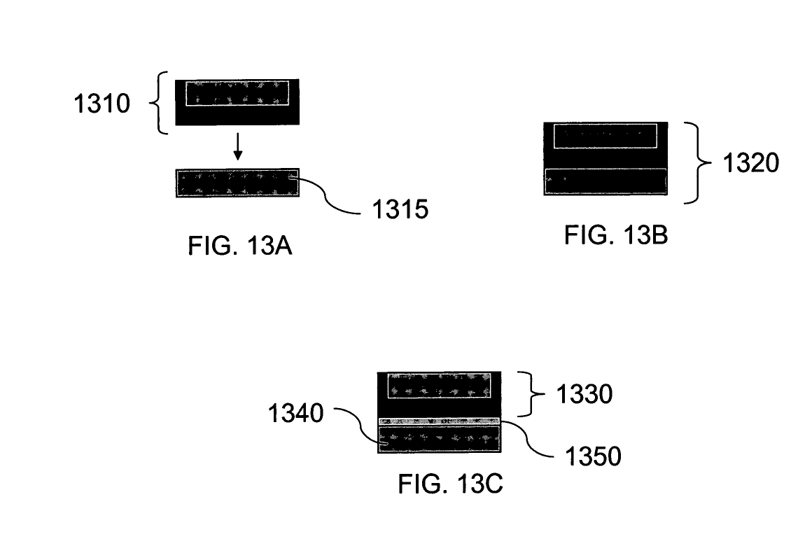

In accordance with certain examples, the cooling device body is typically brought into thermal communication by attachment to the component using any acceptable means that is temporary, that will secure the unit to the component during processing operations, and that does not irreparably alter the component's integrity. In one embodiment, the cooling device body may simply be placed on top of the component's lid, relying on gravity to keep the unit in contact with the component during processing. For example, referring to FIG. 13A, cooling device 1310 can be placed on electronic component 1315 to provide an assembly 1320 (see FIG. 13B) which can then undergo one or more processing steps. Other embodiments utilize attachment techniques such as mechanical fasteners, thermal grease, and tacky flux. For example, in FIG. 13C, thin layer of thermal grease 1350 is coated onto a surface of electronic component 1330 and is operative to hold together, at least temporarily, electronic component 1330 and cooling device 1340. In addition, in the exemplary device shown in FIG. 11, the cooling device body is shown as being attached by thermal grease or tacky flux, collectively represented as 1112.

In accordance with other examples and with reference to FIG. 11, to attach the flip chip package to the PCB, solder spheres 1124 are positioned on the surface of the substrate 1122. The package is then heat treated to adhere the solder spheres to the package. The package is then dipped in a flux to provide temporary adhesion between the solder spheres and the substrate. The package is oriented on the PCB such that the solder spheres are in contact with electrical contacts on the PCB, which have generally been pretreated with solder paste. The PCB, with at least one flip chip package having a cooling device attached thereto, is then placed in a reflow oven to reflow the solder spheres. Typical reflow oven dwell time is from about 2 minutes to about 5 minutes, with the particular dwell time dependent on peak processing temperature, the thermal mass of the board and components, their thermal stability, and the type of solder being used. Typical reflow oven temperature is from about 100° C. to about 300° C., though the temperature may vary outside this range depending on the nature of the solder or flux used or depending on the intended processing operation to be performed.

In accordance with certain examples and without wishing to be bound by any particular scientific theory, during the elevated temperature process heat can be conducted from the electronic component through the cooling device body to the cooling medium. The cooling device body may then be cooled by an endothermic process, reaction or rearrangement undergone by the cooling medium. The endothermic nature of the cooling medium allows the cooling device to yield higher cooling efficiency when compared to the cooling characteristics of a traditional reflective heat shield or a traditional heat sink. Specifically, a reflective heat shield only assists in cooling the package by reflecting a portion of the heat directed toward the package and by minimal conduction through the solid material. The efficiency of the reflective heat shield is limited by its reflective properties, which cannot protect the component from infrared heat, and by its surface area, which impacts its conduction properties. In contrast, examples of the cooling device disclosed herein can dissipate heat by numerous processes including but not limited to conducting heat away from the package, increasing the temperature differential between the cooling device and the electronic component using the cooling medium, and carrying heat from the cooling device to the oven atmosphere by the outgassing of any vapor-phase volatile species. The general evolution of heat by the cooling device is represented by the three dashed arrows 1130 in FIG. 11.

In addition, to the advantages noted above, examples of the cooling devices disclosed herein do not impede the conduction of heat through the PCB during thermal processing. This feature allows the melting of solder paste, which facilitates attachment of the solder spheres to the PCB, by conduction of heat through the board while maintaining a thermal gradient through the assembly with the highest temperatures at the board-side of the package. Again without wishing to be bound by any particular scientific theory, the thermal gradient produced by utilizing the cooling device allows solder joint formation or elevated temperature reworking while protecting heat-sensitive features within the electronic component. In some examples the thermal gradient is configured such that the elevated temperature near the soldering or reworking operation at the extremities of the electronic component, e.g., the package, drops to a safe temperature at the internal features of the package.

In accordance with other examples, the vapor form of any volatile species from the cooling medium may be trapped by a recycling management system. The vaporized volatile species may then be allowed to return to their liquid phase and be reused in later cooling devices. Such recycling prevents adverse effects on the flip chip package assembly, the PCB, the oven, and the environment, while simultaneously improving the cost efficiency of the system.

In accordance with certain other examples, the cooling device can be impregnated with a cooling medium that can undergo repeatable, reversible endothermic reactions. In this example, the cooling device is either sealed to prevent cooling medium loss or the cooling device is reimpregnated with the cooling medium after it has returned to its pre-processing state in a recycling management system. An example of such a cooling medium is one or more hydrated forms of sodium acetate (CH₃COONa) solution. While the solution can be designed to have different melting and boiling points, sodium acetate trihydrate (CH₃COONa.3H₂O) melts at about 58° C. and evaporates at about 120° C. In this example, the cooling device can be removed after the processing is completed and allowed to cool. During cooling, the cooling medium in a sealed cooling device will return to its pre-processing state, i.e., it will undergo an exothermic reaction. Sealing the cooling device in this embodiment refers to the addition of a vapor and/or particulate barrier, such as aluminum foil or a heat resistant polymer. In an alternative example, this vapor and/or particulate barrier is reusable. If the cooling device is not sealed, it can be reimpregnated with the cooling medium that has returned to its pre-processing state in a recycling management system. Suitable methods for recycling the cooling media disclosed here will be recognized by the person of ordinary skill in the art, given the benefit of this disclosure.

In accordance with certain other examples, the cooling device may include an attached piece of foil. In one example, the foil is placed on the bottom of the cooling device, between the lid of the package and the cooling device. In this example, the foil acts to prevent contamination of the package during the endothermic process. In an alternative example, foil is applied to the top of the cooling device. In this example, the foil can facilitate the operation of pick and place operations that utilize vacuum pick-up heads. In yet another example, foil is placed on both the bottom and the top of the cooling device. Any acceptable attachment mechanism can be used to secure the foil to the cooling device, such as being cast with the cooling device in the organic mold or adhered in place after the cooling device has been formed. Apart from a foil acting as a barrier or suction site, other elements can be added to the cooling device to alter its performance characteristics. In one example, an abrasion-resistant coating, such as a glass cloth or expanded metal foil, can be added to the cooling device to reduce its wear rate and thereby extend its life-span. In another example, a heat-reflective pattern or heat-absorbent pattern is applied to the cooling device to further increase the cooling device's heat dissipation capacity. In yet another example, the cooling device can be structurally reinforced by materials that are cast into the cooling device body during its formation, such as chopped fiber, glass cloth, and expanded metal foil. Another example involves structurally reinforcing the cooling device by the affixing additional physical features, such as edge pieces and runners made of a metal, polymer, ceramic, glass, or composite material, which can be added to the cooling device during or after its formation.

In addition to the reflow process, electronic components may be exposed to elevated processing temperatures during the preheating stage prior to wave soldering, rework stages, and repair stages. During the preheating stage prior to wave soldering, the electronic component may be exposed to temperatures between about 100° C. to about 200° C. A rework stage is required when a component has undergone normal processing and is potentially viable, but some correctable processing error must be addressed prior to use, e.g., localized solder repair. During rework processing, localized temperatures are elevated to reflow the solder, e.g., between about 100° C. to about 300° C. Similarly, repair processing is required when a discrete part of the electronic component is the root cause of the component's failure. To return the component to operating order, it is typically necessary to heat the localized area including and surrounding the discrete source of failure to elevated temperatures similar to rework levels. In any of these or other elevated temperature processing stages, a cooling device may be attached to the electronic component to aid in heat dissipation.

In one example, after the processing stage is complete, the cooling device is removed. In this regard, some examples involve bringing a temporary cooling device into thermal communication with the electronic component during elevated temperature operations where the temporary cooling device cools the electronic component and subsequently removing the temporary cooling device from therial communication with the electronic component. One particular example involves subjecting the electronic component to elevated temperature operation temperatures between about 125° C. and about 300° C.

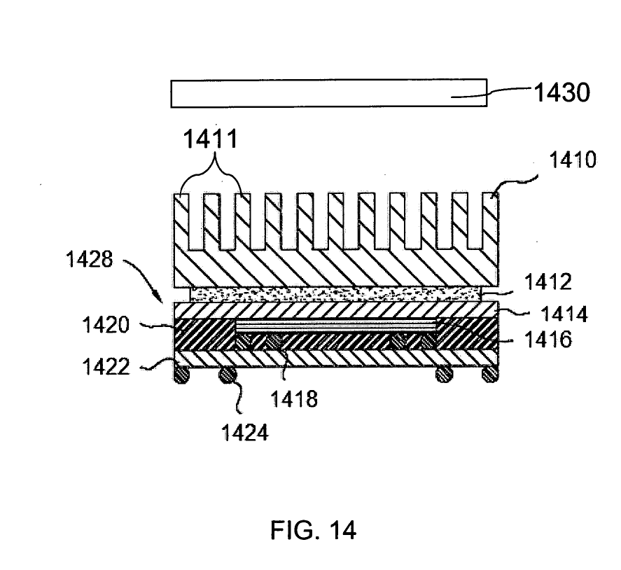

In accordance with certain examples, after removal of the cooling device, an alternate heat dissipation device can be attached to the electronic component, such as a heat sink 1410 attached to lid 1414, as shown in FIG. 14. Flip chip package 1428 includes substrate 1422, semiconductor chip 1416 and lid 1414. The configuration shown in FIG. 14 is similar to the one shown in FIG. 11 and includes underfill and molding compound collectively 1420, solder bump 1418, and solder balls 1424. The alternate heat dissipation device may be attached using thermal grease or adhesive, collectively represented as 1412. This alternate heat dissipation device can provide permanent, in-service heat dissipation for the package. In other examples, the cooling device remains on the component after processing. In one such example, the cooling device is a temporary unit in that even though it remains on the component, it serves no further significant cooling or heat-sink function. In another such example, the cooling device also serves as a permanent cooling device in that it is operative as a heat sink during in-service operation even after its cooling medium is exhausted. In this example, the cooling device can be formed into a shape configuration of a typical heat sink, including cooling fins 411, as seen in heat sink 1410 in FIG. 14 and optionally can include one or more fans, such as fan 1430 disposed on a top surface of the heat sink.

In accordance with certain examples, the cooling devices disclosed here can include one or more coatings, e.g., conductive coatings, IR reflective coatings, UV reflective coatings, etc. In certain examples, the coatings are disposed on the cooling device body using, for example, brush coating, spin-coating, vapor deposition, sputtering, molecular beam epitaxy or other suitable deposition techniques that will be readily selected by the person of ordinary skill in the art, given the benefit of this disclosure. In some examples, the coating includes one or more silver, copper, chromium or gold compounds or mixtures thereof. For example, the coating can include silver oxide, copper oxide, tin oxide, gold oxide, or other suitable metal oxides, metal nitrides and the like, e.g. SnO₂ reactively sputtered onto the cooling device body. In certain examples, the coating includes WO₃, TiO₂, ZnO, BiOₓ or Si₃N₄. The coating may include buffer layers, thickness adjustment layers and the like. For example, one or more buffer layers can first be disposed on a surface or surfaces of the cooling device to provide improved adhesion for the reflective or conductive layer, which is disposed on the buffer layer. In certain examples, the coating is a single layer, e.g., a monolayer, whereas in other examples the coating is a multi-layer coating, e.g., a multi-layer coating that includes at least one infrared reflective layer. For example, the coating may include one or more buffer layers, disposed on the cooling device body, and one or more copper, silver or copper/silver layers disposed on the buffer layer. In other examples, the buffer layer can be omitted and one or more copper, silver or copper/silver layers can be disposed directly on the cooling device body. Without wishing to be bound by any particular scientific theory, selection of suitable materials for the coating can provide cooling devices, or can provide areas on the cooling devices, that are heat-reflective or heat-absorptive. For example, when IR reflective materials such as tin oxide are disposed on the cooling device body, the cooling device body can reflect infrared radiation to the surrounding environment and away from the device or package to be cooled. The exact thickness of the coating can vary depending on the intended use and the desired effect, and in certain examples, a single layer coating is about 10 nm to about 10 um thick, more particularly about 50 nm to about 5 um thick, e.g., about 100, 200, 300, 400 or 500 nm thick. In examples using multi-layer coatings, the total thickness of the coating is about 10 nm to about 100 um, more particularly about 100 nm to about 1 um, e.g., about 200, 400, 600 or 800 nm thick. Other suitable thicknesses for single layer and multi-layer coatings will be readily selected by the person of ordinary skill in the art, given the benefit of this disclosure. In certain examples, the coating may be disposed directly on the package or device to be cooled, and a cooling device can optionally be placed in thermal communication with the coating. In other examples, the coating can be disposed on one or more intervening devices or temporary devices that are placed between the device to be cooled and the cooling device during a processing operation. It will be within the ability of the person of ordinary skill in the art, given the benefit of this disclosure to select suitable coatings for use with the cooling devices, heat sinks and other devices disclosed herein.

In accordance with certain examples, certain configurations of the cooling devices disclosed herein include configurations that allow for localized heat entry, e.g., differential heating, to electronic components. For example, ball grid arrays may include solder spheres provided underneath the component, and to control the reflow temperature of the solder spheres, a cooling device can be configured to provide heat to the regions overlying the solder spheres while maintaining cooling of the rest of the ball grid array. The exact configuration of the cooling devices to provide such selective heating can vary and may include, for example, voids, valves, etc. Suitable configurations for cooling devices that allow for selective heating will be readily selected by the person of ordinary skill in the art, given the benefit of this disclosure.

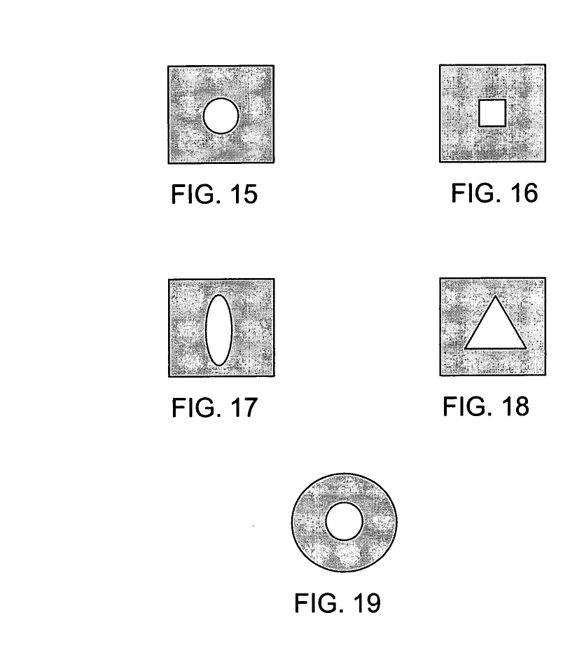

In accordance with certain examples, a cooling device configured with a void is disclosed. Without wishing to be bound by any particular scientific theory, areas underlying a void are cooled to a lesser degree. In certain configurations, it may be desirable to cool certain areas to a lesser degree to provide improved solder reflow, for example, while providing cooling to surrounding areas to prevent heat damage and/or distortion to the component and/or package protected by the cooling device. The exact dimensions, shapes, geometries, etc. of the void can vary depending on the desired cooling capacity of the cooling device and on the dimensions of the electronic component, or portions thereof, to be cooled. For example, the void, when viewed from a top surface of the cooling device body, may be circular (see FIG. 15), square (see FIG. 16), oval (see FIG. 17), triangular (see FIG. 18), etc. Though the cooling device body is shown as being rectangular in FIGS. 15-18, the shape of the cooling device body may be tailored to the shape of the electronic component to be cooled to provide better cooling control. In certain examples, the cooling device body is circular and includes a circular void where a circular electronic component is to be cooled (see FIG. 19). In examples where flip chip packages are to be cooled, the cooling device body may be rectangular having a width and length approximately the same as the width and length of the flip chip package and may include a void of suitable shape and dimension.

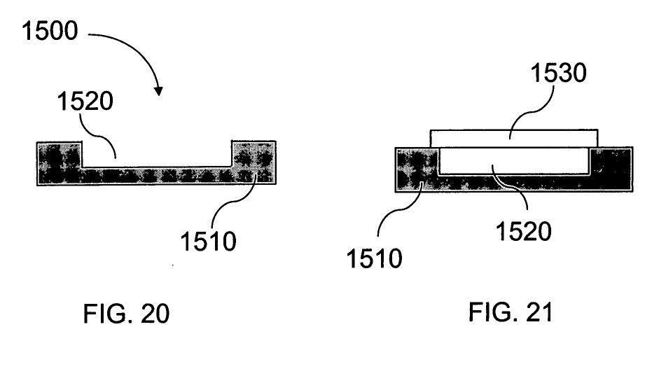

In certain examples, the void may run the entire transverse dimension of the cooling device body, i.e., the dimension perpendicular to the surface of the electronic component to be cooled, such that an opening on the top and bottom surface of the cooling device body is present. In other examples, the void extends into the body of the cooling device body, but does not traverse the entire transverse dimension of the cooling device body. For example and referring to FIG. 20, in certain configurations, void 1520 of cooling device 1500, extends into cooling device body 1510, but does not completely traverse the width of cooling device body 1510.

In certain examples, the void of the cooling device may be filled with one or more cooling media. Again without wishing to be bound by any particular scientific theory, in examples where the void comprises one or more cooling media, the area underlying the cooling media may be cooled to a higher degree than areas underlying the cooling device body depending on the thermal constants, e.g., heat capacity, of the cooling media and the cooling device body. Such configurations allow, for example, region or area specific cooling of portions of an electronic component.

In accordance with certain examples, a fan or cooler may be disposed over the void to further control cooling of the area underlying the void. For example and referring to FIG. 21, fan 1530 is disposed over void 1520. In certain examples, the fan is attached to the cooling device using a fastener, such as a screw, rivet, clip or the like, whereas in other examples, the cooling device is fastened using tape, adhesive, velcro or the like. In some examples the fan or cooler spans the entire opening of the void, whereas in other examples, the fan or cooler is positioned off-center. It will be within the ability of the person of ordinary skill in the art, given the benefit of this disclosure, to select suitable fans and cooling devices to provide additional cooling control.

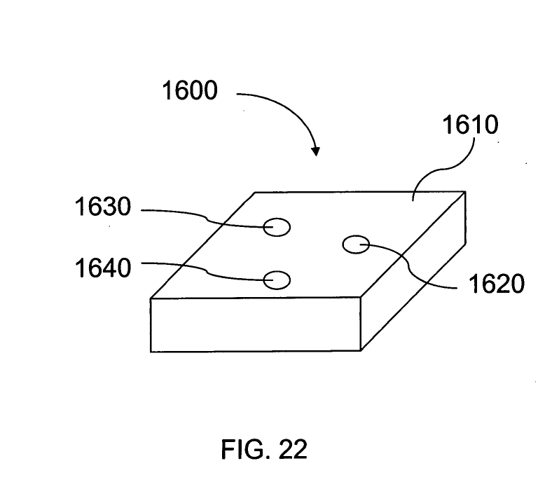

In accordance with certain examples, a cooling device comprising a cooling device body that includes one more voids is disclosed. In certain examples, the cooling device body includes a plurality of voids. For example and referring to FIG. 22, cooling device 1600 comprises cooling device body 1610 with voids 1620, 1630 and 1640. The exact position of voids 1620, 1630 and 1640 can vary depending on the position of areas of the electronic component to be cooled. In examples where voids 1620, 1630 and 1640 are left unfilled, heat can enter into voids 1620, 1630 and 1640 to provide localized heating to areas underlying voids 1620, 1630 and 1640, e.g., to provide localized heating for solder reflow. In examples where one or more of voids 1620, 1630 and/or 1640 are filled, or partially filled, with a cooling media, areas underlying voids 1620, 1630 and 1640 can be cooled. The exact number and shape of voids can vary depending on the number of areas on an electronic component to be heated, or cooled in the case of voids filled or partially filled with cooling media.

In certain examples, the void spans the entire width of the cooling device body, whereas in other examples, the void extends into the cooling device body does not span the entire width. For example, the void can extend into a top surface of the cooling device body but not traverse the entire width of the cooling device body. In some examples, the voids take the form of small impressions or dimples. In certain examples, all surfaces of the cooling device body include such small impressions or dimples, whereas in other examples, only selected surfaces include small impressions or dimples. It will be within the ability of the person of ordinary skill in the art, given the benefit of this disclosure, to select suitable numbers of voids, and placement and configurations of the voids, for use in the cooling devices disclosed herein to selectively cool a component and enable heat to attach the component to a substrate.

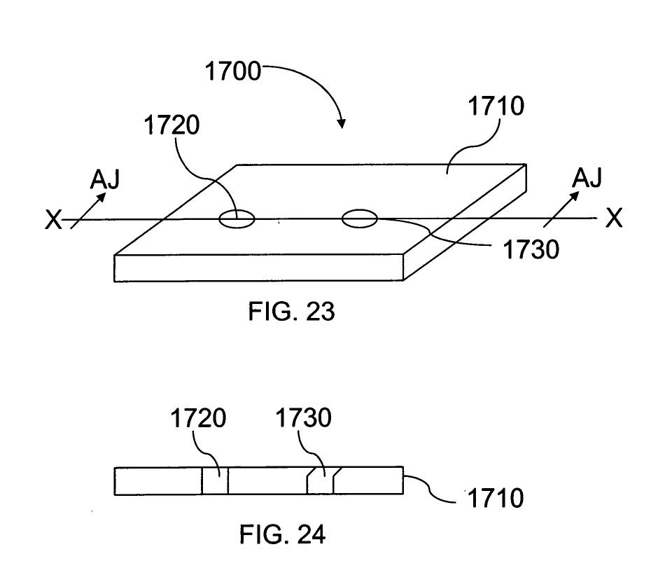

In accordance with certain examples, a cooling device comprising a cooling device body with one or more non-continuous voids is disclosed. As used herein, “non-continuous void” refers to a void in a cooling device body that has an angle greater than zero at some point. For example, referring to FIG. 23 and FIG. 24, cooling device 1700 includes cooling device body 1710, continuous void 1720 and non-continuous void 1730. FIG. 24 shows a side view of cooling device 1700, in section, through line X-X. Void 1720 spans the width of cooling device body 1710 and is perpendicular to the long axis of cooling device body 1710, whereas a portion of void 1730 is set at an angle to the long axis of cooling device body 1710. Without wishing to be bound by any particular scientific theory, by angling or bending at least a portion of the void, heat flow into the non-continuous void is different than heat flow into the continuous void. Such angling and bending of the voids provides for additional heating and/or cooling control using the cooling device disclosed herein. In some examples, the void may include multiple different angles, sharp elbows, round elbows and other shapes and configurations commonly used in the HVAC industry for routing heating air or cooling air. It will be within the ability of the person of ordinary skill in the art, given the benefit of this disclosure, to design cooling devices that include continuous and/or non-continuous voids.

In accordance with certain examples, the voids of the cooling devices disclosed herein may be partially obstructed. For example, the voids may contain a fixed or removable cap that is constructed and arranged to partially obstruct an opening on the void. In certain examples, the void is obstructed proximal to the surface of the electronic component to be cooled, whereas in other examples, the void is obstructed distal to the surface of the electronic component to be cooled. In other examples, the void is partially obstructed within the cooling device body. Such partial obstructions may take numerous forms including, but not limited to, a reduction in diameter of the void within the cooling device body, a frit disposed in the void, filler material disposed in the void, etc. The person of ordinary skill in the art, given the benefit of this disclosure, will be able to select suitable designs and methods for partially obstructing the voids of the cooling devices disclosed herein.

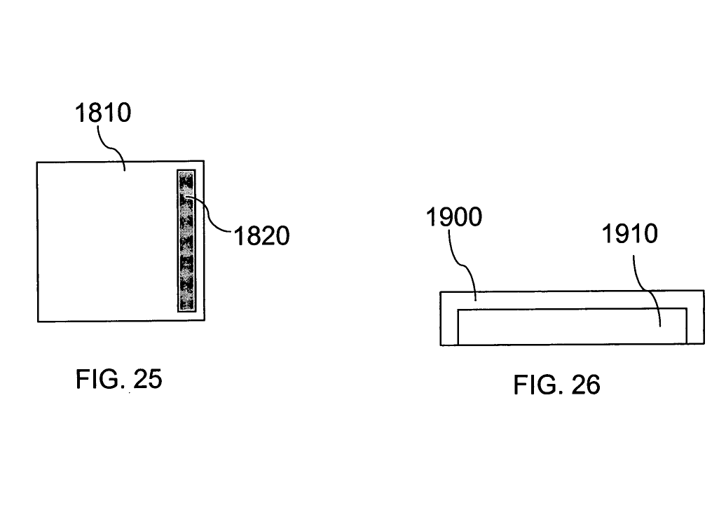

In accordance with certain examples, a cooling device comprising tape optionally with one or more cooling media disposed on the tape is provided. Referring to FIG. 25, a top view of an electronic component 1810 with cooling device 1820 disposed on electronic component 1810 is shown. In the example shown in FIG. 25, cooling device 1820 is in the form of a strip of tape. In certain examples, a plurality of strips of tape can be disposed on select, or all, areas of an electronic component to be cooled. In some examples, the strips of tape are disposed substantially parallel to each other, whereas in other examples, strips of tape are disposed at an angle to each other, e.g., perpendicular to each other. The tape may be disposed in numerous ways, e.g., manually, automated, etc., and in certain examples the tape is disposed using pick and place equipment. For example, the tape may be removably fixed to the pick and place equipment and as the pick and place equipment selects components for placement, the tape releases from the pick and place equipment and becomes affixed to the component. It will be within the ability of the person of ordinary skill in the art, given the benefit of this disclosure, to select suitable methods for disposing cooling devices comprising tape. Numerous pick and place equipment is commercially available from numerous manufacturers, including but not limited to, Universal's Instrument(e.g., GSM® Platform, GSM® Genesis Platform, AdVantis Platform Vantis), Mydata (e.g., MY-SERIES: MY9, MY12, MY15, MY19 or MYSynergy), Siemens Dematic's (e.g., SIPLACE® HS, SIPLACE® S, SIPLACE® F), Automated Production Systems (L60, L40, L20), Laurier Inc.'s (e.g., DS-9000 and DS-4000) and Manncorp (e.g., MC383V). Additional pick and place equipment will be readily selected by the person of ordinary skill in the art, given the benefit of this disclosure.

In certain examples, the exact dimension and configuration of the tape depends, at least in part, on the dimensions of the electronic component, or portion thereof, to be cooled. In some examples, tape having thickness of about 0.25 to about 5 mils, e.g., about 0.5, 1, 2, 3 or 4 mils. In certain examples, the tape may be cut from a roll to fit the cooling device. In some examples, the tape has a width of about 5 mm to about 200 mm, more particularly about 10 mm to about 175 mm, e.g., 12 mm, 51.11 mm, 51.75 mm, 76.80 mm, 101.95 mm, 102.16 mm, and 152.84 mm). The length of the tape typically varies depending on the desired area or region to be cooled. In some examples, the tape is about 5 mm to about 200 mm long, more particularly about 10 mm to about 100 mm long, e.g., about 35 mm long.

In certain examples, the tape may include one or more materials selected from one or more of polyethylene terephthalate, polyimide, aluminum, gold and insulating materials. It will be within the ability of the person of ordinary skill in the art, given the benefit of this disclosure, to select suitable tape dimensions and thicknesses for use in the cooling devices disclosed herein.

In some examples, Sheldahl's family of Polyethylene Terephthalate (PET or polyester) films (e.g., G4053XX, G4052XX) that are aluminized on one side or on both sides, that may be used to reflect heat, or that may be used in multi-layer insulation (MLI) blankets in low temperature applications are used as a tape, optionally with an adhesive.

In certain examples, this product may be used with 0.25, 0.5, 1, 2, 3, or 5 mil thick PET. In other examples, Sheldahl's family of polyimide films (e.g., G4051XX, G4024XX) that are aluminized on one or both sides can be used to reflect heat, or similar films that may be used in multi-layer insulation (MLI) blankets when a wide temperature range is desired may be used as a tape, optionally with an adhesive. In certain examples, this product may be used with 0.3, 0.5, 1, 2, 3, or 5 mils thick polyimide.

In yet other examples, Sheldahl's family of polyimide films (e.g., G4114XX) that are aluminized on one or both sides and protected by AOC can be used to reflect heat, or similar materials that can be used in multi-layer insulation (MLI) blankets when a wide temperature range is desired may also be used as a tape, optionally with an adhesive. In certain examples, this product may be used with 0.3, 0.5, 1, 2, 3, or 5 mils thick polyimide.

In even other examples, Sheldahl's family of aluminum coated black Kapton® films may be used as a tape. This product is available with a variety of polyimide substrate, e.g., 100CB Kapton® (non-conductive), 100XC Kapton® (semi-conductive) and, as custom products, 160XC or 275XC Kapton® (thick, moderately conductive).

In additional examples, Sheldahl's family of polyimide films (e.g., G4049XX, G4018XX) that are gold coated on one or both sides may be used as heat reflective materials, or similar materials that may be used in multi-layer insulation (MLI) blankets when a wide temperature range is desired may also be used as a tape, optionally with an adhesive. In certain examples, this product may be used with 0.3, 0.5, 1, 2, 3, or 5 mils thick polyimide.

In other examples, Sheldahl's first surface aluminized polyimide tape with 966 (acrylic) adhesive may be used. In even other examples, Sheldahl's first surface aluminized polyimide tapes with AOC and 966 adhesive may be used. In additional examples, Sheldahl's second surface aluminized polyimide tapes with 966 acrylic adhesive may be used. In certain examples, Sheldahl's second surface aluminized polyimide tapes with silicone adhesive may be used. In other examples, Sheldahl's first surface gold coated polyimide tapes with 966 adhesive can be used. In yet other examples, Sheldahl's polyimide tapes with 966 adhesive may be used. Exemplary Sheldahl products include G4010XX, G4117XX, G4088XX, G4077XX, G4064XX, and G4011 XX.

In additional examples, Sheldahl's family of black Kapton tapes with acrylic adhesives may be used. In other examples, Sheldahl's one surface or second surface aluminum coated FEP tapes with 966 acrylic adhesive may be used. In certain examples, Sheldahl's one surface or second surface silver coated FEP tapes with 966 acrylic adhesive may be used. In other examples, Sheldahl's ITO coated silver FEP tapes with '966 acrylic adhesive or '9703 conductive acrylic adhesive can be used. In yet other examples, Sheldahl's family of polyimide films that are aluminized on one side and have an indium tin oxide (ITO) coating on the other may be used. In additional examples, Sheldahl's family of germanium coated polyimide films may be used.

It will be recognized by the person of ordinary skill in the art, given the benefit of this disclosure, that the exemplary tapes listed above may be used in combination with one or more other exemplary tapes listed above to provide desired cooling of an electronic component.

In certain examples, the tape may be single-sided or double-sided, may include one or more release layers, pressure sensitive adhesives, scrims and the like. In other examples, the tape may include additives, such as flame retardants, dyes, indicators, anti-oxidants, etc. In some examples, the tape includes a temperature indicator which is configured to change color if the temperature of the tape exceeds a threshold temperature. Exemplary temperature indicators include, but are not limited to, those commercially available from Temperature Indicators, Ltd. (UK), Calex Electronics Limited (UK), 3M Indicator Tapes (e.g., 3M MonitorMark Time Temperature Indicators, 3M MonitorMark Dual Temperature Indicators), Thermographic Measurements (TMC Thermax® Encapsulated Indicators) and the like. Additional additives for inclusion in the tapes will be readily selected by the person of ordinary skill in the art, given the benefit of this disclosure.

In accordance with certain examples, the tape may include one or more cooling media disposed on at least one surface of the tape. The cooling medium may be disposed on the tape using numerous methods including, for example, coating, brushing, rolling, spraying, dipping and the like. In some examples, the tape is positioned in a pick and place device and then dipped into the cooling medium prior to selecting an electronic component for placement. The exact amount of cooling medium disposed on the tape can vary depending on the desired amount of cooling. In certain examples, at least an effective amount of cooling medium is disposed on the tape to provide cooling to an electronic component during exposure of the electronic component to a process temperature between about 100° C. and 300° C. during a processing operation. The cooling medium may be any of the cooling media disclosed herein or other suitable cooling media that will be readily selected by the person of ordinary skill in the art, given the benefit of this disclosure.

In accordance with certain examples, a conforming or conformable cooling device is provided. In certain examples, the conforming cooling device is designed to contact substantially all exposed surfaces of an electronic component to be cooled. In some examples, the conforming cooling device is formed by casting using a suitable mold or die that is configured to be complementary to the electronic component to be cooled. In other examples, the conforming cooling device is constructed by stamping a metal sheet, perforated metal sheet, or metal screen to form a conforming cap or ring. For example, referring to FIG. 26, cooling device 1900 has taken the form of a conforming cap which can be placed in thermal communication with electronic component 1910. In some examples, the cooling device may take the form of a ring with a void in the center of the ring. In some examples, the conforming cap or ring may include one or more cooling media to provide additional cooling. The cooling media may be disposed on the conforming cooling device by brushing, coating, spraying, rolling, dipping, or other suitable methods for disposing the cooling media that will be readily selected by the person of ordinary skill in the art, given the benefit of this disclosure.

In accordance with certain examples, the conforming cooling device may be manually placed on an electronic component to be cooled or may be placed using mechanical devices, such as robotic arms, pick and place equipment, e.g., with expanding grippers, and the like. The conforming cooling device can be removed from the electronic component after a processing operation or may be left in thermal communication with the electronic component after the processing operation. The person of ordinary skill in the art, given the benefit of this disclosure, will be able to place conforming cooling devices in thermal communication with an electronic component using suitable methods and devices.

In certain examples, the conforming cooling device may include a fan, fins or other suitable devices disposed on the cooling device to facilitate additional heat removal. In some examples, the conforming cooling device includes a thermoelectric cooler to provide additional cooling. It will be within the ability of the person of ordinary skill in the art, given the benefit of this disclosure, to include additional devices with the conforming cooling device to provide additional cooling.

In accordance with certain examples, a cooling device comprising a polymeric cooling device body is disclosed. The polymeric cooling device body may include voids, may be conforming or may take other suitable forms, such as those disclosed herein. The exact composition of the polymeric cooling device body can vary and may include straight chain and cross-linked polymers, co-polymers, homopolymers, heteropolymers, plastics and the like. In certain examples the polymeric cooling device body includes polyimide, polyphenylene sulfide, fluoropolymers, polyetheretherketone (PEEK), a polyphthalamide (PPA), liquid crystal polymers (LCP) and the like. Additional suitable polymers will be readily selected by the person of ordinary skill in the art, given the benefit of this disclosure. In certain examples, the polymeric cooling device body is formed, or stamped into, an inverted cup without a lid, e.g., a 5-sided box. In some examples, one or more surfaces of the inverted cup includes one or more voids, which may or may not be partially obstructed with, for example, tape, caps, covers or the like.

In some examples, the polymeric cooling device body includes one or more cooling media disposed, impregnated, adsorbed, coated, etc., on or into the polymeric cooling device body. The cooling medium may be any of the cooling media disclosed here or mixtures thereof. In some examples the polymeric cooling device body is soaked or saturated with cooling media so that cooling media may be taken into the pores or voids of the polymeric cooling device body. In other examples, the polymeric cooling device body is coated with a carrier that is configured to retain cooling media. Additional configurations of polymeric cooling device bodies with disposed cooling media will be readily selected by the person of ordinary skill in the art, given the benefit of this disclosure.

In accordance with certain examples, a cooling device comprising a stamped metal cooling device body is provided. The stamped metal cooling device body can be constructed from numerous different metals including, but not limited to, gold, copper, aluminum, steel, and the like and mixtures and alloys thereof. Without wishing to be bound by any particular scientific theory, the exact composition of the stamped metal cooling device body may vary based on numerous considerations such as, for example, meeting the requirement of good infrared reflection while maintaining thermal isolation of the component. Additional suitable metals will be readily selected by the person of ordinary skill in the art, given the benefit of this disclosure. In certain examples, the stamped metal cooling device body takes the form of an inverted cup, e.g. a 5-sided box. The inverted cup may include voids that are unobstructed or partially obstructed. The inverted cup may also include one or more cooling media disposed on a surface of the inverted cup. In some examples, tape is disposed on a surface of the inverted cup, and a cooling medium is disposed on the tape. Other suitable configurations will be readily selected by the person of ordinary skill in the art, given the benefit of this disclosure.

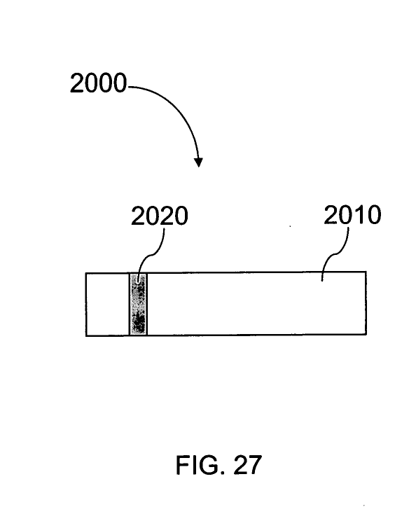

In accordance with certain examples, a cooling device comprising a cooling device body that includes one or more valves is disclosed. In certain examples, at least one valve is positioned substantially perpendicular to the surface of an electronic component to be cooled. In certain configurations, the valve spans the width of the cooling device body such that heat can enter into valve to heat the area underlying the valve when the valve is open, and heat is prevented from entry to the area underlying the valve when the valve is closed. For example, referring to FIG. 27, cooling device 2000 includes cooling device body 2010 with valve 2020 disposed in cooling device body 2010. Valve 2020 spans the width of cooling device body 2010. When valve 2020 is open, heat can flow into the valve to provide heat to the area underlying the valve, and when valve 2020 is closed, heat is prevented from entering into area underlying the valve opening. In certain examples, the valve is manually opened and closed, whereas in other examples, the default state of the valve is open, and the valve automatically closes when the temperature exceeds a certain threshold. In yet other examples, the valve is electronically actuated using a controller or the like. The valve can be opened partially, e.g., 25%-75% open, 40-55% open, 50% open, etc, or can be opened fully. In some examples, the valve is cycled open and closed at a frequency of about 0.1 Hz to about 100 Hz, e.g., about 1-20 Hz, 10-15 Hz. Without wishing to be bound by any particular scientific theory, by cycling a valve with a cycle frequency that approaches infinity, the valve allows heat entry as if it were continuously open even though the valve is closed for some time during operation. The cycle frequency of the valve can be varied during a processing operation. For example, during part of a processing operation where it is desirable to minimize heat entry into an area underlying the valve, the cycle frequency can be close to 0 Hz. If necessary during the processing operation to provide heat to an area underlying the valve, the cycle frequency can be increased, e.g., from about 0.1 Hz to about 0.5 Hz, to allow heating of the area.

In certain examples, the valve is selected from the group consisting of butterfly valves, needle valves, diaphragm valves, solenoid valves, valves commonly used in HVAC components, such as compressors, temperature actuated valves commonly used in sprinkler systems, directional control valves, check valves, flow control valves, etc. Additional suitable valves will be readily selected by the person of ordinary skill in the art, given the benefit of this disclosure. In some examples, the valve may include two or more inlets and a single outlet, a single inlet and two or more outlets, or multiple inlets and outlets. In some examples, the valve is passive, in that it can open or close without an external power source, e.g., a temperature actuated valve, whereas in other examples, the valve is active and requires a power source and/or a controller.

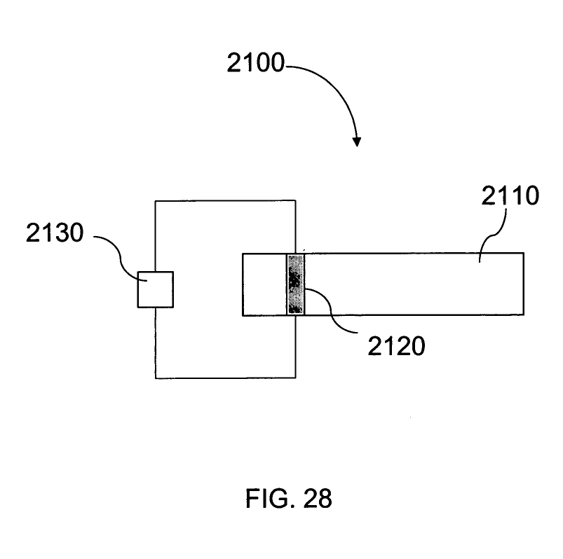

In examples where an electronically controlled valve is used, a cycling sequence may be implemented to provide automatic adjustment of the valve to allow, or prevent, heating of areas underlying the valve. For example and referring to FIG. 28, cooling device 2100 comprises cooling device body 2110 and a valve 2120 disposed in cooling device body 2110. Valve 2120 is in electrical communication with controller 2130, which is configured to control opening and closing of the valve. In certain examples, controller 2130 is a microprocessor, which may optionally include additional devices, such as memory devices for storage of cycle sequences. In other examples, the controller is in wireless electrical communication with the valve to send electronic signals to the valve for opening and closing of the valve. Suitable wireless configurations typically use wireless transmitters and receivers, such as, for example, those commonly found in 802.11a, 802.11b and 802.11g wireless devices. The person of ordinary skill in the art, given the benefit of this disclosure, will be able to design suitable cooling devices that include electronically actuated valves and will be able to select suitable wired and wireless methods for controlling such valves.

In certain examples, the cooling device comprises a valve that is pressure or temperature actuated. For example, in certain configurations, a valve in the cooling device body may be open to provide heat to areas underlying the valve. If the temperature reaches above a certain threshold however, the valve can close to prevent damage to that area of the electronic component. Suitable pressure and temperature actuated valves will be readily selected by the person of ordinary skill in the art, given the benefit of this disclosure, and exemplary commercially available valves can be obtained, for example, from Cole-Parmer (Vernon Hills, Ill.), The Viking Corp. (Hastings, Mich.), Armstrong-International, Inc. (Three Rivers, Mich.), Parker Hannifin® Corp., NUMATICS® and the like.

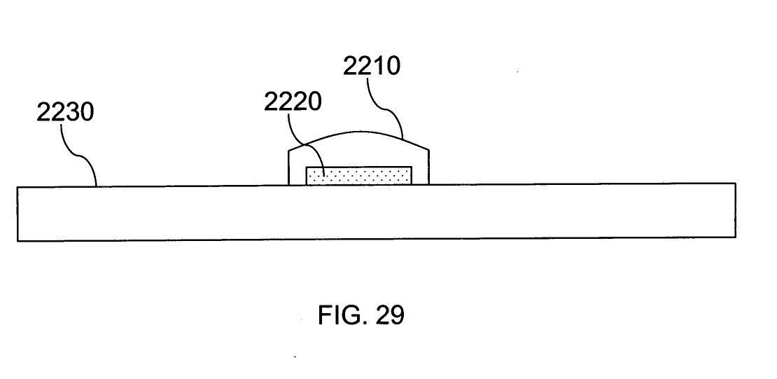

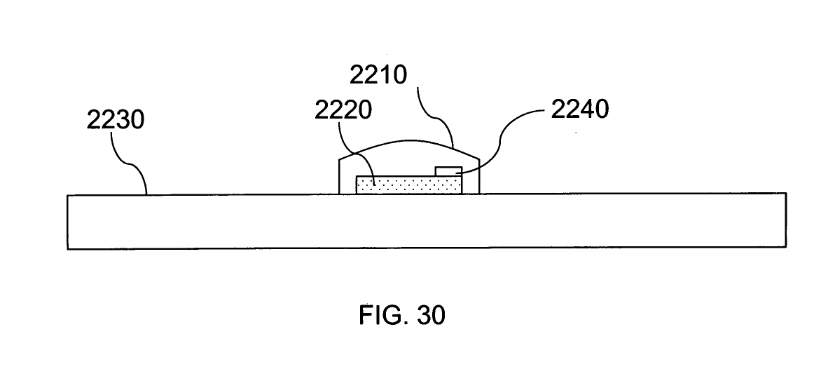

In accordance with certain examples, a cooling device comprising a mold compound body is provided. Without wishing to be bound by any particular scientific theory, the mold compound body is capable of being molded or formed into a suitable shape that can be placed in thermal communication with an electronic component. For example and referring to FIG. 29, mold compound body 2210 is in thermal communication with electronic component 2220 that has been placed on board 2230. As discussed in more detail below, mold compound body 2210 can be configured with heat absorptive and heat reflective regions to provide thermal protection to certain regions of electronic component 2220 while still allowing heat penetration to other areas of an electronic component, e.g., areas of an electronic component that include solder spheres. In some examples, mold compound body 2210 is placed on or around the entire surface of board 2230 to provide thermal protection to the board during a processing operation. In yet other examples, mold compound body 2210 may include tape 2240 disposed on the mold compound body (see FIG. 30). As discussed elsewhere herein, tape can be configured to provide additional cooling and may optionally include a cooling medium disposed on the tape. The tape may be disposed in many different patterns and configurations, and suitable patterns and configurations will be readily selected by the person of ordinary skill in the art, given the benefit of this disclosure. In some examples, the mold compound body includes one or more voids.

Suitable mold compounds for including in the mold compound body include, but are not limited to, thermosetting mold compounds, such as those commercially available from AIN plastics, Inc. H.B. Fuller Co., Monsanto Co., etc. curable mold compounds, rubber mold compounds, “green” mold compounds, flame retardant mold compounds, such as those commercially available from LNP Engineering Plastics, EMS-Grivory America, Plastx World Inc., RTP Co., etc., flexible mold compounds, epoxy mold compounds and the like. Additional suitable mold compounds that can be configured to provide thermal protection to an electronic component will be readily selected by the person of ordinary skill in the art, given the benefit of this disclosure.

In accordance with certain examples, a mold compound body may be manually molded into a suitable shape and disposed on an electronic component. In certain instances, the mold compound body is manually molded around exposed surfaces of an electronic component. In other examples, the mold compound body is placed into a cast or die that is configured to impart a suitable shape to the mold compound body to provide thermal protection to an electronic component in thermal communication with the mold compound body. Suitable casts or dies typically provide a cup shape or an inverted box shape to the mold compound body so that the cast mold compound body can be disposed on an electronic component with minimal or no additional molding.

In accordance with certain examples, the mold compound body can be selected to provide desired properties. For example, in certain configurations the mold compound body is selected so that it can flow into voids, cavities and the like present in or around an electronic component. The mold compound body can be injected into the voids, cavities, etc. or can be disposed on or near the voids, cavities, etc. and allowed to flow into the voids, cavities, etc. under gravitational forces. In some examples, the mold compound body encapsulates substantially all exposed surfaces of the electronic component to provide thermal protection to the exposed surfaces but does not flow into voids, cavities, etc. present in or around an electronic component.

In accordance with certain examples, the mold compound body may include one or more cooling media disposed on the mold compound body. The cooling media may be any one or more of the exemplary cooling media discussed herein or other suitable cooling media that will be readily selected by the person of ordinary skill in the art, given the benefit of this disclosure. In certain examples, the mold compound body includes a cooling medium that can flow into voids, cavities, etc. to provide additional thermal protection near the voids, cavities, etc. In some examples, the mold compound body is impregnated, soaked in or saturated with cooling media prior to placement of the mold compound body in thermal communication with an electronic component, whereas in other examples, the mold compound body is placed in thermal communication with an electronic component and a cooling media is disposed on the mold compound body. Without wishing to be bound by any particular scientific theory, the physical properties of the mold compound body may result in different retention volumes of cooling medium. For example, certain mold compound bodies may be highly porous and can retain larger amounts of cooling media, whereas other mold compound bodies may have few or no pores and may retain less cooling media. In examples, where mold compound bodies that retain little cooling media are selected it may be desirable or necessary to use a film, web or carrier to enhance cooling media retention. The mold compound body can be molded around the film, web or carrier or the film, web or carrier can be disposed on a surface of the mold compound body, e.g., the surface or surfaces of the mold compound body to be placed in thermal communication with an electronic component. The cooling medium may be disposed on the film, web or carrier prior to contact with the mold compound body or after contact with the mold compound. The person of ordinary skill in the art, given the benefit of this disclosure, will be able to select suitable methods and devices for disposal of cooling media on, or in, a mold compound body.

In accordance with certain examples, a cooling device comprising a mold compound body with tape disposed on the mold compound body is provided. In certain examples, the tape is disposed on the mold compound body using an automated process such as pick and place equipment, whereas in other examples tape is manually placed on certain areas of the mold compound body. The tape may be any of the exemplary tapes disclosed herein or other suitable tape that will be readily selected by the person of ordinary skill in the art, given the benefit of this disclosure. In some examples, the tape may include one or more cooling media disposed on the tape.

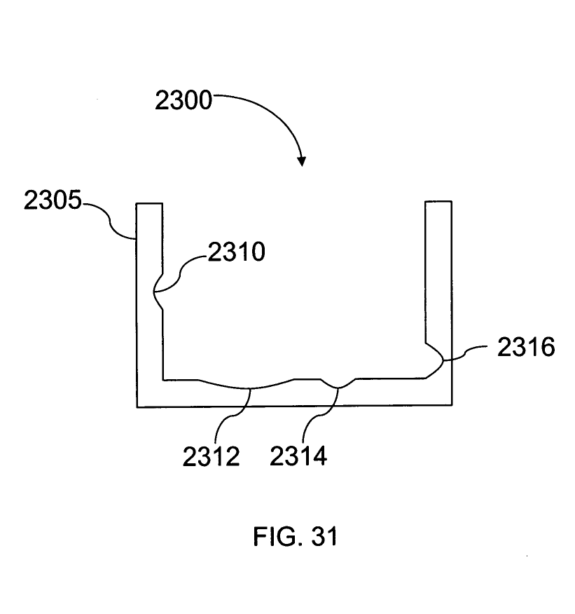

In accordance with certain examples, the mold compound body may include depressions, dimples or the like. Referring to FIG. 31, cooling device 2300 includes depressions 2310 and 2316 formed in sidewalls of cooling device body 2305. Cooling device body 2305 also includes depressions 2312 and 2314 formed in a top surface of cooling device 2300. In certain examples, a cast or die that includes projections may be used to provide depressions in surfaces of the mold compound body that are to be placed in thermal communication with an electronic component. In other examples, depressions or dimples can be manually placed in the mold compound body. In yet other examples, a depression or dimple can be formed by a device configured to dispose a cooling media on the mold compound body. For example, an injector can contact the surface of the mold compound body to form a depression and may then subsequently dispose a cooling medium in the depression. Additional methods and devices for forming depressions and dimples will be readily selected by the person of ordinary skill in the art, given the benefit of this disclosure. In examples where a cooling medium is disposed in a depression or dimple, the cooling medium may be any of the exemplary cooling media disclosed herein or other suitable cooling media that will be readily selected by the person of ordinary skill in the art, given the benefit of this disclosure.

In accordance with certain examples, the mold compound body can be reinforced with materials to provide additional rigidity to the mold compound body. For example, the mold compound body can include wires, powders, whiskers, fillers, fibers and the like to provide rigidity and/or alter the physical properties of the mold compound body. It will be within the ability of the person of ordinary skill in the art, given the benefit of this disclosure, to select suitable materials for providing rigidity and/or altering the physical properties of cooling devices comprising a mold compound body.

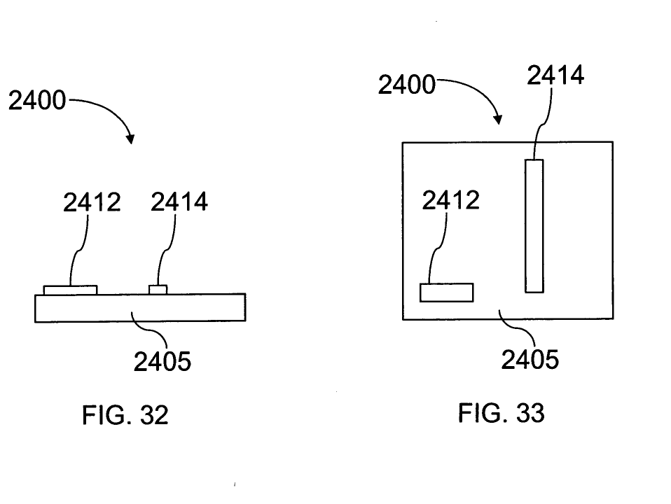

In accordance with certain examples, a cooling device comprising heat reflective materials disposed on the cooling device body is provided. In certain examples, at least one area of the cooling device includes a heat or infrared reflective material configured to reflect or direct heat to certain regions of an electronic component, e.g., regions of an electronic component that include solder spheres. For example and referring to FIGS. 32 and 33, cooling device 2400 includes cooling device body 2405 with heat reflective materials 2412 and 2414 disposed on certain regions of cooling device body 2405. The selected pattern or patterns for disposal of heat reflective materials depends at least in part on areas of the electronic component that need thermal protection and areas of the electronic component that need heat, e.g., for a reflow or rework operation. Areas of an electronic component that need heat for a reflow or rework operation typically underlie one or more heat reflective materials, whereas areas of an electronic component that require thermal protection typically underlie the cooling device body and/or a cooling medium. In some examples, the cooling device includes one or more voids.

In certain examples, the nature of the heat reflective material depends on the desired amount of heat to be reflected. In certain examples, at least about 75% of the heat is reflected, more particularly at least about 90% of the heat is reflected, e.g., at least about 95% of the heat is reflected. In other examples, a material with a low heat capacity, e.g., less than about 18-20 cal/deg-mol at 25° C., more particularly less than about 10-15 cal/deg-mol at 25° C., e.g., about 5-10 cal/deg-mol at 25° C., is disposed on the cooling device body to reflect heat. Exemplary materials that can be disposed on the cooling device body to reflect heat include, but are not limited to, aluminum, antimony, barium, beryllium, bismuth, boron, bromine, cadmium, calcium, carbon, cerium, chromium, cobalt, dysprosium, erbium, europium, gadolinium, germanium, gold, hafnium, holmium, indium, iridium, lanthanum, lithium, lutetium, magnesium, manganese, molybdenum, neodymium, nickel, niobium, osmium, palladium, platinum, praesodymium, promethium, rhenium, rhodium, rubidium, ruthenium, samarium, scandium, selenium, silicon, silver, sodium, strontium, sulfur, tantalum, technetium, tellurium, terbium, thallium, thorium, tin, titanium, tungsten, vanadium, ytterbium, yttrium, zinc, zirconium, and oxides, nitrides, hydrides, and alloys thereof. Additional suitable heat reflective materials include, but are not limited to, the materials included in the exemplary Sheldahl tapes disclosed herein.

In accordance with certain examples, the heat reflective materials can be disposed on the cooling device using numerous suitable methods including but not limited to rolling, spraying, brushing, spin-coating, physical vapor deposition, chemical vapor deposition, plasma assisted vapor deposition, molecular beam epitaxy and the like. Additional suitable methods for disposing heat reflective materials on a cooling device will be readily selected by the person of ordinary skill in the art, given the benefit of this disclosure.

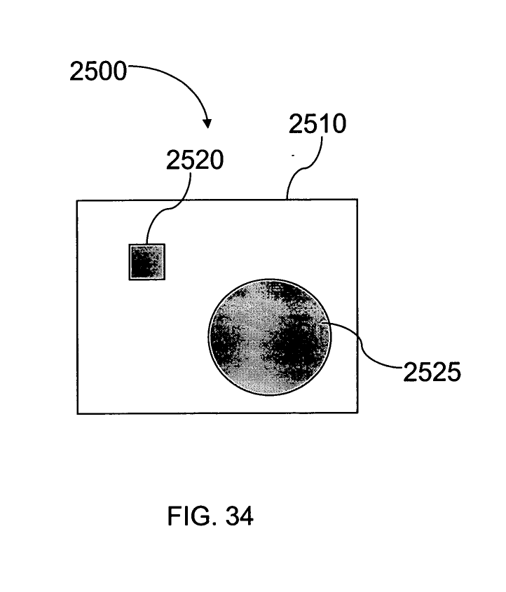

In accordance with certain examples, a cooling device having a cooling device body that is heat or infrared reflective is disclosed. In certain examples areas or regions of the heat reflective cooling device body that are to be placed in thermal communication with heat sensitive regions of an electronic component may include a heat absorptive region that optionally includes a cooling medium. For example and referring to FIG. 34, cooling device 2500 includes heat reflective cooling device body 2510 with heat absorptive regions 2520 and 2525. In some examples, one or both of heat absorptive regions 2520 and 2525 may include a cooling medium operative to provide thermal protection to areas underlying the heat absorptive regions. The cooling medium may be any of the exemplary cooling media disclosed herein or additional cooling media that will be readily selected by the person of ordinary skill in the art, given the benefit of this disclosure. While the exemplary heat absorptive regions shown in FIG. 34 are square and circular, the pattern or shape of the heat absorptive regions depends, at least in part, on the shape or configuration of the area of an electronic component that needs thermal protection. In certain examples, the shape or configuration of the heat absorptive region mirrors the shape of the area of the electronic component to be cooled. In some examples, the cooling device includes one or more voids.

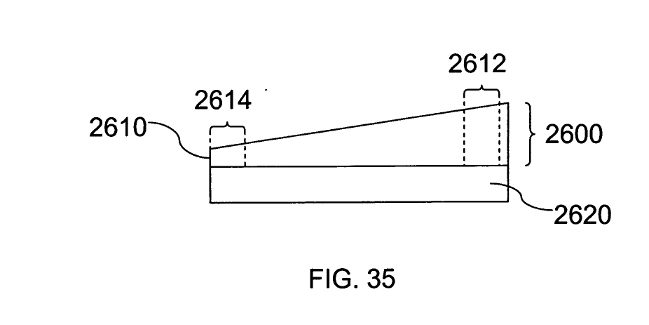

In accordance with certain examples, a cooling device having variable thermal mass is provided. Without wishing to be bound by any particular scientific theory, as thickness of the cooling device body increases, the ability of the cooling device to absorb heat also increases. For example, referring to FIG. 35, cooling device 2600 has a cooling device body 2610 with variable thickness. Electronic component 2620 is in thermal communication with cooling device 2600. Again without wishing to be bound by any particular scientific theory, region 2612 of cooling device body 2610 provides greater thermal mass than regions 2614 of cooling device body 2610 due to increased thickness at region 2612. In certain applications, it may be necessary to provide greater thermal mass to certain regions of an electronic component, e.g., the edges of a ball grid array. For example, thicker regions at the edges of the cooling device body can provide greater thermal mass to the edges of an electronic component. Such thicker regions may or may not include voids, cooling media, etc.

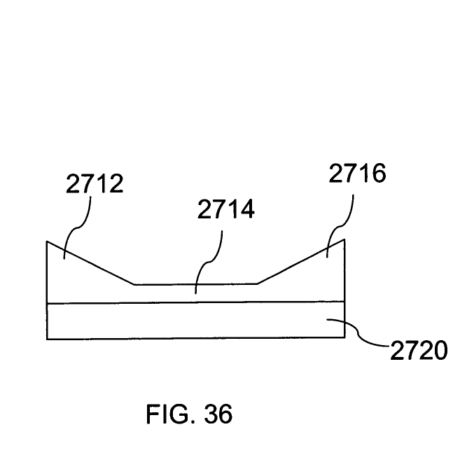

In accordance with certain examples, an integral or unitary cooling device is provided. Referring to FIG. 36, submount 2720 may include an electronic component mounted to it and beneath the electronic component may be a ball grid array, for example. Regions 2712 and 2716 are thicker portions that may optionally have tape, cooling media, etc. disposed on a surface in thermal communication with the submount. It will be within the ability of the person of ordinary skill in the art, given the benefit of this disclosure, to design and use integral cooling devices.

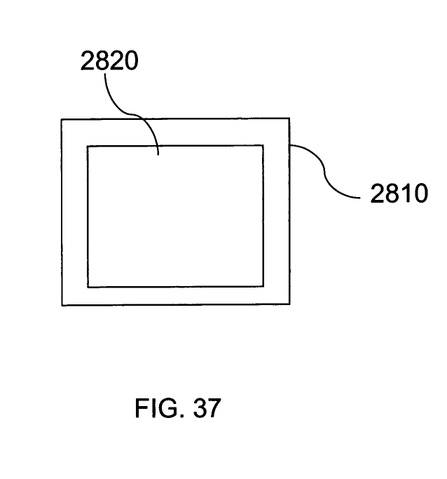

In accordance with certain examples, a cooling device configured to provide protection to the outer edges of an electronic component is disclosed. Referring to FIG. 37, cooling device 2810 is in thermal communication with the perimeter, e.g., the outer edges, of electronic component 2820 while leaving the top surface of electronic component 2820 open to ambient atmosphere. In certain examples, cooling device 2810 comprises one or more of a mold compound, tape, a polymer or polymers, a supporting skeleton, etc. In some examples, cooling device 2810 comprises tape optionally with a cooling medium disposed on the tape. In yet other examples, cooling device 2810 comprises a polymeric body optionally with a cooling medium disposed on the polymeric body. Additional configurations of cooling devices configured to provide thermal protection to the perimeter of electronic components, will be readily selected by the person of ordinary skill in the art, given the benefit of this disclosure. In some examples, the cooling device includes one or more voids, depressions, etc.

In accordance with certain examples, a cooling device configured for surface mount applications is provided. In certain examples, the cooling device is configured to be in thermal communication with exposed surfaces of an electronic component during fabrication of a board comprising the electronic component. In certain examples, the cooling device is permanently or removably mounted to a surface of an electronic component and is configured suitably to provide thermal protection to substantially all exposed surfaces of the electronic component. The cooling device may be mounted using clips, adhesives, tape or other suitable devices to retain the cooling device in thermal communication with surfaces of the electronic component. Additional suitable devices and methods for surface mounting cooling devices will be readily selected by the person of ordinary skill in the art, given the benefit of this disclosure.

In accordance with certain examples, surface mounted cooling devices may include one or more cooling media disposed on or in the cooling device body of the surface mounted cooling device. In other examples, the surface mounted cooling device includes tape disposed on the cooling device body. In yet other examples, the surface mounted cooling device includes heat or IR reflective materials disposed on one or more areas of the cooling device body. In still other examples, the surface mounted cooling device includes a mold compound in contact with one or more surfaces of the cooling device body. Additional configuration for surface mount cooling devices will be readily selected by the person of ordinary skill in the art, given the benefit of this disclosure. In some examples, the cooling device includes one or more voids.

In accordance with certain examples, a method of cooling an electronic component is provided. In certain examples, the method includes selecting a cooling device constructed and arranged to cool an electronic component during a processing operation. The cooling device may be any of the cooling devices disclosed herein or other suitable cooling devices that will be readily selected by the person of ordinary skill in the art, given the benefit of this disclosure. In certain examples, the cooling device comprises single-sided or double-sided tape optionally with a cooling medium disposed on the single-sided or double-sided tape. In certain examples, the selected cooling device may be placed on the electronic component before or after the electronic component is placed on a substrate. In some examples, a pick and place machine configured for a tape and reel process is used to place the cooling device. For example, the pick and place equipment may be configured to select a cooling device from a supply of cooling devices and place the selected cooling device and to release the cooling device on the electronic component.

In accordance with certain examples, a method of placing an electronic component is disclosed. The method includes selecting a cooling device constructed and arranged to cool an electronic component and placing the selected cooling device on the electronic component. The method further includes selecting the electronic component with the placed cooling device and placing the selected electronic component with the placed cooling device on a substrate. In certain examples, the cooling device comprises single-sided or double-sided tape optionally with a cooling medium disposed on the single-sided or double-sided tape. In some examples, pick and place equipment is used to select and place the cooling device on the electronic component and to select and place the electronic component/cooling device assembly on a substrate. In certain examples, the same pick and place equipment is used to perform the method. For example, a single pick and place equipment may be used to select and place the cooling device on an electronic component. The same pick and place equipment can be used to place the electronic component/cooling device assembly on a substrate. In other examples two or more pick and place devices may be used to perform the method. For example, a first pick and place device may be used to place the cooling device on the electronic component, and a second pick and place device may be used to place the electronic component/cooling device assembly on a substrate. The person of ordinary skill in the art, given the benefit of this disclosure, will be able to select a suitable pick and place device, or suitable pick and place devices, for selecting and placing cooling devices and electronic components.

Certain specific examples are described below to further illustrate the novel cooling devices disclosed herein. These specific examples should not be construed as limiting the scope and spirit of the appended claims.

### EXAMPLE 1

### 125° C. Peak Temperature

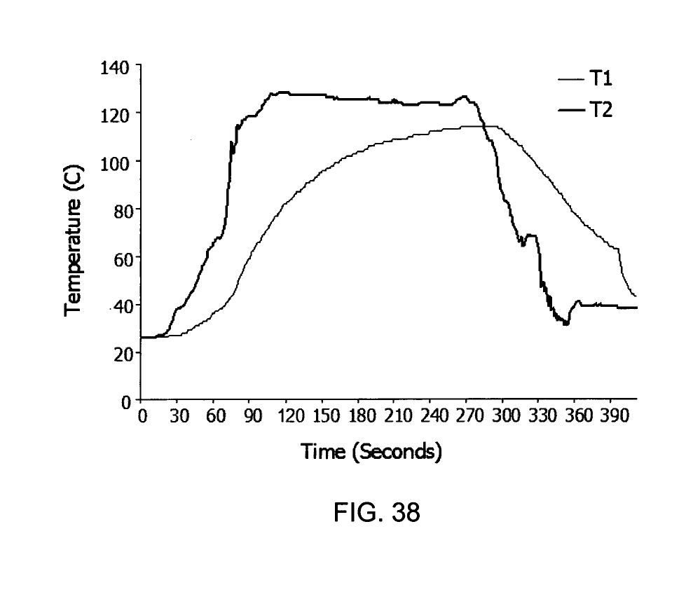

Commercial grade Plaster of Paris (75% CaSO₄.½H₂O) powder was mixed with water in a 2:1 weight ratio. Castings 1 cm thick were formed in an organic tray mold, then cut into six 3 cm×3 cm×1 cm samples using a band saw. The samples were then stored in a desiccator containing dry nitrogen to dry the samples. The samples were weighed at an average weight of 10.75 g. Two samples were soaked in water at room temperature for two hours. Two samples were soaked in NR330 flux (solids content of 4% and pH of 2.6) at room temperature for two hours. The four soaked samples weighed an average of 13.45 g. To compare the affect, if any, of the printed circuit board's thickness, three trials were performed on three boards with a thickness of about 62 mils, and three trials were performed on three boards with a thickness of about 93 mils. One thermocouple was placed at the center of a semiconductor package on each board (represented by T1), while another thermocouple was placed approximately 1 cm from the edge of the same semiconductor package (represented by T2). The six samples were then exposed to reflow processing at a peak temperature of 125° C. The results of these six trials are illustrated graphically in FIGS. 38-43. Board thickness did not appear to have a consistent effect on the samples' performance.

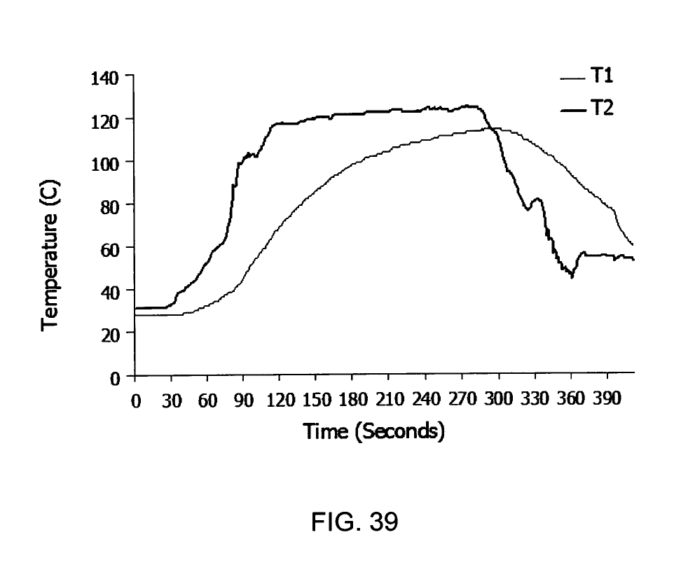

For the two dry samples, there was virtually no weight loss. The peak temperature at T1 was approximately 9-12° C. lower than at T2. See FIG. 38 for the 62 mil board and FIG. 39 for the 93 mil board).

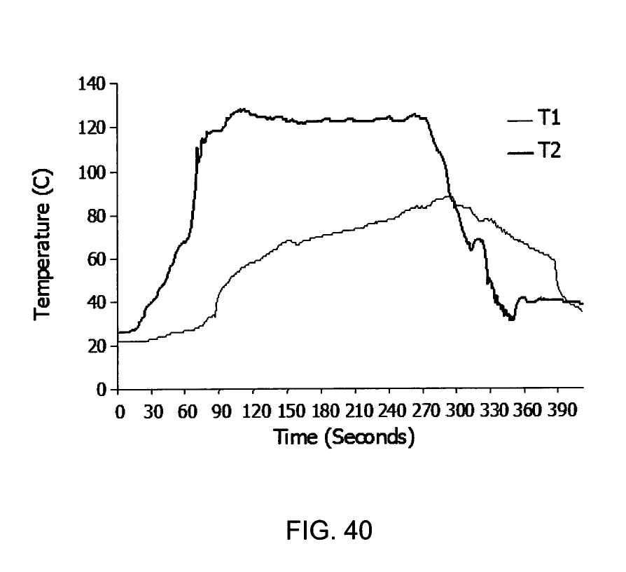

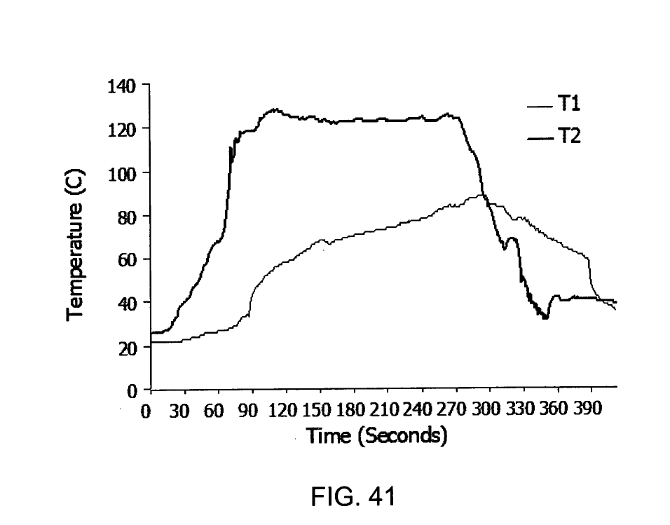

For the two samples soaked in water, there was a reduction of approximately 10-20% of the absorbed water weight. The peak temperature at T1 was approximately 58-63° C. lower than at T2. See FIG. 40 for the 62 mil board and FIG. 41 for the 93 mil board. Some residue on the boards was evident when the samples were removed after processing.

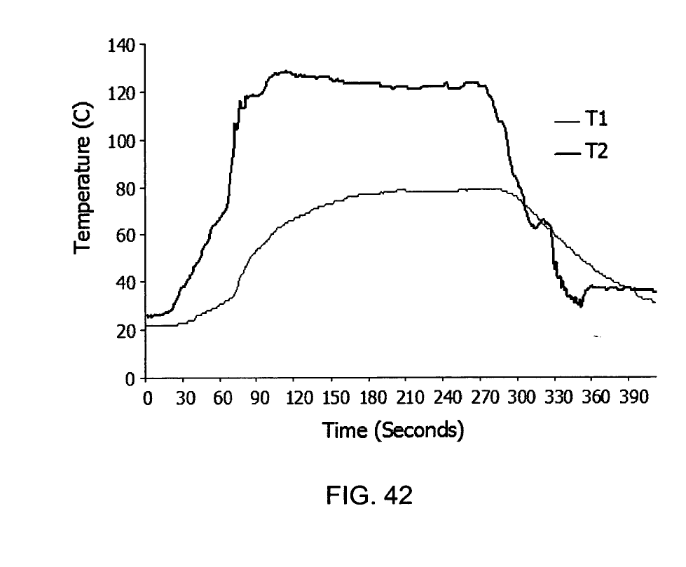

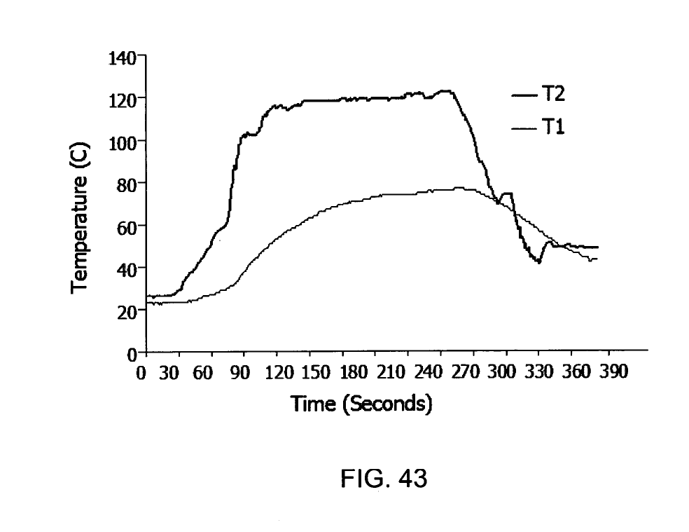

For the two samples soaked in flux, there was a reduction of approximately 10-20% of the absorbed flux weight. The peak temperature at T1 was approximately 35-45° C. lower than at T2. See FIG. 42 for the 62 mil board and FIG. 43 for the 93 mil board. Some residue on the boards was evident when the samples were removed after processing.

### EXAMPLE 2

### 220° C. Peak Temperature

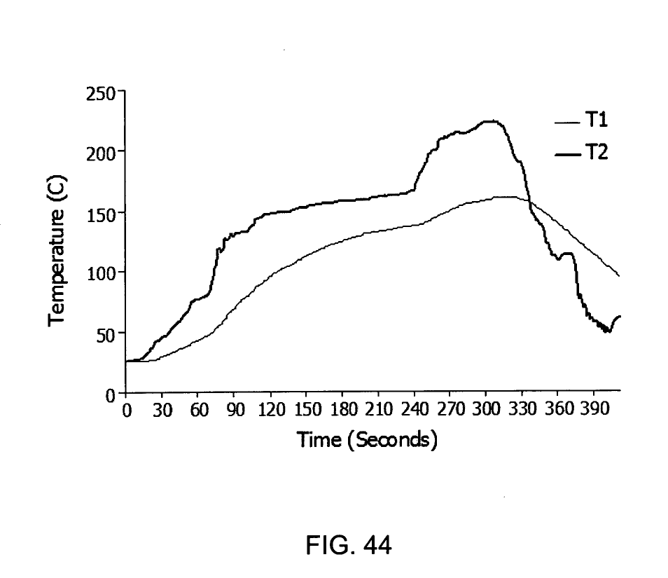

The experimental setup from Example 1 was duplicated to produce six additional samples, two of which were dry, two of which were soaked in water, and two of which were soaked in flux. The experimental procedure was carried out at a peak processing temperature of 220° C. The results of these six trials are illustrated graphically in FIGS. 44-49. Board thickness did not appear to have a consistent effect on the samples' performance.

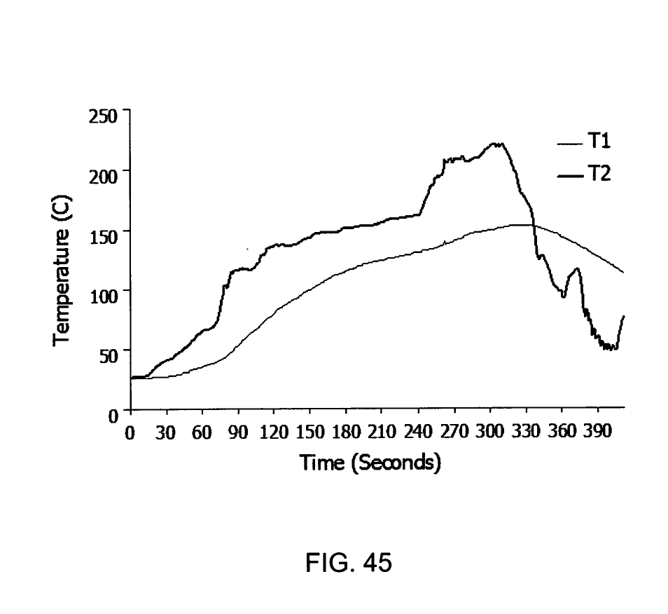

For the two dry samples, there was a reduction of approximately 7-8% by weight, which represents the residual water of hydration from the original sample mixing process. The peak temperature at T1 was approximately 43-48° C. lower than at T2. See FIG. 44 for the 62 mil board and FIG. 45 for the 93 mil board.

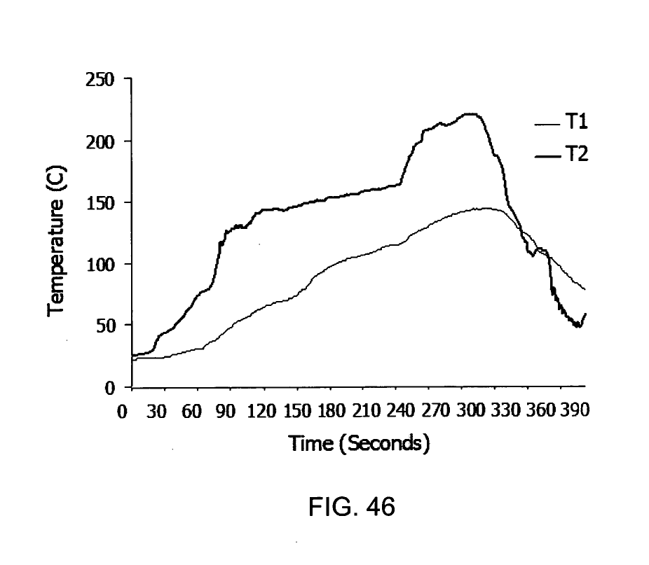

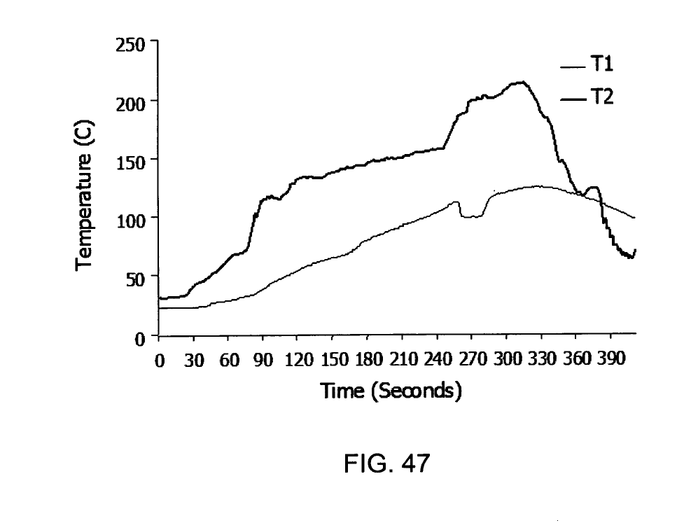

For the two samples soaked in water, there was a reduction of nearly 100% of the absorbed water weight. The peak temperature at T1 was approximately 67-88° C. lower than at T2. See FIG. 46 for the 62 mil board and FIG. 47 for the 93 mil board.

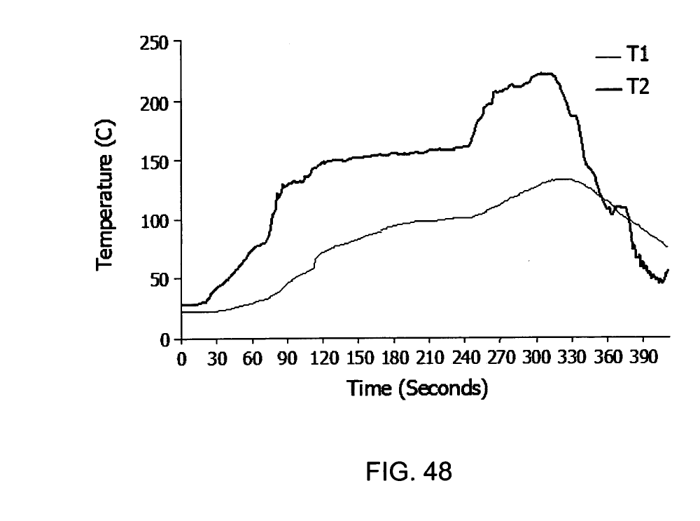

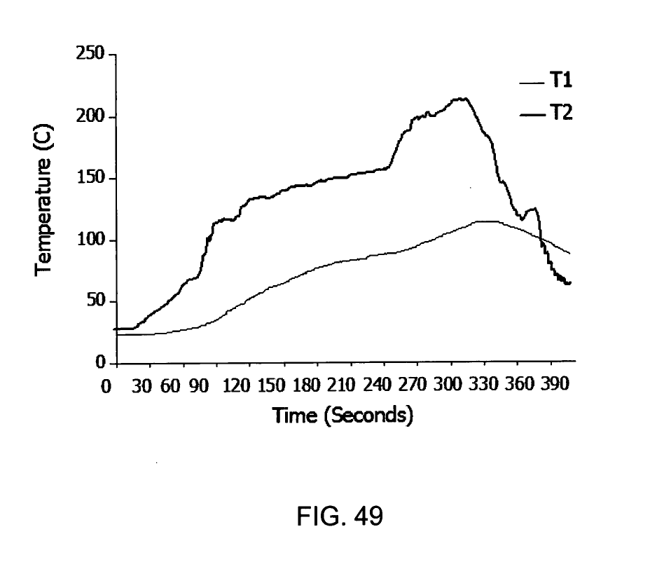

For the two samples soaked in flux, there was a reduction of approximately 94-97% of the absorbed flux weight. The peak temperature at T1 was approximately 32-70° C. lower than at T2. See FIG. 48 for the 62 mil board and FIG. 49 for the 93 mil board.

### EXAMPLE 3

### 260° C. Peak Temperature

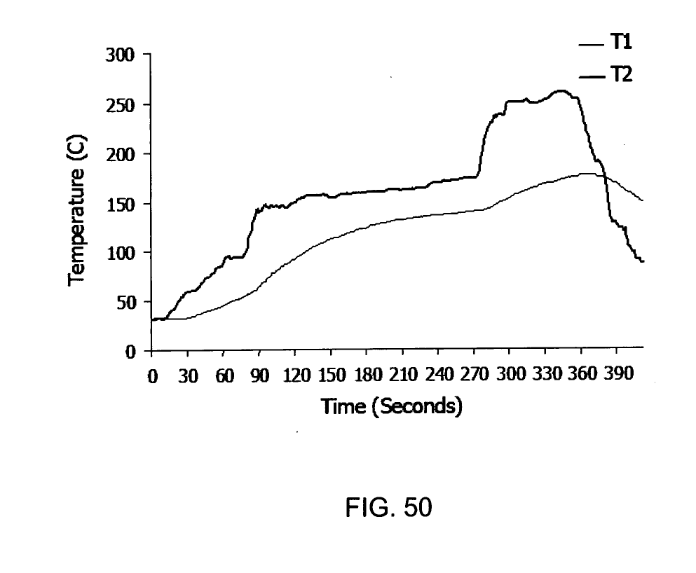

The experimental setup from Example 1 was duplicated to produce six additional samples, two of which were dry, two of which were soaked in water, and two of which were soaked in flux. The experimental procedure was carried out at a peak processing temperature of 260° C. The results of these six trials are illustrated graphically in FIGS. 50-55. Board thickness did not appear to have a consistent effect on the samples' performance.

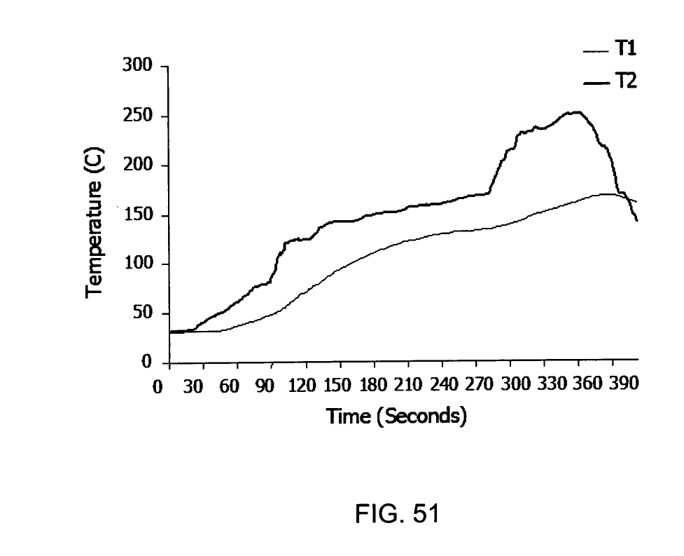

For the two dry samples, there was a reduction of approximately 8% by weight, which represents the residual water of hydration from the original sample mixing process. The peak temperature at T1 was approximately 47-49° C. lower than at T2. See FIG. 50 for the 62 mil board and FIG. 51 for the 93 mil board.

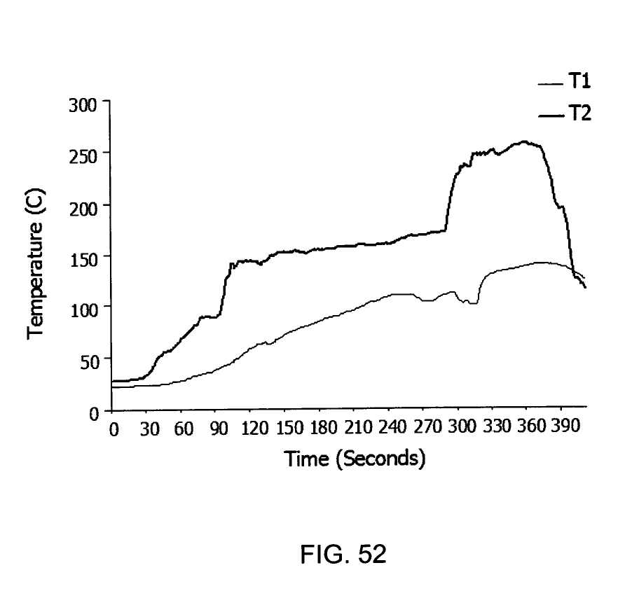

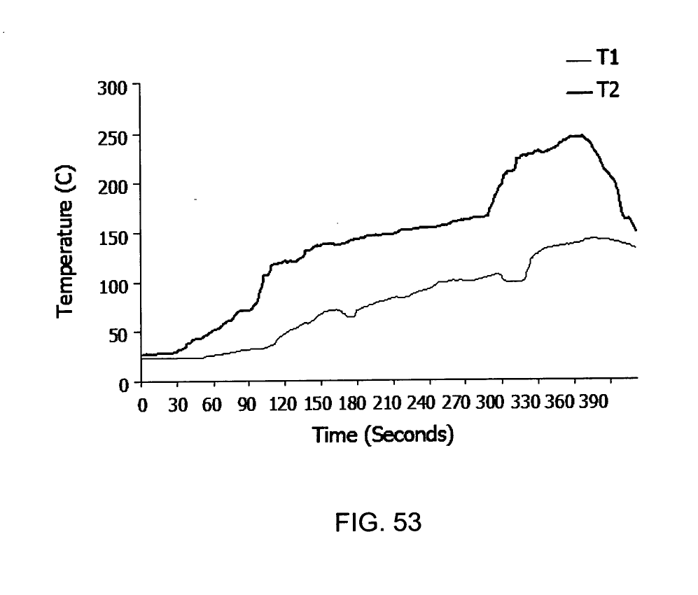

For the two samples soaked in water, there was a reduction of approximately 100% of the absorbed water weight and approximately 2% of the dry sample's weight, representing a loss of all the water absorbed during the two hour soak plus a portion of the residual water of hydration in the sample. The peak temperature at T1 was approximately 67-68° C. lower than at T2. See FIG. 52 for the 62 mil board and FIG. 53 for the 93 mil board. Some residue on the boards was evident when the samples were removed after processing.

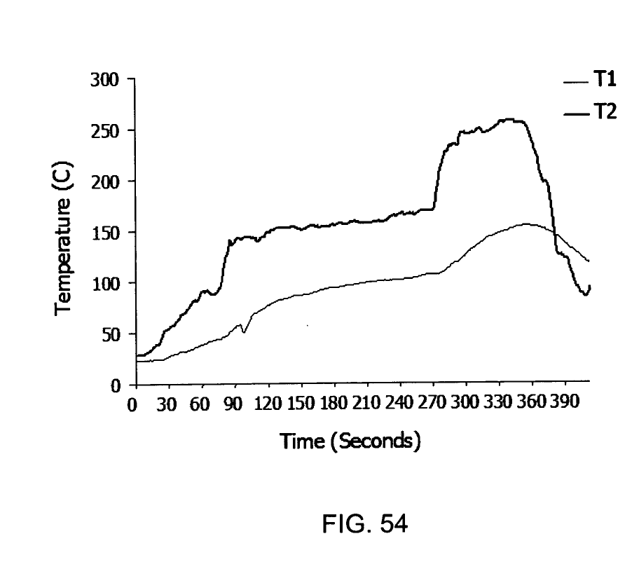

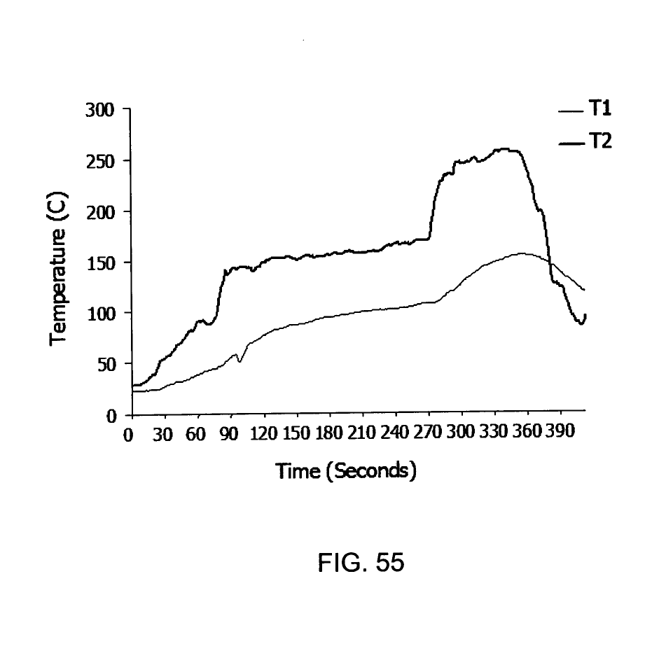

For the two samples soaked in flux, there was a reduction of approximately 100% of the absorbed flux weight and approximately 10% of the dry sample's weight, representing a loss of all the flux absorbed during the two hour soak plus a portion of the residual water of hydration in the sample. The peak temperature at T1 was approximately 73-85° C. lower than at T2. See FIG. 54 for the 62 mil board and FIG. 55 for the 93 mil board. Some residue on the boards was evident when the samples were removed after processing.

### EXAMPLE 4

A board-sized cooling device was prepared by casting commercial grade Plaster of Paris (75% CaSO₄) powder and water in a 2:1 weight ratio into a mold 14 inches wide and 22 inches long. The mold also contained a glass cloth, which was laid into the mold before the Plaster of Paris was poured into the mold. The cooling device casting was then removed from the mold and attached to a metal frame using room temperature vulcanizing (RTV) silicone. The metal frame/cooling device assembly was placed around multiple electronic components by joining the metal frame to the bottom of a printed circuit board, i.e., the side of the board opposite the electronic components.

### EXAMPLE 5

United State Gypsum's Hydrostone and water are weighed. 32 parts of water per 100 parts of plaster is the mixing ratio used for Hydrostone brand. Hydrostone is added to water and mixed slowly until a homogeneous slurry is formed. The soaking time varies with the batch size. A mixer is used to mix the water and Hydrostone. The mixer size and design can be changed based on the quantity to be mixed. The slurry is then poured slowly in a non-stick mold. Care is taken to avoid any entrapment of air. If needed a vibratory table is used, to remove any air bubbles from the cast. Depending on the cast size, and the material of the mold, ‘release agent’ is sometimes sprayed on the mold surface. A mold surface which is nonstick and with tapering shape which can be easily removed by push, is generally preferred. The poured material is then dried in a normal room temperature. The natural setting time is around 30 minutes and varies with the batch size. If dried in an oven, the drying temperature is kept below 49° C. to avoid calcinations of Hydrostone. The sheets after drying become hard and are removed from the mold. The cast sheets are then cut on a fine tooth band saw and block machined to shape using a milling machine and end mills. The machined cooling devices are dried in a oven which is set at 45 degree C. The drying is done as per “Standard Test Methods for Physical Testing of Gypsum, Gypsum Plasters and Gypsum Concrete” ASTM C-472-99 standard, the entire disclosure of which is hereby incorporated by reference for all purposes. The cooling devices are then stored in moisture sensitive bags, in a stable indoor environment.

For automated processes a CNC machine is used for machining. Alternatively, parts are directly molded to a desired shape. Ice cube type of non-stick trays can be used conveniently for making cooling devices. Resins are cast into a desired shape and heat reflective materials, e.g., tapes, are placed on the skeleton provided by the cast resin.

When introducing elements of the examples disclosed herein, the articles “a”, “an”, “the” and “said” are intended to mean that there are one or more of the elements. The terms “comprising”, “including” and “having” are intended to be open ended and mean that there may be additional elements other than the listed elements. It will be recognized by the person of ordinary skill in the art, given the benefit of this disclosure, that various components of the examples can be interchanged or substituted with various components in other examples. Should the meaning of the terms of any of the patents, patent applications or publications incorporated herein by reference conflict with the meaning of the terms used in this disclosure, the meaning of the terms in this disclosure are intended to be controlling.

Although certain aspects, examples and embodiments have been described above, it will be recognized by the person of ordinary skill in the art, given the benefit of this disclosure, that additions, substitutions, modifications, and alterations of the disclosed illustrative aspects, examples and embodiments are possible.

1. A cooling device comprising:
a cooling device body adapted to thermally protect an electronic component, the cooling device body comprising a void constructed and arranged to allow heat entry to the electronic component; and
a cooling medium disposed on or within the cooling device body, wherein the cooling device is constructed and arranged to cool at least some portion of an
electronic component during exposure of the electronic component to a process temperature between about 100° C. and 300° C. during a processing operation.

2. The cooling device of claim 1 in which the void is partially obstructed.

3. The cooling device of claim 2 in which the void is partially obstructed about 25%, 50% or about 75%.

4. The cooling device of claim 1 in which the cooling device body further comprises a cap for obstructing the void.

5. The cooling device of claim 1 in which the cooling device body comprises stamped metal or perforated metal.

6. The cooling device of claim 1 in which the void is round, oval, rectangular, triangular, rhomboidal or hexagonal.

7. The cooling device of claim 1 in which each of the cooling device body and the cooling medium is independently selected from the group consisting of Al₂O₃.1H₂O, Al₂O₃.3H₂O, Al₂SO₄, Al₂SO₄.6H₂O, Al(NO₃)₃.6H₂O, NH₄Al(SO₄)₂.12H₂O, Al₆Si₂O₁₃, Ba(BrO₃).2H₂O, Ba(IO₃)₂, Ba(NO₃)₂, BaO.2SiO₂, 2 BaO.SiO₂, 2BaO.3SiO₂, BaCrO₄, Bi₂(SO₄)₃, B(C₂H₅)₃, B(OCH₃)₃, HBrO₃, Ca(PO₃)₂, Ca₂P₂O₇, Ca₃(PO₄)₂, CaHPO₄.2H₂O, Ca(H₂PO₄).H₂O, CaC₂O₄.H₂O, 2CaO.SiO₂, CaO.Al₂O₃, CaO.2Al₂O₃, 2 CaO.Al₂O₃, 3CaO.Al₂O₃, CaO.Al₂O₃.2 SiO₂, CaO.Fe₂O₃, 2CaO.5MgO.8SiO₂.H₂O, CCl₄, CBr₄, NH₄CN, CH₃NO₃, CH₃COOH, CH₃COO—, CH₂ClCH₂Cl, CCl₃CHO, CCl₃CH(OH)₂, CF₂ClCFCl₂, CH₂BrCH₂Br, (CH₃)₂SO, C₂H₅NO₂, CH₃CH₂ONO₂, (NH₄)₂C₂O₄, CH₃N, Ce₂(SO₄)₃.5H₂O, Cs₂SO₄, Cs₂Cr₂O₇, Cs₂UO₄, Cr₂(SO₄)₃, Cr₇C₃, Cr₂₃C₆, Ag₂CrO₄, CoSO₄.6H₂O, CoSO₄.7H₂O, [Co(NH₃)₆]Br₃, CuSO₄.3H₂O, CuSO₄.5H₂O, DyCl₃.6H₂O, ErCl₃.6H₂O, EuCl₃.6H₂O, Eu₂(SO₄).8H₂O, GdCl₃.6H₂O, Gd₂(SO₄).8H₂O, Gd(NO₃).6H₂O, HoCl₃.6H₂O, Fe₃O₄, FeSO₄.7H₂O, LaCl₃.7H₂O, La₂(SO₄)₃.9H₂O, LiSO₄.H₂O, Li₂SO₄.D₂O, LuCl₃.6H₂O, MgCl₂.2H₂O, MgCl₂.4H₂O, MgCl₂.6H₂O, MgSO₄.6H₂O, Mg₂P₂O₇, Mg₃(PO₄)₂, Mg₃SiO₅(OH)₄, Mg₃Si₄O₁₀(OH)₂, Mg₂Al₄Si₅O₁₈, MgV₂O₆, MgV₂O₇, Mg₂TiO₄, MgUO₄, MgU₃O₁₀, Mn₃O₄, MnSO₄.5H₂O, Hg₂SO₄, MoF₆, Mo(CO)₆, FeMoO₄, NdCl₃.6H₂O, Nd₂(SO₄)₃.8H₂O, Nd₂Se₃, NiSO₄, NiSO₄.6H₂O, NiSO₄.7H₂O, Ni(NO₃)₂.6H₂O, NiCO₃, Ni(CO)₄, Nb₂O₅, NbF₅, NbCl₅, N₂O₃, NH₄OH, NH₄NO₃, (NH₄)₂O, P₄O₁₀, KClO₄, KBrO, KBrO₃, KBrO₄, K₂SO₄, KH₂AsO₄, KAl(SO₄)₂, KAl(SO₄)₂.12H₂O, K₄Fe(CN)₆, C₂Cr₂O₇, Rb₂SO₄, Sm₂O₃, SmCl₃.6H₂O, Sc₂(SO₄)₃, Sc(HCO₂)₃, Sc₂(C₂O₄)₃, Ag₂SO₄, Na₂SO₄, Na₃PO₄, (NaPO₃)₃, Na₄P₂O₇, Na₅P₃O₁₀, Na₂HPO₄, Na₂H₂P₂O₇, Na₂CO₃.H₂O, Na₂CO₃.10H₂O, Na₂C₂O₄, Na₂B₄O₇, Na₂B₄O₇.10H₂O, NaAlSi₂O₆, Na₂CrO₄, Na₂MoO₄, Na₂WO₄, Na₂VO₃, Na₄V₂O₇, Na₂Ti₂O₅, Na₂UO₄, SrCl₂.2H₂O, Sr(NO₃)₂, Sr₂SiO₄, Sr₂TiO₄, H₂SO₄.1H₂O, H₂SO₄.2H₂O, H₂SO₄.3H₂O, H₂SO₄.4H₂O, H₂SO₄.6.5H₂O, SOCl₂, SO₂Cl₂, Ta₂O₅, Tb₂O₃, Tm₂O₃, SnCl₂.2H₂O, TiCl₄, TiBr₄, TiI₂, W(CO)₆, Fe₇W₆, MnWO₄, V₂O₄, V₂O₅, ZnSO₄.6H₂O, ZnSO₄.7H₂O, Zn(NO₃)₂.6H₂O, Zn₂SiO₄, ZrCl₄, and Zr(SO₄)₂.

8. The cooling device of claim 1 further comprising a cooling medium disposed in the void.

9. The cooling device of claim 8 in which the cooling medium disposed in the void is selected from the group consisting of Al₂O₃.H₂O, Al₂O₃.3H₂O, Al₂SO₄, Al₂SO₄.6H₂O, Al(NO₃)₃.6H₂O, NH₄Al(SO₄)₂.12H₂O, Al₆Si₂O₁₃, Ba(BrO₃).2H₂O, Ba(IO₃)₂, Ba(NO₃)₂, BaO.2SiO₂, 2 BaO.SiO₂, 2BaO.3SiO₂, BaCrO₄, Bi₂(SO₄)₃, B(C₂H₅)₃, B(OCH₃)₃, HBrO₃, Ca(PO₃)₂, Ca₂P₂O₇, Ca₃(PO₄)₂, CaHPO₄.2H₂O, Ca(H₂PO₄).H₂O, CaC₂O₄.H₂O, 2CaO.SiO₂, CaO.Al₂O₃, CaO.2Al₂O₃, 2 CaO.Al₂O₃, 3CaO.Al₂O₃, CaO.Al₂O₃.2SiO₂, CaO.Fe₂O₃, 2CaO.5MgO.8SiO₂.H₂O, CCl₄, CBr₄, NH₄CN, CH₃NO₃, CH₃COOH, CH₃COO—, CH₂ClCH₂Cl, CCl₃CHO, CCl₃CH(OH)₂, CF₂ClCFCl₂, CH₂BrCH₂Br, (CH₃)₂SO, C₂H₅NO₂, CH₃CH₂ONO₂, (NH₄)₂C₂O₄, CH₃N, Ce₂(SO₄)₃.5H₂O, Cs₂SO₄, Cs₂Cr₂O₇, Cs₂UO₄, Cr₂(SO₄)₃, Cr₇C₃, Cr₂₃C₆, Ag₂CrO₄, CoSO₄.6H₂O, CoSO₄.7H₂O, [Co(NH₃)₆]Br₃, CuSO₄.3H₂O, CuSO₄.5H₂O, DyCl₃.6H₂O, ErCl₃.6H₂O, EuCl₃.6H₂O, Eu₂(SO₄).8H₂O, GdCl₃.6H₂O, Gd₂(SO₄).8H₂O, Gd(NO₃).6H₂O, HoCl₃.6H₂O, Fe₃O₄, FeSO₄.7H₂O, LaCl₃.7H₂O, La₂(SO₄)₃.9H₂O, LiSO₄.H₂O, Li₂SO₄.D₂O, LuCl₃.6H₂O, MgCl₂.2H₂O, MgCl₂.4H₂O, MgCl₂.6H₂O, MgSO₄.6H₂O, Mg₂P₂O₇, Mg₃(PO₄)₂, Mg₃Si₂O₅(OH)₄, Mg₃Si₄O₁₀(OH)₂, Mg₂Al₄Si₅O₁₈, MgV₂O₆, MgV₂O₇, Mg₂TiO₄, MgUO₄, MgU₃O₁₀, Mn₃O₄, MnSO₄.5H₂O, Hg₂SO₄, MoF₆, Mo(CO)₆, FeMoO₄, NdCl₃.6H₂O, Nd₂(SO₄)₃.8H₂O, Nd₂Se₃, NiSO₄, NiSO₄.6H₂O, NiSO₄.7H₂O, Ni(NO₃)₂.6H₂O, NiCO₃, Ni(CO)₄, Nb₂O₅, NbF₅, NbCl₅, N₂O₃, NH₄OH, NH₄NO₃, (NH₄)₂O, P₄O₁₀, KClO₄, KBrO, KBrO₃, KBrO₄, K₂SO₄, KH₂AsO₄, KAl(SO₄)₂, KAl(SO₄)₂.12H₂O, K₄Fe(CN)₆, C₂Cr₂O₇, Rb₂SO₄, Sm₂O₃, SmCl₃.6H₂O, Sc₂(SO₄)₃, Sc(HCO₂)₃, Sc₂(C₂O₄)₃, Ag₂SO₄, Na₂SO₄, Na₃PO₄, (NaPO₃)₃, Na₄P₂O₇, Na₅P₃O₁₀, Na₂HPO₄, Na₂H₂P₂O₇, Na₂CO₃.H₂O, Na₂CO₃.10H₂O, Na₂C₂O₄, Na₂B₄O₇, Na₂B₄O₇.10H₂O, NaAlSi₂O₆, Na₂CrO₄, Na₂MoO₄, Na₂WO₄, Na₂VO₃, Na₄V₂O₇, Na₂Ti₂O₅, Na₂UO₄, SrCl₂.2H₂O, Sr(NO₃)₂, Sr₂SiO₄, Sr₂TiO₄, H₂SO₄.1H₂O, H₂SO₄.2H₂O, H₂SO₄.3H₂O, H₂SO₄.4H₂O, H₂SO₄.6.5H₂O, SOCl₂, SO₂Cl₂, Ta₂O₃, Tb₂O₃, Tm₂O₃, SnCl₂.2H₂O, TiCl₄, TiBr₄, TiI₄, W(CO)₆, Fe₇W₆, MnWO₄, V₂O₄, V₂O₅, ZnSO₄.6H₂O, ZnSO₄.7H₂O, Zn(NO₃)₂.6H₂O, Zn₂SiO₄, ZrCl₄, and Zr(SO₄)₂.

10. A cooling device comprising:
a cooling device body adapted to thermally protect an electronic component, the cooling device body comprising a plurality of voids each configured to provide heat entry to the electronic component; and
a cooling medium disposed on or within the cooling device body, wherein the cooling device is constructed and arranged to cool an electronic component during
exposure of the electronic component to a process temperature between about 100° C. and 300° C. during a processing operation.

11. The cooling device of claim 10 in which one or more of the plurality of voids is filled with a cooling medium selected from the group consisting of Al₂O₃.H₂O, Al₂O₃.3H₂O, Al₂SO₄, Al₂SO₄.6H₂O, Al(NO₃)₃.6H₂O, NH₄Al(SO₄)₂.12H₂O, Al₆Si₂O₁₃, Ba(BrO₃).2H₂O, Ba(IO₃)₂, Ba(NO₃)₂, BaO.2SiO₂, 2 BaO.SiO₂, 2BaO.3SiO₂, BaCrO₄, Bi₂(SO₄)₃, B(C₂H₅)₃, B(OCH₃)₃, HBrO₃, Ca(PO₃)₂, Ca₂P₂O₇, Ca₃(PO₄)₂, CaHPO₄.2H₂O, Ca(H₂PO₄).H₂O, CaC₂O₄.H₂O, 2CaO.SiO₂, CaO.Al₂O₃, CaO.2Al₂O₃, 2 CaO.Al₂O₃, 3CaO.Al₂O₃, CaO.Al₂O₃.2SiO₂, CaO.Fe₂O₃, 2CaO.5MgO.8SiO₂.H₂O, CCl₄, CBr₄, NH₄CN, CH₃NO₃, CH₃COOH, CH₃COO—, CH₂ClCH₂Cl, CCl₃CHO, CCl₃CH(OH)₂, CF₂ClCFCl₂, CH₂BrCH₂Br, (CH₃)₂SO, C₂H₅NO₂, CH₃CH₂ONO₂, (NH₄)₂C₂O₄, CH₃N, Ce₂(SO₄)₃.5H₂O, Cs₂SO₄, Cs₂Cr₂O₇, Cs₂UO₄, Cr₂(SO₄)₃, Cr₇C₃, Cr₂₃C₆, Ag₂CrO₄, CoSO₄.6H₂O, CoSO₄.7H₂O, [Co(NH₃)₆]Br₃, CuSO₄.3H₂O, CuSO₄.5H₂O, DyCl₃.6H₂O, ErCl₃.6H₂O, EuCl₃.6H₂O, Eu₂(SO₄).8H₂, GdCl₃.6H₂O, Gd₂(SO₄).8H₂O, Gd(NO₃).6H₂O, HoCl₃.6H₂O, Fe₃O₄, FeSO₄.7H₂O, LaCl₃.7H₂O, La₂(SO₄)₃.9H₂O, LiSO₄.H₂O, Li₂SO₄.D₂O, LuCl₃.6H₂O, MgCl₂.2H₂O, MgCl₂.4H₂O, MgCl₂.6H₂O, MgSO₄.6H₂O, Mg₂P₂O₇, Mg₃(PO₄)₂, Mg₃Si₂O₅(OH)₄, Mg₃Si₄O₁₀(OH)₂, Mg₂Al₄Si₅O₁₈, MgV₂O₆, MgV₂O₇, Mg₂TiO₄, MgUO₄, MgU₃O₁₀, Mn₃O₄, MnSO₄.5H₂O, Hg₂SO₄, MoF₆, Mo(CO)₆, FeMoO₄, NdCl₃.6H₂O, Nd₂(SO₄)₃.8H₂O, Nd₂Se₃, NiSO₄, NiSO₄.6H₂O, NiSO₄.7H₂O, Ni(NO₃)₂.6H₂O, NiCO₃, Ni(CO)₄, Nb₂O₅, NbF₅, NbCl₅, N₂O₃, NH₄OH, NH₄NO₃, (NH₄)₂O, P₄O₁₀, KClO₄, KBrO, KBrO₃, KBrO₄, K₂SO₄, KH₂AsO₄, KAl(SO₄)₂, KAl(SO₄)₂.12H₂O, K₄Fe(CN)₆, C₂Cr₂O₇, Rb₂SO₄, Sm₂O₃, SmCl₃.6H₂O, Sc₂(SO₄)₃, Sc(HCO₂)₃, Sc₂(C₂O₄)₃, Ag₂SO₄, Na₂SO₄, Na₃PO₄, (NaPO₃)₃, Na₄P₂O₇, Na₅P₃O₁₀, Na₂HPO₄, Na₂H₂P₂O₇, Na₂CO₃.H₂O, Na₂CO₃.10H₂O, Na₂C₂O₄, Na₂B₄O₇, Na₂B₄O₇.10H₂O, NaAlSi₂O₆, Na₂CrO₄, Na₂MoO₄, Na₂WO₄, Na₂VO₃, Na₄V₂O₇, Na₂Ti₂O₅, Na₂UO₄, SrCl₂.2H₂O, Sr(NO₃)₂, Sr₂SiO₄, Sr₂TiO₄, H₂SO₄.1H₂O, H₂SO₄.2H₂O, H₂SO₄.3H₂O, H₂SO₄.4H₂O, H₂SO₄.6.5H₂O, SOCl₂, SO₂Cl₂, Ta₂O₅, Tb₂O₃, Tm₂O₃, SnCl₂.2H₂O, TiCl₄, TiBr₄, TiI₂, W(CO)₆, Fe₇W₆, MnWO₄, V₂O₄, V₂O₅, ZnSO₄.6H₂O, ZnSO₄.7H₂O, Zn(NO₃)₂.6H₂O, Zn₂SiO₄, ZrCl₄, and Zr(SO₄)₂.

12. The cooling device of claim 10 in which one or more of the plurality of voids is partially obstructed.

13. The cooling device of claim 12 in which tape partially obstructs the one or more plurality of voids.

14. The cooling device of claim 13 in which the tape comprises one or more cooling media.

15. The cooling device of claim 14 in which the tape is selected from the group consisting of polyimide tapes, gold coated polyimide tapes, aluminum coated polyimide tapes, and aluminum coated polyimide tapes comprising silicone adhesive.

16. The cooling device of claim 12 in which the one or more plurality of voids is partially obstructed by 25%-75%.

17. The cooling device of claim 16 in which the one or more plurality of voids is partially obstructed by 40%-55%.

18. A cooling device comprising:
tape constructed and arranged to cool an electronic component during exposure of the electronic component to a process temperature between about 100° C. and 300° C. during a processing operation; and
a cooling medium disposed on the tape.

19. The cooling device of claim 18 in which the tape is selected from the group consisting of polyimide tapes, gold coated polyimide tapes, aluminum coated polyimide tapes, and aluminum coated polyimide tapes comprising silicone adhesive.

20. The cooling device of claim 18 in which the cooling medium is selected from the group consisting of Al₂O₃.H₂O, Al₂O₃.3H₂O, Al₂SO₄, Al₂SO₄.6H₂O, Al(NO₃)₃.6H₂O, NH₄Al(SO₄)₂.12H₂O, Al₆Si₂O₁₃, Ba(BrO₃).2H₂O, Ba(IO₃)₂, Ba(NO₃)₂, BaO.2SiO₂, 2 BaO.SiO₂, 2BaO.3SiO₂, BaCrO₄, Bi₂(SO₄)₃, B(C₂H₅)₃, B(OCH₃)₃, HBrO₃, Ca(PO₃)₂, Ca₂P₂O₇, Ca₃(PO₄)₂, CaHPO₄.2H₂O, Ca(H₂PO₄).H₂O, CaC₂O₄.H₂O, 2CaO.SiO₂, CaO.Al₂O₃, CaO.2Al₂O₃, 2 CaO.Al₂O₃, 3CaO.Al₂O₃, CaO.Al₂O₃.2SiO₂, CaO.Fe₂O₃, 2CaO.5MgO.8SiO₂.H₂O, CCl₄, CBr₄, NH₄CN, CH₃NO₃, CH₃COOH, CH₃COO—, CH₂ClCH₂Cl, CCl₃CHO, CCl₃CH(OH)₂, CF₂ClCFCl₂, CH₂BrCH₂Br, (CH₃)₂SO, C₂H₅NO₂, CH₃CH₂ONO₂, (NH₄)₂C₂O₄, CH₃N, Ce₂(SO₄)₃.5H₂O, Cs₂SO₄, Cs₂Cr₂O₇, Cs₂UO₄, Cr₂(SO₄)₃, Cr₇C₃, Cr₂₃C₆, Ag₂CrO₄, CoSO₄.6H₂O, CoSO₄.7H₂O, [Co(NH₃)₆]Br₃, CuSO₄.3H₂O, CuSO₄.5H₂O, DyCl₃.6H₂O, ErCl₃.6H₂O, EuCl₃.6H₂O, Eu₂(SO₄).8H₂O, GdCl₃.6H₂O, Gd₂(SO₄).8H₂O, Gd(NO₃).6H₂O, HoCl₃.6H₂O, Fe₃O₄, FeSO₄.7H₂O, LaCl₃.7H₂O, La₂(SO₄)₃.9H₂O, LiSO₄.H₂O, Li₂SO₄.D₂O, LuCl₃.6H₂O, MgCl₂.2H₂O, MgCl₂.4H₂O, MgCl₂.6H₂O, MgSO₄.6H₂O, Mg₂P₂O₇, Mg₃(PO₄)₂, Mg₃Si₂O₅(OH)₄, Mg₃Si₄O₁₀(OH)₂, Mg₂Al₄Si₅O₁₈, MgV₂O₆, MgV₂O₇, Mg₂TiO₄, MgUO₄, MgU₃O₁₀, Mn₃O₄, MnSO₄.5H₂O, Hg₂SO₄, MoF₆, Mo(CO)₆, FeMoO₄, NdCl₃.6H₂O, Nd₂(SO₄)₃.8H₂O, Nd₂Se₃, NiSO₄, NiSO₄.6H₂O, NiSO₄.7H₂O, Ni(NO₃)₂.6H₂O, NiCO₃, Ni(CO)₄, Nb₂O₅, NbF₅, NbCl₅, N₂O₃, NH₄OH, NH₄NO₃, (NH₄)₂O, P₄O₁₀, KClO₄, KBrO, KBrO₃, KBrO₄, K₂SO₄, KH₂AsO₄, KAl(SO₄)₂, KAl(SO₄)₂.12H₂O, K₄Fe(CN)₆, C₂Cr₂O₇, Rb₂SO₄, Sm₂O₃, SmCl₃.6H₂O, Sc₂(SO₄)₃, Sc(HCO₂)₃, Sc₂(C₂O₄)₃, Ag₂SO₄, Na₂SO₄, Na₃PO₄, (NaPO₃)₃, Na₄P₂O₇, Na₅P₃O₁₀, Na₂HPO₄, Na₂H₂P₂O₇, Na₂CO₃.H₂O, Na₂CO₃.10H₂O, Na₂C₂O₄, Na₂B₄O₇, Na₂B₄O₇.10H₂O, NaAlSi₂O₆, Na₂CrO₄, Na₂MoO₄, Na₂WO₄, Na₂VO₃, Na₄V₂O₇, Na₂Ti₂O₅, Na₂UO₄, SrCl₂.2H₂O, Sr(NO₃)₂, Sr₂SiO₄, Sr₂TiO₄, H₂SO₄.1H₂O, H₂SO₄.2H₂O, H₂SO₄.3H₂O, H₂SO₄.4H₂O, H₂SO₄.6.5H₂O, SOCl₂, SO₂Cl₂, Ta₂O₅, Tb₂O₃, Tm₂O₃, SnCl₂.2H₂O, TiCl₄, TiBr₄, TiI₂, W(CO)₆, Fe₇W₆, MnWO₄, V₂O₄, V₂O₅, ZnSO₄.6H₂O, ZnSO₄.7H₂O, Zn(NO₃)₂.6H₂O, Zn₂SiO₄, ZrCl₄, and Zr(SO₄)₂.

21. The cooling device of claim 20 further comprising voids in the tape, wherein the voids are configured to allow heat entry.

22. The cooling device of claim 18 in which the tape is about 0.25 mils to about 7 mils thick.

23. The cooling device of claim 18 in which the tape comprises a temperature indicator.

24-26. (canceled)

27. A cooling device comprising:
a polymeric cooling device body constructed and arranged to cool an electronic component during exposure of the electronic component to a process temperature between about 100° C. and 300° C. during a processing operation.

28. The cooling device of claim 27 further comprising a cooling medium disposed on the polymeric cooling device body.

29. The cooling device of claim 27 in which the polymeric cooling device body comprises polyimide, polyphenylene sulfide, a fluoropolymer, polyetheretherketone, a liquid-crystal polymer, a polyphthalamide or combinations thereof.

30. The cooling device of claim 29 further comprising a cooling medium disposed on the polymeric cooling device body.

31. The cooling device of claim 27 further comprising a tape disposed on the polymeric cooling device body.

32-73. (canceled)
